(19) United States
(12) Patent Application Publication
(10) Pub. No.: US 2024/0386959 A1
(43) Pub. Date: Nov. 21, 2024

(54) THREE-DIMENSIONAL MEMORY DEVICE INCLUDING TRENCH BRIDGE STRUCTURES HAVING DIFFERENT VOLUMES AND METHODS OF FORMING THE SAME

(71) Applicant: WESTERN DIGITAL TECHNOLOGIES, INC., SAN JOSE, CA (US)

(72) Inventors: Jixin YU, Milpitas, CA (US); Koichi MATSUNO, Fremont, CA (US); Seyyed Ehsan Esfahani RASHIDI, San Jose, CA (US); Ehsan ESMAILI, San Jose, CA (US); Johann ALSMEIER, San Jose, CA (US)

(21) Appl. No.: 18/450,150

(22) Filed: Aug. 15, 2023

Related U.S. Application Data
(60) Provisional application No. 63/467,848, filed on May 19, 2023.

(51) Int. Cl. G11C 16/04; H01L 23/522; H01L 23/528; H10B 41/10; H10B 41/27; H10B 41/35; H10B 43/10; H10B 43/27; H10B 43/35

(52) U.S. Cl. CPC G11C 16/0483; H01L 23/5226; H01L 23/5283; H10B 41/10; H10B 41/27; H10B 41/35; H10B 43/10; H10B 43/27; H10B 43/35

(57) ABSTRACT

A three-dimensional memory device includes at least one alternating stack of insulating layers and electrically conductive layers, memory openings vertically extending through the at least one alternating stack, memory opening fill structures located in the memory openings, and a laterally-extending trench fill structure contacting a first lengthwise sidewall of the at least one alternating stack, and including a first-type dielectric bridge structure having a first volume, a second-type dielectric bridge structure having a second volume greater than the first volume, and a trench dielectric material portion.

### FIELD

The present disclosure relates generally to the field of semiconductor devices, and particularly to a three-dimensional memory device including trench bridge structures having different volumes and methods of forming the same.

### BACKGROUND

Three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a three-dimensional memory device comprises: at least one alternating stack of insulating layers and electrically conductive layers having a first lengthwise sidewall and a second lengthwise sidewall that laterally extend along a first horizontal direction; memory openings vertically extending through the at least one alternating stack; memory opening fill structures located in the memory openings, wherein each of the memory opening fill structures comprises a vertical semiconductor channel and a respective vertical stack of memory elements located at levels of the electrically conductive layers; and a first laterally-extending trench fill structure contacting the first lengthwise sidewall of the at least one alternating stack and comprising: a first-type dielectric bridge structure having a first volume; a second-type dielectric bridge structure having a second volume greater than the first volume; and a first trench dielectric material portion.

According to another aspect of the present disclosure, a three-dimensional memory device comprises: at least one alternating stack of insulating layers and electrically conductive layers having a first lengthwise sidewall and a second lengthwise sidewall that laterally extend along a first horizontal direction; memory openings vertically extending through the at least one alternating stack; memory opening fill structures located in the memory openings, wherein each of the memory opening fill structures comprises a vertical semiconductor channel and a respective vertical stack of memory elements located at levels of the electrically conductive layers; and a first laterally-extending trench fill structure contacting the first lengthwise sidewall of the at least one alternating stack and comprising: a first trench dielectric material portion; a plurality of the first-type dielectric bridge structures having the first volume and a first pitch; and a plurality of the second-type dielectric bridge structures having a second volume greater than the first volume, and a second pitch smaller than the first pitch.

According to another aspect of the present disclosure, a method of forming a three-dimensional memory device comprises: forming at least one vertically alternating sequence of insulating layers and sacrificial material layers over a substrate; forming memory openings through the at least one vertically alternating sequence; forming memory opening fill structures in the memory openings, wherein each of the memory opening fill structures comprises a vertical semiconductor channel and a respective vertical stack of memory elements; forming laterally-extending trenches through the at least one at least one vertically alternating sequence, the laterally-extending trenches comprising a first laterally-extending trench and a second laterally-extending trench; forming a first sacrificial laterally-extending trench fill structure and a second sacrificial laterally-extending trench fill structure in the first laterally-extending trench and the second laterally-extending trench, respectively; forming a first-type recess cavity having a first volume and a second-type recess cavity having a second volume by recessing portions of the first sacrificial laterally-extending trench fill structure, wherein the second volume is greater than the first volume; forming a first-type dielectric bridge structure and a second-type dielectric bridge structure in the first-type recess cavity and the second-type recess cavity, respectively; removing the first sacrificial laterally-extending trench fill structure and the second sacrificial laterally-extending trench fill structure; and replacing remaining portions of the sacrificial material layers with electrically conductive layers.

### BRIEF DESCRIPTION OF THE DRAWINGS

FIG. 1 is a plan view of a configuration of an exemplary semiconductor die including multiple three-dimensional memory array regions according to an embodiment of the present disclosure.

FIGS. 2A-2D are various views of an exemplary structure after formation of a first vertically alternating sequence of first-tier insulating layers and first-tier sacrificial material layers, first stepped surfaces, and first retro-stepped dielectric material portions according to an embodiment of the present disclosure. FIG. 2A is a top-down view. FIG. 2B is a vertical cross-sectional view along the vertical plane B-B′ of FIG. 2A. FIG. 2C is a vertical cross-sectional view along the vertical plane C-C′ of FIG. 2A. FIG. 2D is a vertical cross-sectional view along the vertical plane D-D′ of FIG. 2D.

FIGS. 3A-3E are various views of the exemplary structure after formation of first-tier sacrificial memory opening fill structures according to an embodiment of the present disclosure. FIG. 3A is a top-down view. FIG. 3B is a vertical cross-sectional view along the vertical plane B-B′ of FIG. 3A. FIG. 3C is a vertical cross-sectional view along the vertical plane C-C′ of FIG. 3A. FIG. 3D is a vertical cross-sectional view along the vertical plane D-D′ of FIG. 3D. FIG. 3E is a vertical cross-sectional view along the vertical plane E-E′ of FIG. 3E.

FIGS. 4A-4F are various views of the exemplary structure after formation of a second vertically alternating sequence of second-tier insulating layers and second-tier sacrificial material layers, second stepped surfaces, second retro-stepped dielectric material portions, and second-tier sacrificial memory opening fill structures according to an embodiment of the present disclosure. FIG. 4A is a top-down view. FIG. 4B is a vertical cross-sectional view along the vertical plane B-B′ of FIG. 4A. FIG. 4C is a vertical cross-sectional view along the vertical plane C-C′ of FIG. 4A. FIG. 4D is a vertical cross-sectional view along the vertical plane D-D′ of FIG. 4D. FIG. 4E is a vertical cross-sectional view along the vertical plane E-E′ of FIG. 4E. FIG. 4F is a vertical cross-sectional view along the vertical plane F-F′ of FIG. 4F.

FIGS. 5A-5F are various views of the exemplary structure after formation of a third vertically alternating sequence of third-tier insulating layers and third-tier sacrificial material layers, third stepped surfaces, third retro-stepped dielectric material portions, and third-tier memory opening according to an embodiment of the present disclosure. FIG. 5A is a top-down view. FIG. 5B is a vertical cross-sectional view along the vertical plane B-B′ of FIG. 5A. FIG. 5C is a vertical cross-sectional view along the vertical plane C-C′ of FIG. 5A. FIG. 5D is a vertical cross-sectional view along the vertical plane D-D′ of FIG. 5D.

FIG. 5E is a vertical cross-sectional view along the vertical plane E-E′ of FIG. 5E. FIG. 5F is a vertical cross-sectional view along the vertical plane F-F′ of FIG. 5F.

FIGS. 6A-6F are various views of the exemplary structure after formation of inter-tier memory openings according to an embodiment of the present disclosure. FIG. 6A is a top-down view. FIG. 6B is a vertical cross-sectional view along the vertical plane B-B′ of FIG. 6A. FIG. 6C is a vertical cross-sectional view along the vertical plane C-C′ of FIG. 6A. FIG. 6D is a vertical cross-sectional view along the vertical plane D-D′ of FIG. 6D.

FIG. 6E is a vertical cross-sectional view along the vertical plane E-E′ of FIG. 6E. FIG. 6F is a vertical cross-sectional view along the vertical plane F-F′ of FIG. 6F.

FIGS. 7A-7F illustrate sequential vertical cross-sectional views of a memory opening during formation of a memory opening fill structure according to an embodiment of the present disclosure.

FIGS. 8A-8F are various views of the exemplary structure after formation of memory opening fill structures according to an embodiment of the present disclosure. FIG. 8A is a top-down view. FIG. 8B is a vertical cross-sectional view along the vertical plane B-B′ of FIG. 8A. FIG. 8C is a vertical cross-sectional view along the vertical plane C-C′ of FIG. 8A. FIG. 8D is a vertical cross-sectional view along the vertical plane D-D′ of FIG. 8D. FIG. 8E is a vertical cross-sectional view along the vertical plane E-E′ of FIG. 8E. FIG. 8F is a vertical cross-sectional view along the vertical plane F-F′ of FIG. 8F.

FIGS. 9A-9H are various views of the exemplary structure after formation of laterally-extending trenches according to an embodiment of the present disclosure. FIG. 9A is a top-down view. FIG. 9B is a vertical cross-sectional view along the vertical plane B-B′ of FIG. 9A. FIG. 9C is a vertical cross-sectional view along the vertical plane C-C′ of FIG. 9A. FIG. 9D is a vertical cross-sectional view along the vertical plane D-D′ of FIG. 9D.

FIG. 9E is a vertical cross-sectional view along the vertical plane E-E′ of FIG. 9E. FIG. 9F is a vertical cross-sectional view along the vertical plane F-F′ of FIG. 9F. FIG. 9G is a vertical cross-sectional view along the vertical plane F-F′ of FIG. 9G. FIG. 9H is a vertical cross-sectional view along the vertical plane F-F′ of FIG. 9H.

FIGS. 10A-10H are various views of the exemplary structure after formation of sacrificial laterally-extending trench fill structures according to an embodiment of the present disclosure. FIG. 10A is a top-down view. FIG. 10B is a vertical cross-sectional view along the vertical plane B-B′ of FIG. 10A. FIG. 10C is a vertical cross-sectional view along the vertical plane C-C′ of FIG. 10A. FIG. 10D is a vertical cross-sectional view along the vertical plane D-D′ of FIG. 10D. FIG. 10E is a vertical cross-sectional view along the vertical plane E-E′ of FIG. 10E. FIG. 10F is a vertical cross-sectional view along the vertical plane F-F′ of FIG. 10F. FIG. 10G is a vertical cross-sectional view along the vertical plane F-F′ of FIG. 10G. FIG. 10H is a vertical cross-sectional view along the vertical plane F-F′ of FIG. 10H.

FIGS. 11A-11H are various views of the exemplary structure after formation of recess cavities in the sacrificial laterally-extending trench fill structures according to an embodiment of the present disclosure. FIG. 11A is a top-down view. FIG. 11B is a vertical cross-sectional view along the vertical plane B-B′ of FIG. 11A. FIG. 11C is a vertical cross-sectional view along the vertical plane C-C′ of FIG. 11A. FIG. 11D is a vertical cross-sectional view along the vertical plane D-D′ of FIG. 11D. FIG. 11E is a vertical cross-sectional view along the vertical plane E-E′ of FIG. 11E. FIG. 11F is a vertical cross-sectional view along the vertical plane F-F′ of FIG. 11F. FIG. 11G is a vertical cross-sectional view along the vertical plane F-F′ of FIG. 11G. FIG. 11H is a vertical cross-sectional view along the vertical plane F-F′ of FIG. 11H.

FIGS. 12A-12H are various views of the exemplary structure after vertical extension of second-type recess cavities according to an embodiment of the present disclosure. FIG. 12A is a top-down view. FIG. 12B is a vertical cross-sectional view along the vertical plane B-B′ of FIG. 12A. FIG. 12C is a vertical cross-sectional view along the vertical plane C-C′ of FIG. 12A. FIG. 12D is a vertical cross-sectional view along the vertical plane D-D′ of FIG. 12D. FIG. 12E is a vertical cross-sectional view along the vertical plane E-E′ of FIG. 12E. FIG. 12F is a vertical cross-sectional view along the vertical plane F-F′ of FIG. 12F. FIG. 12G is a vertical cross-sectional view along the vertical plane F-F′ of FIG. 12G. FIG. 12H is a vertical cross-sectional view along the vertical plane F-F′ of FIG. 12H.

FIGS. 13A-13H are various views of the exemplary structure after vertical extension of third-type recess cavities according to an embodiment of the present disclosure. FIG. 13A is a top-down view. FIG. 13B is a vertical cross-sectional view along the vertical plane B-B′ of FIG. 13A. FIG. 13C is a vertical cross-sectional view along the vertical plane C-C′ of FIG. 13A. FIG. 13D is a vertical cross-sectional view along the vertical plane D-D′ of FIG. 13D. FIG. 13E is a vertical cross-sectional view along the vertical plane E-E′ of FIG. 13E. FIG. 13F is a vertical cross-sectional view along the vertical plane F-F′ of FIG. 13F. FIG. 13G is a vertical cross-sectional view along the vertical plane F-F′ of FIG. 13G. FIG. 13H is a vertical cross-sectional view along the vertical plane F-F′ of FIG. 13H.

FIGS. 14A-14J are various views of the exemplary structure after formation of dielectric bridge structures according to an embodiment of the present disclosure. FIG. 14A is a top-down view. FIG. 14B is a vertical cross-sectional view along the vertical plane B-B′ of FIG. 14A. FIG. 14C is a vertical cross-sectional view along the vertical plane C-C′ of FIG. 14A. FIG. 14D is a vertical cross-sectional view along the vertical plane D-D′ of FIG. 14D. FIG. 14E is a vertical cross-sectional view along the vertical plane E-E′ of FIG. 14E. FIG. 14F is a vertical cross-sectional view along the vertical plane F-F′ of FIG. 14F. FIG. 14G is a vertical cross-sectional view along the vertical plane F-F′ of FIG. 14G. FIG. 14H is a vertical cross-sectional view along the vertical plane F-F′ of FIG. 14H. FIGS. 14I and 14J are top-down views of alternative embodiments of the exemplary structure.

FIGS. 15A-15H are various views of the exemplary structure after removal of sacrificial laterally-extending trench fill structures according to an embodiment of the present disclosure. FIG. 15A is a top-down view. FIG. 15B is a vertical cross-sectional view along the vertical plane B-B′ of FIG. 15A. FIG. 15C is a vertical cross-sectional view along the vertical plane C-C′ of FIG. 15A. FIG. 15D is a vertical cross-sectional view along the vertical plane D-D′ of FIG. 15D. FIG. 15E is a vertical cross-sectional view along the vertical plane E-E′ of FIG. 15E. FIG. 15F is a vertical cross-sectional view along the vertical plane F-F′ of FIG. 15F. FIG. 15G is a vertical cross-sectional view along the vertical plane F-F′ of FIG. 15G. FIG. 15H is a vertical cross-sectional view along the vertical plane F-F′ of FIG. 15H.

FIGS. 16A-16H are various views of the exemplary structure after formation of lateral recesses according to an embodiment of the present disclosure. FIG. 16A is a top-down view. FIG. 16B is a vertical cross-sectional view along the vertical plane B-B′ of FIG. 16A. FIG. 16C is a vertical cross-sectional view along the vertical plane C-C′ of FIG. 16A. FIG. 16D is a vertical cross-sectional view along the vertical plane D-D′ of FIG. 16D. FIG. 16E is a vertical cross-sectional view along the vertical plane E-E′ of FIG. 16E. FIG. 16F is a vertical cross-sectional view along the vertical plane F-F′ of FIG. 16F. FIG. 16G is a vertical cross-sectional view along the vertical plane F-F′ of FIG. 16G. FIG. 16H is a vertical cross-sectional view along the vertical plane F-F′ of FIG. 16H.

FIGS. 17A-17H are various views of the exemplary structure after formation of electrically conductive layers according to an embodiment of the present disclosure. FIG. 17A is a top-down view. FIG. 17B is a vertical cross-sectional view along the vertical plane B-B′ of FIG. 17A. FIG. 17C is a vertical cross-sectional view along the vertical plane C-C′ of FIG. 17A. FIG. 17D is a vertical cross-sectional view along the vertical plane D-D′ of FIG. 17D. FIG. 17E is a vertical cross-sectional view along the vertical plane E-E′ of FIG. 17E. FIG. 17F is a vertical cross-sectional view along the vertical plane F-F′ of FIG. 17F. FIG. 17G is a vertical cross-sectional view along the vertical plane F-F′ of FIG. 17G. FIG. 17H is a vertical cross-sectional view along the vertical plane F-F′ of FIG. 17H.

FIGS. 18A-18H are various views of the exemplary structure after formation of laterally-extending trench fill structures according to an embodiment of the present disclosure. FIG. 18A is a top-down view. FIG. 18B is a vertical cross-sectional view along the vertical plane B-B′ of FIG. 18A. FIG. 18C is a vertical cross-sectional view along the vertical plane C-C′ of FIG. 18A. FIG. 18D is a vertical cross-sectional view along the vertical plane D-D′ of FIG. 18D. FIG. 18E is a vertical cross-sectional view along the vertical plane E-E′ of FIG. 18E. FIG. 18F is a vertical cross-sectional view along the vertical plane F-F′ of FIG. 18F. FIG. 18G is a vertical cross-sectional view along the vertical plane F-F′ of FIG. 18G. FIG. 18H is a vertical cross-sectional view along the vertical plane F-F′ of FIG. 18H.

FIGS. 19A-19H are various views of the exemplary structure after formation of various contact via structures according to an embodiment of the present disclosure. FIG. 19A is a top-down view. FIG. 19B is a vertical cross-sectional view along the vertical plane B-B′ of FIG. 19A. FIG. 19C is a vertical cross-sectional view along the vertical plane C-C′ of FIG. 19A. FIG. 19D is a vertical cross-sectional view along the vertical plane D-D′ of FIG. 19D. FIG. 19E is a vertical cross-sectional view along the vertical plane E-E′ of FIG. 19E. FIG. 19F is a vertical cross-sectional view along the vertical plane F-F′ of FIG. 19F. FIG. 19G is a vertical cross-sectional view along the vertical plane F-F′ of FIG. 19G. FIG. 19H is a vertical cross-sectional view along the vertical plane F-F′ of FIG. 19H.

FIG. 20 is a vertical cross-sectional view of the exemplary structure after formation of a memory die and attachment of a logic die to the memory die according to an embodiment of the present disclosure.

FIG. 21 is a vertical cross-sectional view of a first alternative configuration of the exemplary structure according to an embodiment of the present disclosure.

FIG. 22 is a vertical cross-sectional view of a second alternative configuration of the exemplary structure according to an embodiment of the present disclosure.

FIG. 23 is a vertical cross-sectional view of a second alternative configuration of the exemplary structure according to an embodiment of the present disclosure.

### DETAILED DESCRIPTION

As discussed above, the present disclosure is directed to a three-dimensional memory device including trench bridge structures having different volumes (e.g., different thicknesses, lengths and/or widths) and/or different pitches (i.e., the bridge length and space between bridges) in different regions and methods of forming the same, the various aspects of which are described below. The embodiments of the disclosure can be employed to form three-dimensional memory array devices comprising a plurality of NAND memory strings.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an element is “electrically connected to” a second element if there exists a conductive path consisting of at least one conductive material between the element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

Generally, a semiconductor die, or a semiconductor package, can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which are the smallest unit that can be erased in a single erase operation. Each block contains a number of pages, which are the smallest unit that can be programmed, i.e., a smallest unit on which a read operation can be performed.

As used herein, a “semiconducting material” refers to a material having electrical conductivity in the range from 1.0×10⁻⁵ S/m to 1.0×10⁵ S/m. As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

According to an aspect of the present disclosure, dielectric bridge structures having different vertical extents are provided in laterally-extending trenches to provide enhanced structural support to stacks of insulating layers and memory opening fill structures during replacement of sacrificial material layers with electrically conductive layers.

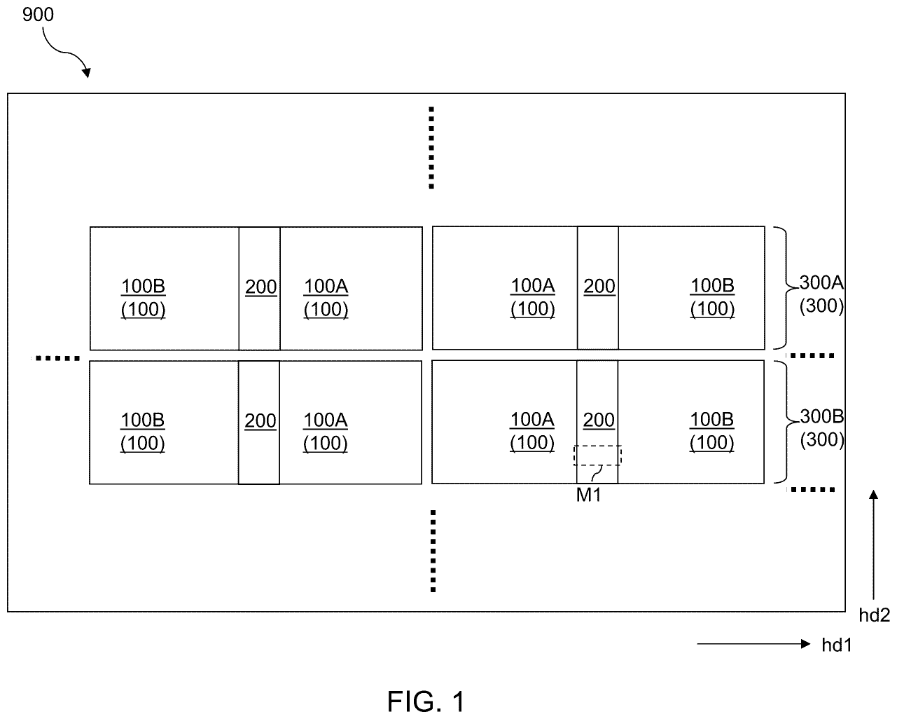

Referring to FIG. 1, an exemplary semiconductor die according to an embodiment of the present disclosure is illustrated, which may be a memory die 900. The memory dic 900 includes multiple three-dimensional memory array regions and multiple inter-array regions. The memory die 900 can include multiple planes 300 (e.g., 300A, 300B), each of which includes two memory array regions 100, such as a first memory array region 100A and a second memory array region 100B that are laterally spaced apart by a respective contact region 200. Generally, the memory die 900 may include a single plane 300 or multiple planes. The total number of planes in the memory die 900 may be selected based on performance requirements on the memory die 900. A pair of memory array regions 100 in a plane 300 may be laterally spaced apart along a first horizontal direction hd1 (which may be the word line direction) by a contact region 200. A second horizontal direction hd2 (which may be the bit line direction) can be perpendicular to the first horizontal direction hd1.

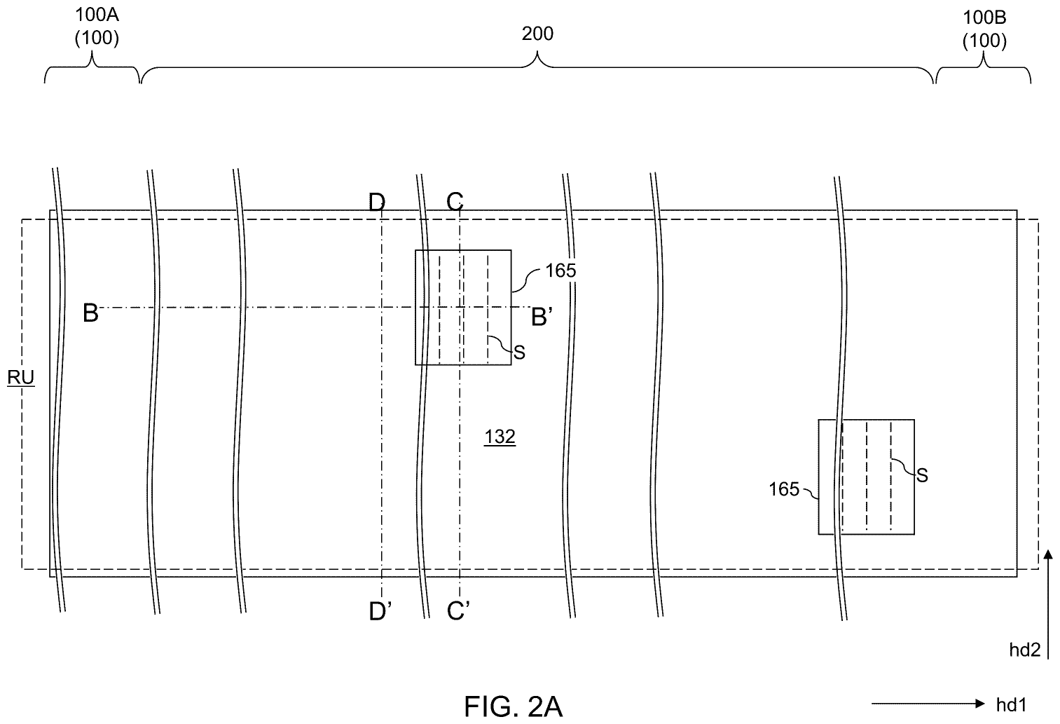

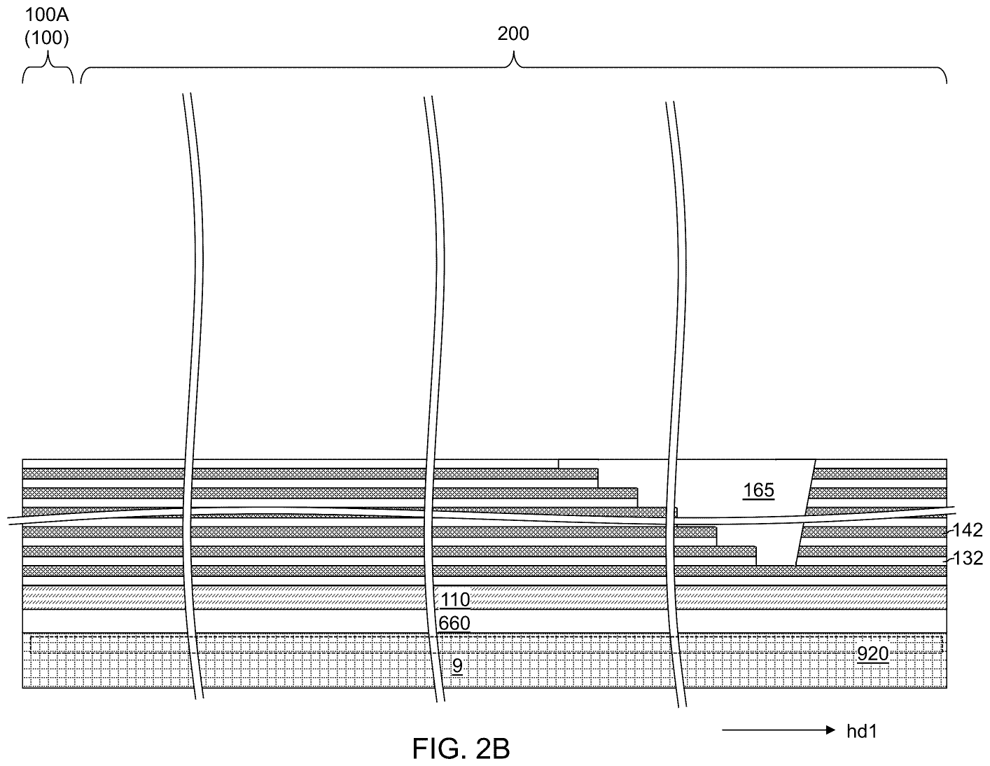

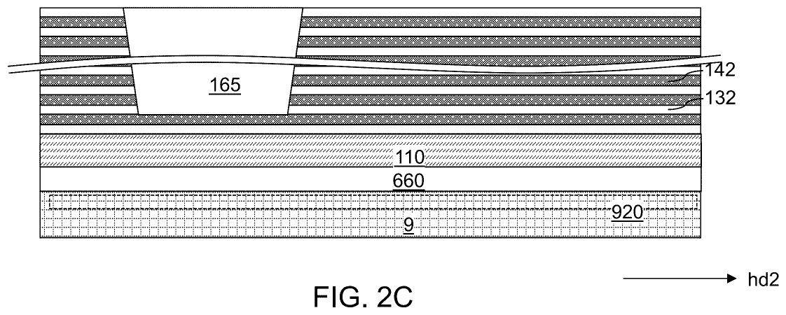

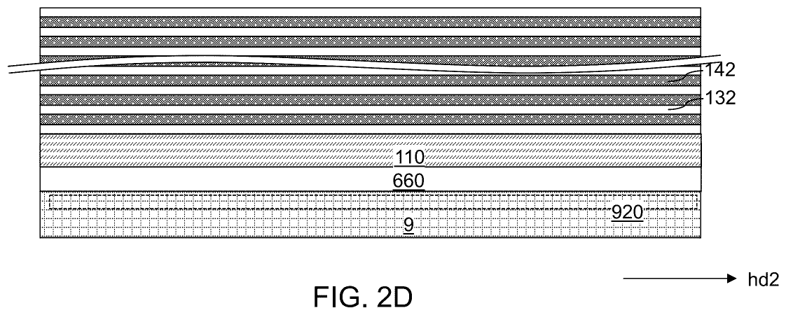

Referring to FIGS. 2A-2D, an exemplary structure for forming the memory die 900 of FIG. 1 is illustrated at an initial stage of a manufacturing process. The illustrated region of FIGS. 2A-2D corresponds to region M1 in FIG. 1. i.e., a portion of a contact region 200 and two peripheral portions of memory array regions 100.

The exemplary structure can include a substrate 9, and optionally at least one lower-level dielectric material layer 660 and a semiconductor material layer 110. The substrate 9 may be incorporated into the final device structure, or may be a carrier substrate that is subsequently removed. In case the substrate 9 is incorporated into the final device structure, the substrate 9 may comprise a single crystalline silicon substrate. In this case, optional semiconductor devices, such as field effect transistors and passive devices may be formed on the top surface of the substrate 9. The semiconductor devices may be employed as a first peripheral circuit that controls operation of a three-dimensional memory device to be subsequently formed. Alternatively, the substrate 9 may be a carrier substrate that is subsequently removed. In one embodiment, the substrate may comprise a commercially available silicon substrate. An optional peripheral circuit 920 may be located on the substrate 9 and may comprise word line switch devices configured to control a bias voltage to respective word lines, and/or bit line driver devices, such as sense amplifiers.

At least one lower-level dielectric material layer 660 may be optionally formed over the substrate 9. In case semiconductor devices are formed on the top surface of the substrate 9, lower-level metal interconnect structures, such as metal via structures and metal line structures, can be formed in the at least one lower-level dielectric material layer 660. While an embodiment is described in which lower-level metal interconnect structures are formed in the at least one lower-level dielectric material layer 660, alternative embodiments are expressly contemplated in which lower-level metal interconnect structures are not formed in the at least one lower-level dielectric material layer 660.

A semiconductor material layer 110 may be optionally formed over the at least one lower-level dielectric material layer 660. The semiconductor material layer 110 may comprise a single crystalline or polycrystalline semiconductor material, such as single crystalline silicon or polysilicon. In one embodiment, the semiconductor material layer 110 may include source-level material layers or in-process source-level material layers that are provided with, or are at least partly replaced with, a source contact layer. Alternatively, the semiconductor material layer 110 may be employed at least partly as a horizontal channel layer. Yet alternatively, the semiconductor material layer 110 may be omitted or subsequently removed. Generally speaking, various configurations may be employed for the combination of the substrate 9, the at least one lower-level dielectric material layer 660, and the at least one optional semiconductor material layer 110, and each component of the combination may become a permanent component of a final device structure, or may be removed from the final device structure.

A first vertically alternating sequence, i.e., a first alternating stack, of first insulating layers 132 and first sacrificial material layers 142 can be formed over the substrate 9 (e.g., over the semiconductor material layer 110 if present). As used herein, a “vertically alternating sequence,” or an “alternating stack,” refers to a sequence of multiple instances of a first element and multiple instances of a second element that is arranged such that an instance of a second element is located between each vertically neighboring pair of instances of the first element, and an instance of a first element is located between each vertically neighboring pair of instances of the second element.

The first insulating layers 132 can be composed of the first material, and the first sacrificial material layers 142 can be composed of the second material, which is different from the first material. Each of the first insulating layers 132 is an insulating layer that continuously extends over the entire area of the substrate 9, and may have a uniform thickness throughout. Each of the first sacrificial material layers 142 includes is a sacrificial material layer that includes a dielectric material and continuously extends over the entire area of the substrate 9, and may have a uniform thickness throughout. Insulating materials that may be used for the first insulating layers 132 include, but are not limited to silicon oxide (including doped or undoped silicate glass), silicon nitride, silicon oxynitride, organosilicate glass (OSG), spin-on dielectric materials, dielectric metal oxides that are commonly known as high dielectric constant (high-k) dielectric oxides (e.g., aluminum oxide, hafnium oxide, etc.) and silicates thereof, dielectric metal oxynitrides and silicates thereof, and organic insulating materials. In one embodiment, the first material of the first insulating layers 132 may be silicon oxide.

The second material of the first sacrificial material layers 142 is a sacrificial material that may be removed selective to the first material of the first insulating layers 132. As used herein, a removal of a first material is “selective to” a second material if the removal process removes the first material at a rate that is at least twice the rate of removal of the second material. The ratio of the rate of removal of the first material to the rate of removal of the second material is herein referred to as a “selectivity” of the removal process for the first material with respect to the second material.

The second material of the first sacrificial material layers 142 may be subsequently replaced with electrically conductive electrodes which may function, for example, as control gate electrodes of a vertical NAND device. In one embodiment, the first sacrificial material layers 142 may be material layers that comprise silicon nitride. The first vertically alternating sequence of the first insulating layers 132 and the first sacrificial material layers 142 is employed to form a first-tier structure, and may also be referred to as a first-tier vertically alternating sequence (132, 142).

Staircases containing first stepped surfaces “S” can be formed within the staircase regions of the contact region 200 which will be filled with the first-tier retro-stepped dielectric material portions 165. For example, a combination of a sacrificial hard mask layer and a trimming mask layer may be employed to form the first stepped surfaces. In one embodiment, a row of multiple first staircase regions can be formed within each area that corresponds to a combination of the area of a laterally-neighboring pair of first-tier retro-stepped dielectric material portions 165 and an intervening area. In this case, the multiple first staircase regions can be subsequently vertically offset by different depths by subsequently performing area recess etch processes.

In an illustrative example, 2^{M} sets of first stepped surfaces can be formed within a combination of the area of a laterally-neighboring pair of first-tier retro-stepped dielectric material portions 165 and an intervening area. M can be an integer in a range from 1 to 8. Each set of first stepped staircases may include P steps such that sidewalls of P first continuous spacer material layers are physically exposed with lateral offsets. P may be an integer from 2 to 64. M area recess etch processes can be performed such that each area recess etch process vertically recesses P times 21 sets of a first insulating layer 132 and a first sacrificial material layer 142, in which i is a different integer from 0 to (M-1). A total of up to 2^{M} x P stepped surfaces can be formed for the first vertically alternating sequence of the first insulating layers 132 and the first sacrificial material layers 142. The total number of the stepped surfaces within each continuous cavity overlying the first stepped surfaces can be the same as the total number of the first sacrificial material layers 142 in the first vertically alternating sequence (132, 142). Alternative processing sequences for forming first stepped surfaces in first areas may also be employed.

A first dielectric fill material (such as undoped silicate glass (i.e., silicon oxide) or a doped silicate glass) can be deposited in each first continuous retro-stepped cavity. The first dielectric fill material can be planarized to remove excess portions of the first dielectric fill material from above the horizontal plane including the topmost surface of the first vertically alternating sequence (132, 142). Each remaining portion of the first dielectric fill material that fills a respective first continuous retro-stepped cavity constitutes a first-tier retro-stepped dielectric material portion 165. Generally, the first-tier retro-stepped dielectric material portions 165 can be formed in contact regions 200 located between a respective first memory array region 100A and a respective second memory array region 100B that are laterally spaced apart along the first horizontal direction hd1. The first stepped surfaces contact stepped bottom surfaces of a respective first retro-stepped dielectric material portion 165.

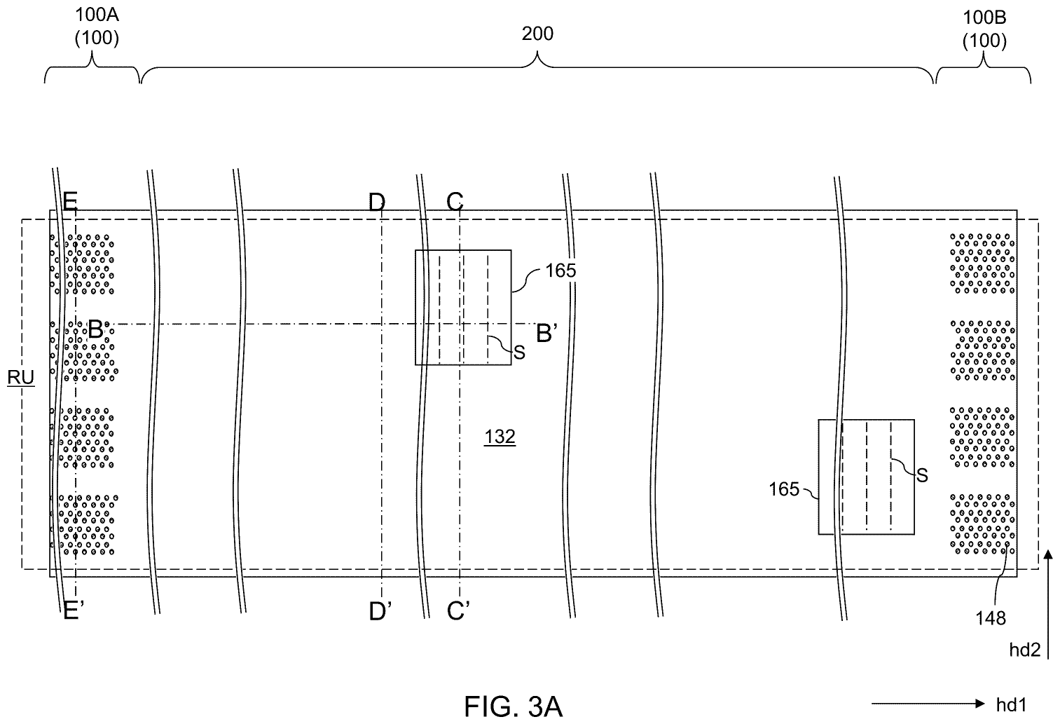

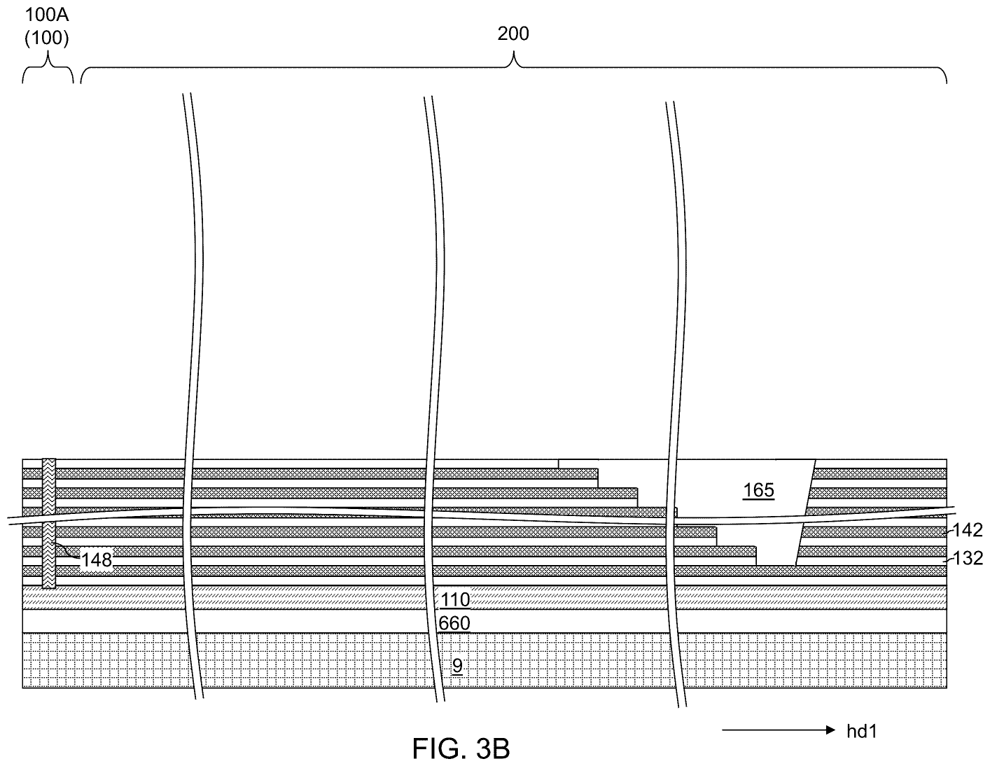

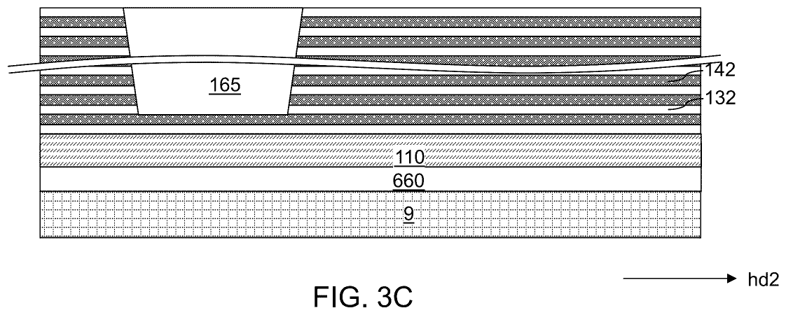

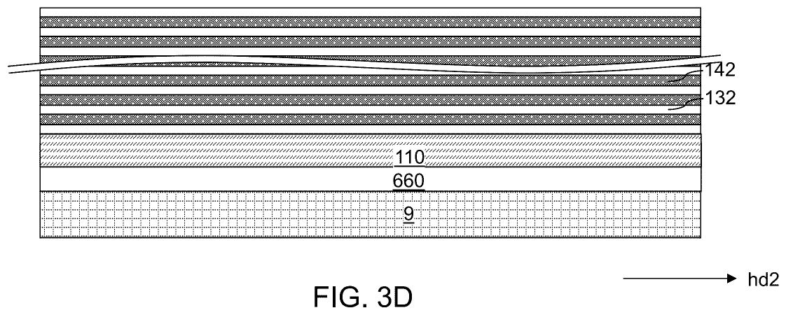

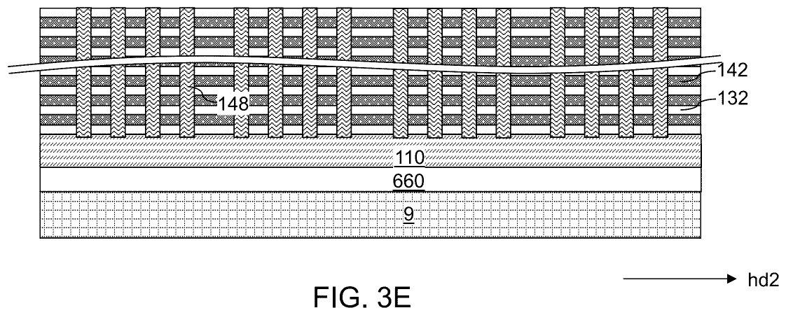

Referring to FIGS. 3A-3E, various first-tier openings may be formed through the first vertically alternating sequence (132, 142) and into the semiconductor material layer 110. The optional peripheral circuit 920 not shown in these figures and subsequent figures for simplicity. A photoresist layer (not shown) may be applied over the first vertically alternating sequence (132, 142), and may be lithographically patterned to form various openings therethrough. The pattern of openings in the photoresist layer may be transferred through the first vertically alternating sequence (132, 142) and into the semiconductor material layer 110 by a first anisotropic etch process to form the various first-tier openings concurrently, i.e., during the first isotropic etch process. The various first-tier openings may include first-tier memory openings formed in the memory array regions 100 and first-tier support openings formed in the contact region 200. The first-tier support openings are not illustrated for simplicity. Each cluster of first-tier memory openings may be formed as a two-dimensional array of first-tier memory openings. The first-tier support openings are openings that are formed in the contact region 200, and are subsequently employed to form support pillar structures. A subset of the first-tier support openings may be formed through a respective horizontal surface of the first stepped surfaces.

Sacrificial first-tier opening fill portions may be formed in the various first-tier openings. For example, a sacrificial first-tier fill material is deposited concurrently deposited in each of the first-tier openings. The sacrificial first-tier fill material includes a material that may be subsequently removed selective to the materials of the first insulating layers 132 and the first sacrificial material layers 142. In one embodiment, the sacrificial first-tier fill material may include a semiconductor material such as silicon (e.g., a-Si or polysilicon), a silicon-germanium alloy, germanium, a III-V compound semiconductor material, or a combination thereof. Optionally, a thin etch stop liner (such as a silicon oxide layer or a silicon nitride layer having a thickness in a range from 1 nm to 3 nm) may be used prior to depositing the sacrificial first-tier fill material. The sacrificial first-tier fill material may be formed by a non-conformal deposition or a conformal deposition method.

In another embodiment, the sacrificial first-tier fill material may include a silicon oxide material having a higher etch rate than the materials of the first insulating layers 132. For example, the sacrificial first-tier fill material may include borosilicate glass or porous or non-porous organosilicate glass having an etch rate that is at least 100 times higher than the etch rate of densified TEOS oxide (i.e., a silicon oxide material formed by decomposition of tetraethylorthosilicate glass in a chemical vapor deposition process and subsequently densified in an anneal process) in a 100:1 dilute hydrofluoric acid. In this case, a thin etch stop liner (such as a silicon nitride layer having a thickness in a range from 1 nm to 3 nm) may be used prior to depositing the sacrificial first-tier fill material. The sacrificial first-tier fill material may be formed by a non-conformal deposition or a conformal deposition method.

In yet another embodiment, the sacrificial first-tier fill material may include carbon-containing material (such as amorphous carbon or diamond-like carbon) that may be subsequently removed by ashing, or a silicon-based polymer that may be subsequently removed selective to the materials of the first vertically alternating sequence (132, 142). Portions of the deposited sacrificial first-tier fill material may be removed from above the topmost layer of the first vertically alternating sequence (132, 142), such as from above the topmost first insulating layer 132. For example, the sacrificial first-tier fill material may be recessed to a top surface of the topmost first insulating layer 132 using a planarization process. The planarization process may include a recess etch, chemical mechanical planarization (CMP), or a combination thereof. The top surface of the topmost first insulating layer 132 may be used as an etch stop layer or a planarization stop layer.

Remaining portions of the sacrificial first-tier fill material comprise sacrificial first-tier opening fill portions. Specifically, each remaining portion of the sacrificial first-tier fill material in a first-tier memory opening constitutes a sacrificial first-tier memory opening fill portion 148. Each remaining portion of the sacrificial first-tier fill material in a first-tier support opening constitutes a sacrificial first-tier support opening fill portion (not illustrated). The various sacrificial first-tier opening fill portions are concurrently formed, i.e., during a same set of processes including the deposition process that deposits the sacrificial first-tier fill material and the planarization process that removes the first-tier deposition process from above the first vertically alternating sequence (132, 142) (such as from above the top surface of the topmost first insulating layer 132). The top surfaces of the sacrificial first-tier opening fill portions may be coplanar with the top surface of the topmost first insulating layer 132. Each of the sacrificial first-tier opening fill portions may, or may not, include cavities therein. The set of all structures located between the bottommost surface of the first vertically alternating sequence (132, 142) and the topmost surface of the first vertically alternating sequence (132, 142) or embedded within the first vertically alternating sequence (132, 142) constitutes a first-tier structure.

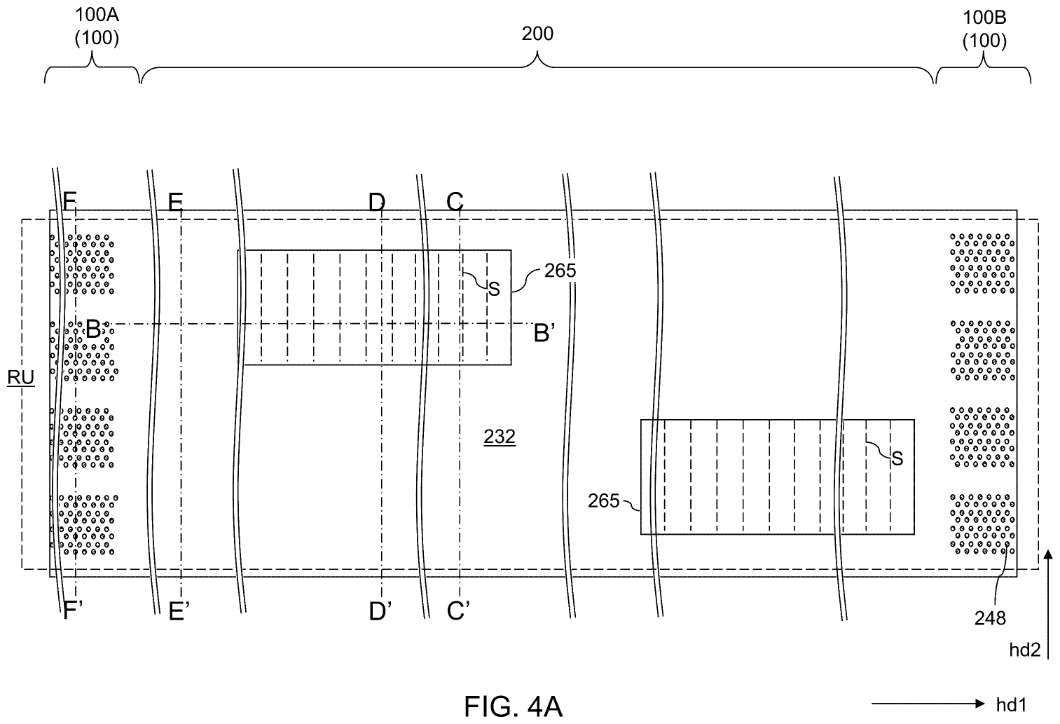

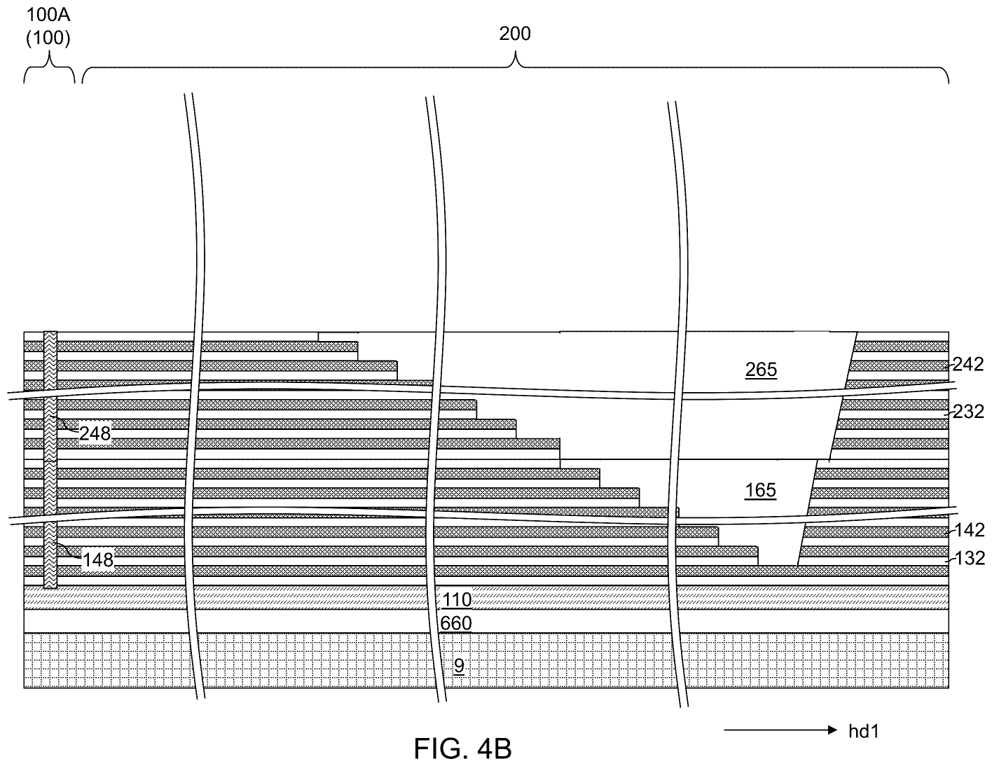

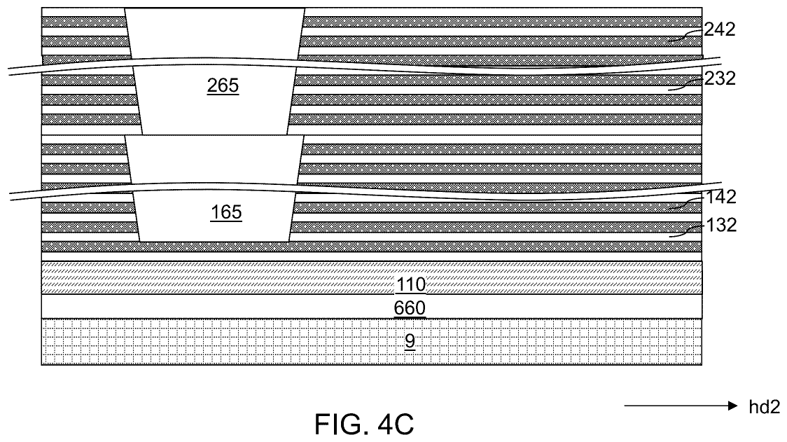

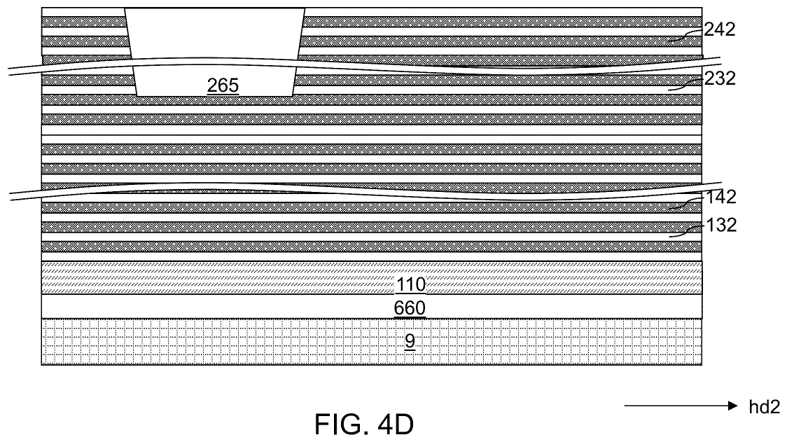

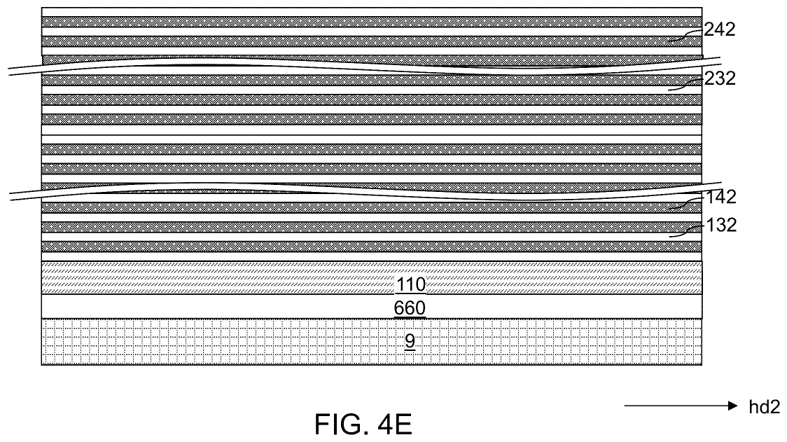

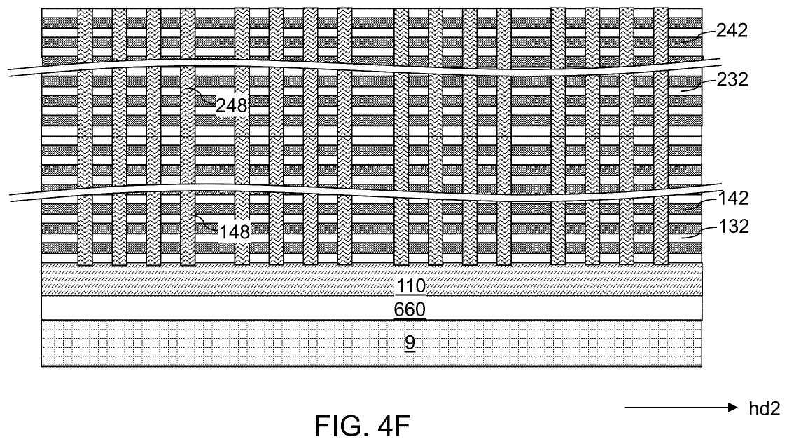

Referring to FIGS. 4A-4F, a second vertically alternating sequence of second insulating layers 232 and second sacrificial material layers 242 can be formed. Each of the second insulating layers 232 is an insulating layer that continuously extends over the entire area of the substrate 9, and may have a uniform thickness throughout. Each of the second sacrificial material layers 242 includes a sacrificial material, and continuously extends over the entire area of the substrate 9, and may have a uniform thickness throughout. The second insulating layers 232 can have the same material composition and the same thickness as the first insulating layers 132. The second sacrificial material layers 242 can have the same material composition and the same thickness as the first sacrificial material layers 142.

Generally, at least one additional vertically alternating sequence of additional insulating layers and additional sacrificial material layers can be optionally formed over the first vertically alternating sequence (132, 142) and the first-tier retro-stepped dielectric material portions 165.

Second stepped surfaces can be formed within the staircase regions of the contact region 200 which will be filled with the second-tier retro-stepped dielectric material portions 265. For example, a combination of a sacrificial hard mask layer and a trimming mask layer may be employed to form the second stepped surfaces. In one embodiment, a row of multiple second staircase regions can be formed within each area that corresponds to a combination of the area of a laterally-neighboring pair of second-tier retro-stepped dielectric material portions 265 and an intervening area. In this case, the multiple second staircase regions can be subsequently vertically offset by different depths by subsequently performing area recess etch processes. The second stepped surfaces may be formed employing a set of processing steps that is similar to a set of processing steps for forming the first stepped surfaces. The second stepped surfaces can be laterally offset from the first stepped surfaces. The total number of the stepped surfaces within each continuous cavity overlying the second stepped surfaces can be the same as the total number of the second sacrificial material layers 242 in the second vertically alternating sequence (232, 242).

A second dielectric fill material (such as undoped silicate glass (i.e., silicon oxide) or a doped silicate glass) can be deposited in each second continuous retro-stepped cavity. The second dielectric fill material can be planarized to remove excess portions of the second dielectric fill material from above the horizontal plane including the topmost surface of the second vertically alternating sequence (232, 242). Each remaining portion of the second dielectric fill material that fills a respective second continuous retro-stepped cavity constitutes a second-tier retro-stepped dielectric material portion 265. The second stepped surfaces contact stepped bottom surfaces of a respective second retro-stepped dielectric material portion 265.

Generally, a second-tier structure is formed, which comprises a second vertically alternating sequence of second insulating layers 232 and second sacrificial material layers 242 and second-tier retro-stepped dielectric material portions 265 overlying second stepped surfaces of the second vertically alternating sequence that are located in the contact regions 200.

Various second-tier openings may be formed through the second vertically alternating sequence (232, 242) and over the sacrificial first-tier opening fill portions. A photoresist layer (not shown) may be applied over the second vertically alternating sequence (232, 242), and may be lithographically patterned to form various openings therethrough. The pattern of openings in the photoresist layer may be transferred through the second vertically alternating sequence (232, 242) to form the various second-tier openings concurrently, i.e., during the second isotropic etch process.

The various second-tier openings may include second-tier memory openings formed in the memory array regions 100 and second-tier support openings (not illustrated) formed in the contact region 200. Each second-tier opening may be formed within the area of a respective one of the sacrificial first-tier opening fill portions. Thus, a top surface of a sacrificial first-tier opening fill portion can be physically exposed at the bottom of each second-tier opening. Specifically, each second-tier memory openings can be formed directly over a respective sacrificial first-tier memory opening fill portion 148, and each second-tier support opening (not illustrated) can be formed directly over a respective sacrificial first-tier support opening fill portion (not illustrated). Each cluster of second-tier memory openings may be formed as a two-dimensional array of second-tier memory openings. The second-tier support openings are openings that are formed in the contact region 200, and are subsequently employed to form support pillar structures. A subset of the second-tier support openings may be formed through a respective horizontal surface of the second stepped surfaces.

Sacrificial second-tier opening fill portions may be formed in the various second-tier openings. For example, a sacrificial first-tier fill material is deposited concurrently deposited in each of the second-tier openings. The sacrificial second-tier fill material can include any material that may be employed for the sacrificial first-tier fill material. Portions of the deposited sacrificial second-tier fill material may be removed from above the topmost layer of the second vertically alternating sequence (232, 242). Remaining portions of the sacrificial second-tier fill material comprise sacrificial second-tier opening fill portions. Specifically, each remaining portion of the sacrificial second-tier fill material in a second-tier memory opening constitutes a sacrificial second-tier memory opening fill portion 248. Each remaining portion of the sacrificial second-tier fill material in a first-tier support opening constitutes a sacrificial second-tier support opening fill portion (not illustrated). The top surfaces of the sacrificial second-tier opening fill portions may be coplanar with the top surface of the topmost second insulating layer 232. Each of the sacrificial second-tier opening fill portions may, or may not, include cavities therein. The set of all structures located between the bottommost surface of the second vertically alternating sequence (232, 242) and the topmost surface of the second vertically alternating sequence (232, 242) or embedded within the second vertically alternating sequence (232, 242) constitutes a second-tier structure.

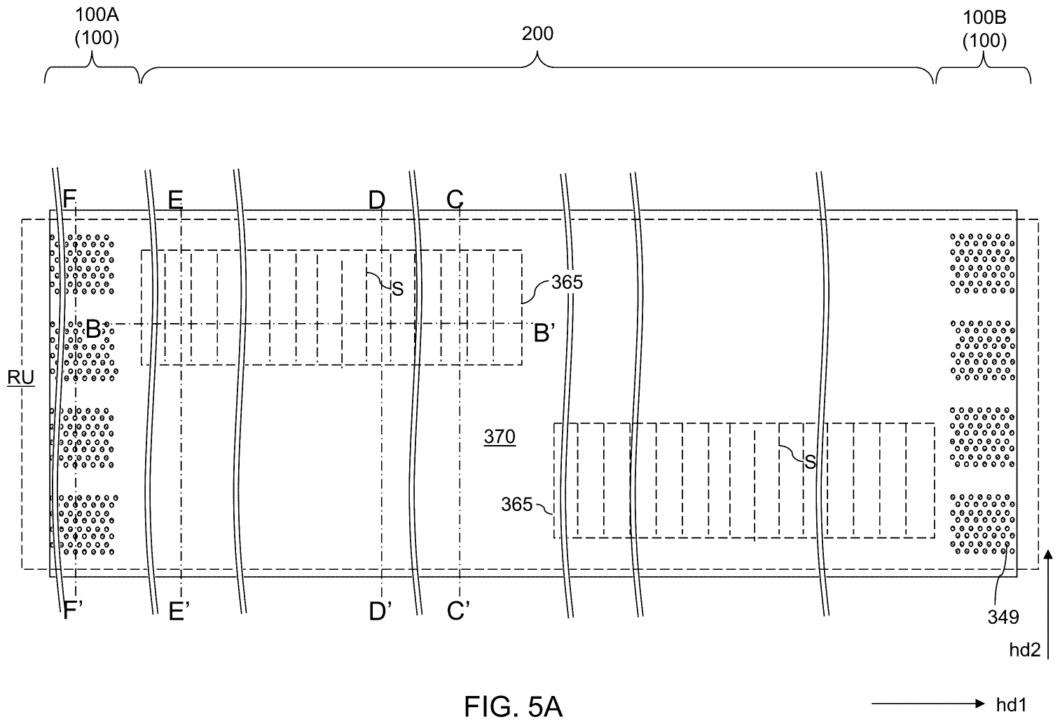

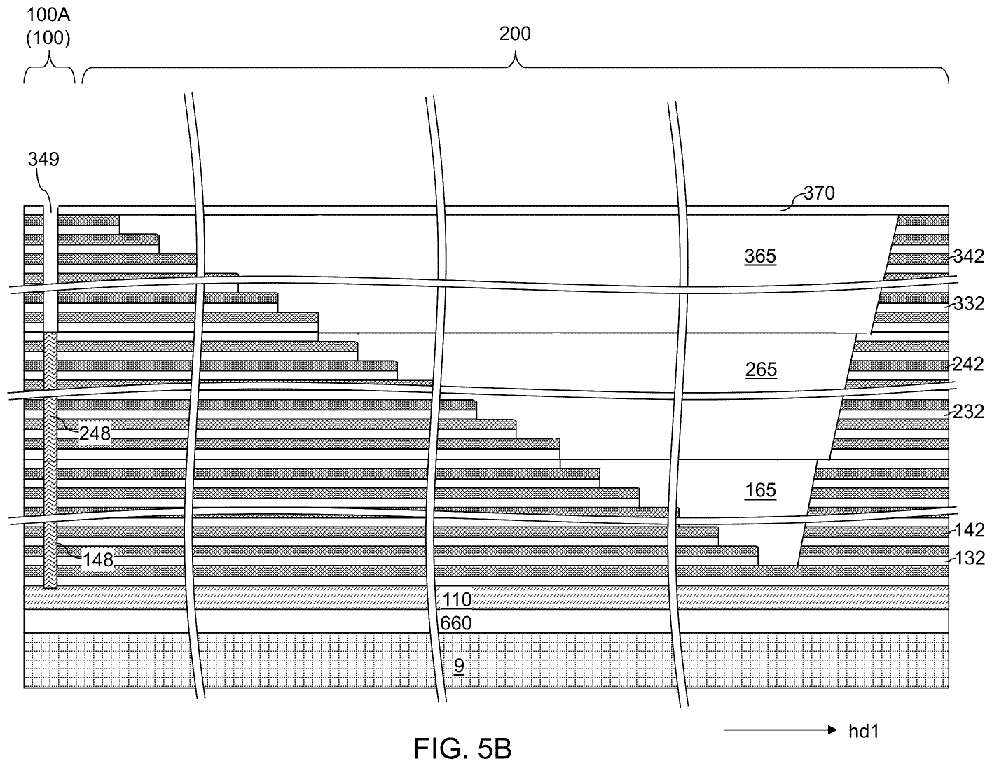

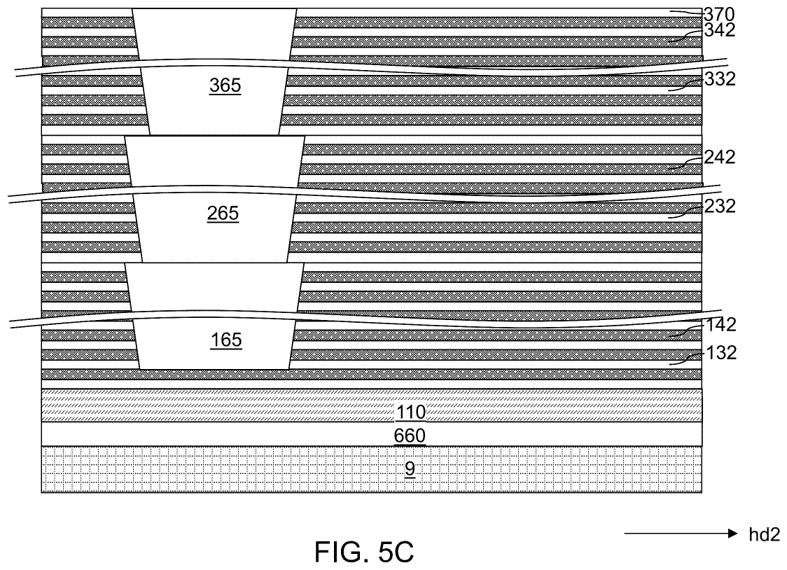

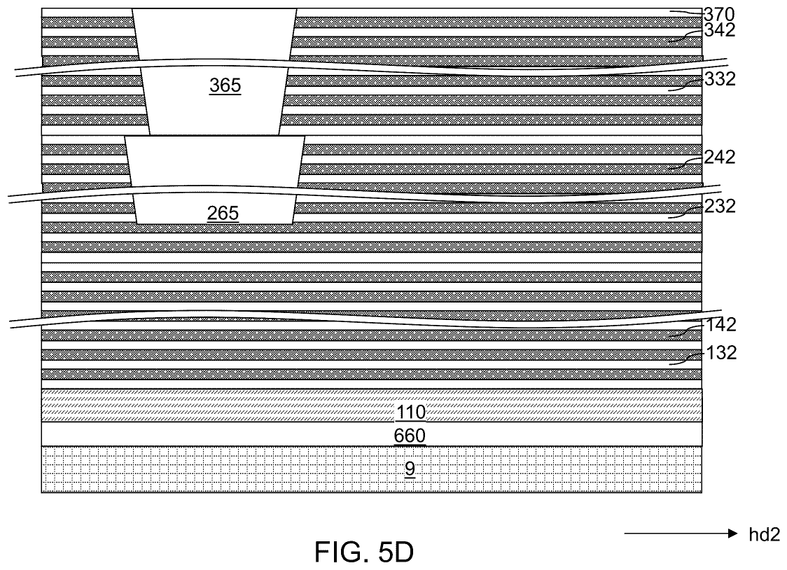

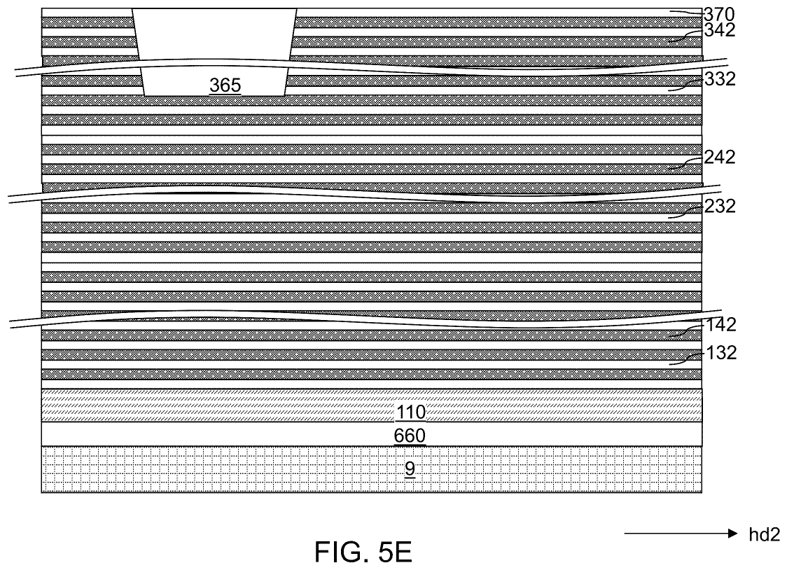

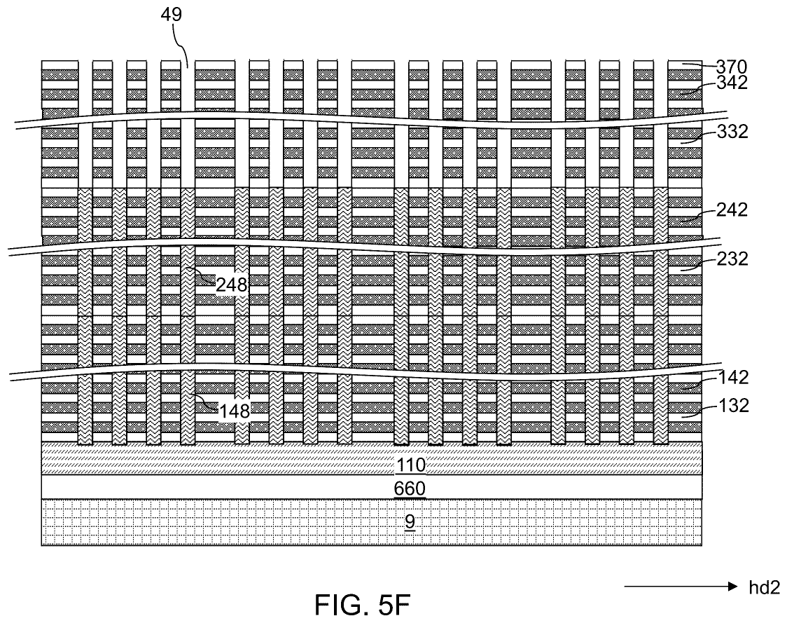

Referring to FIGS. 5A-5F, a third vertically alternating sequence of third insulating layers 332 and third sacrificial material layers 342 can be formed. Each of the third insulating layers 332 is an insulating layer that continuously extends over the entire area of the substrate 9, and may have a uniform thickness throughout. Each of the third sacrificial material layers 342 includes a sacrificial material, and continuously extends over the entire area of the substrate 9, and may have a uniform thickness throughout. The third insulating layers 332 can have the same material composition and the same thickness as the first insulating layers 132. The third sacrificial material layers 342 can have the same material composition and the same thickness as the first sacrificial material layers 142.

Third stepped surfaces can be formed within the staircase regions of the contact region 200 which will be filled with the third-tier retro-stepped dielectric material portions 365. For example, a combination of a sacrificial hard mask layer and a trimming mask layer may be employed to form the third stepped surfaces. The third stepped surfaces can be laterally offset from the first stepped surfaces and the second stepped surfaces. Cavities can be formed above each area of the first stepped surfaces and the second stepped surfaces. It should be noted that the staircase directions can be reversed, with the lower part of the staircase on the left side and the upper part of the staircase on the right side of FIG. 5B.

In one embodiment, the staircase directions are symmetrical across a plane extending in the second horizontal direction (e.g., bit line direction hd2). Thus, if the first staircase adjacent to first memory array region 100A has the lower portion on one side (e.g., on the right side along the first horizontal direction (e.g., word line direction) hd1), then the second staircase adjacent to the second memory array region 100B has the lower portion on the opposite side as the first staircase region (e.g., on the left side along the first horizontal direction hd1).

A third dielectric fill material (such as undoped silicate glass (i.e., silicon oxide) or a doped silicate glass) can be deposited in each third continuous retro-stepped cavity. The third dielectric fill material can be planarized to remove excess portions of the third dielectric fill material from above the horizontal plane including the topmost surface of the third vertically alternating sequence (332, 342). Each remaining portion of the third dielectric fill material that fills a respective third continuous retro-stepped cavity constitutes a third-tier retro-stepped dielectric material portion 365. The third stepped surfaces contact stepped bottom surfaces of a respective third retro-stepped dielectric material portion 365.

Generally, a third-tier structure is formed, which comprises a third vertically alternating sequence of third insulating layers 332 and third sacrificial material layers 342 and third-tier retro-stepped dielectric material portions 365 overlying third stepped surfaces of the third vertically alternating sequence that are located in the contact regions 200.

An insulating cap layer 370 may be formed over the third vertically alternating sequence and the third retro-stepped dielectric material portions 365. The insulating cap layer 370 comprises an insulating material such as silicon oxide, and may have a thickness in a range from 20 nm to 100 nm, although lesser and greater thicknesses may also be employed.

Various third-tier openings may be formed through the insulating cap layer 370 and the third vertically alternating sequence (332, 342) in areas of the sacrificial second-tier opening fill portions. For example, a photoresist layer (not shown) may be applied over the insulating cap layer 370, and may be lithographically patterned to form various openings therethrough. The pattern of openings in the photoresist layer may be transferred through the third vertically alternating sequence (332, 342) to form the various third-tier openings concurrently, i.e., during the third isotropic etch process.

The various third-tier openings may include third-tier memory openings formed in the memory array regions 100 and third-tier support openings (not illustrated) formed in the contact region 200. Each third-tier opening may be formed within the area of a respective one of the sacrificial second-tier opening fill portions. Thus, a top surface of a sacrificial second-tier opening fill portion can be physically exposed at the bottom of each third-tier opening. Specifically, each third-tier memory openings 349 can be formed directly over a respective sacrificial second-tier memory opening fill portion 248, and each third-tier support opening (not illustrated) can be formed directly over a respective sacrificial second-tier support opening fill portion (not illustrated). Each cluster of third-tier memory openings 349 may be formed as a two-dimensional array of third-tier memory openings 349. The third-tier support openings (not shown) are openings that are formed in the contact region 200, and are subsequently employed to form support pillar structures. A subset of the third-tier support openings may be formed through a respective horizontal surface of the third stepped surfaces.

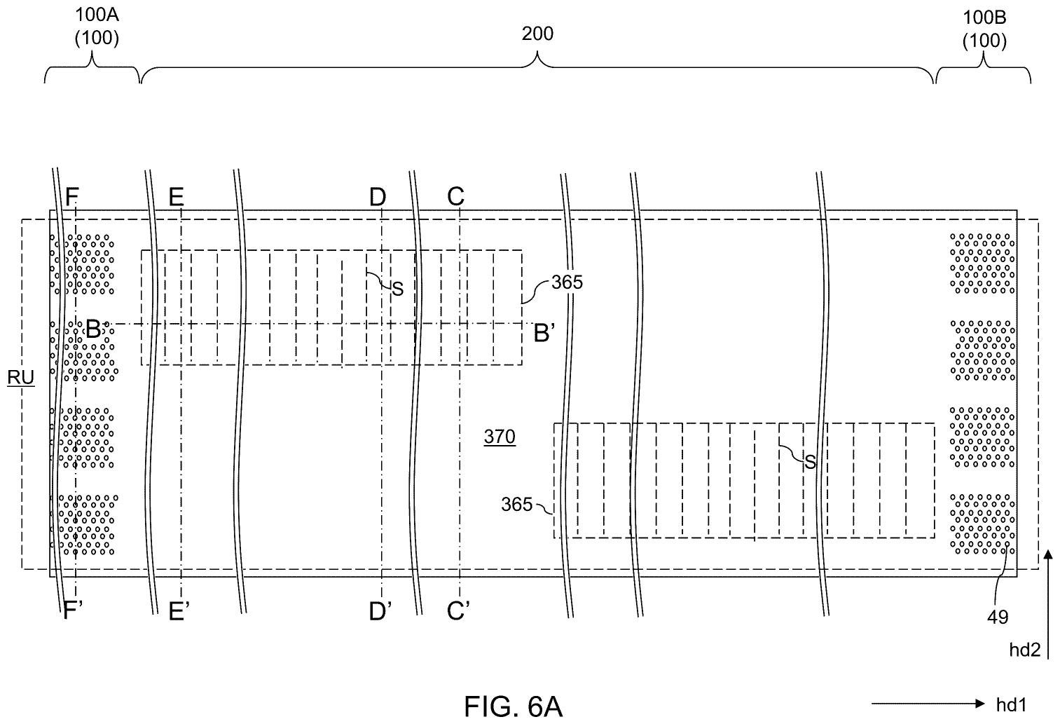

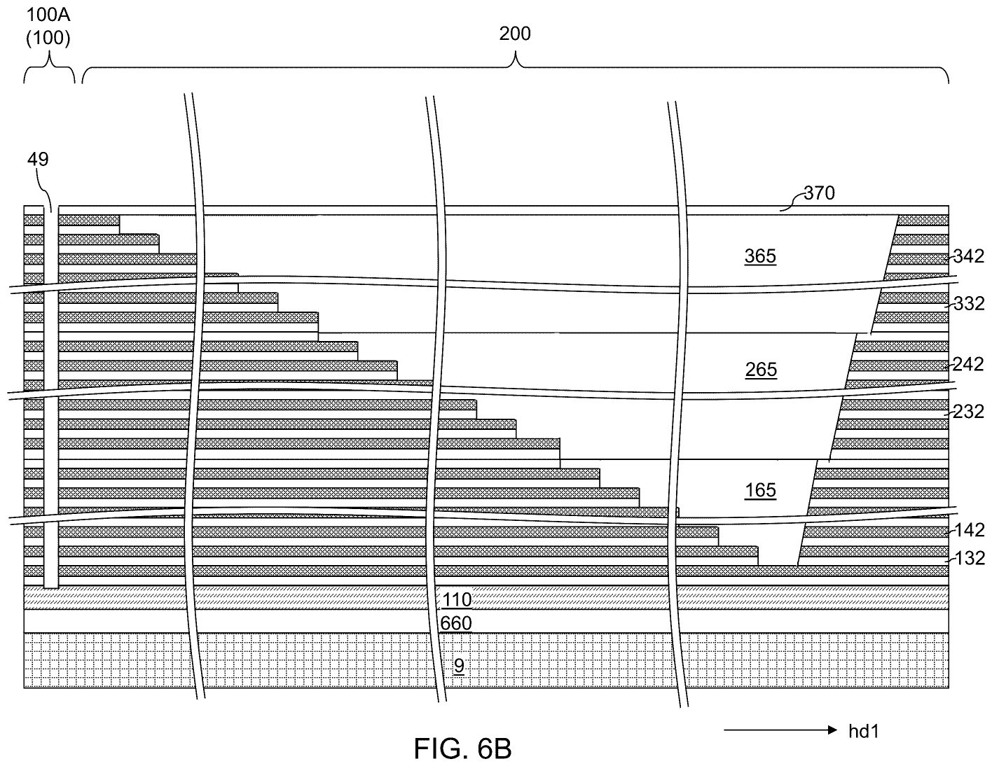

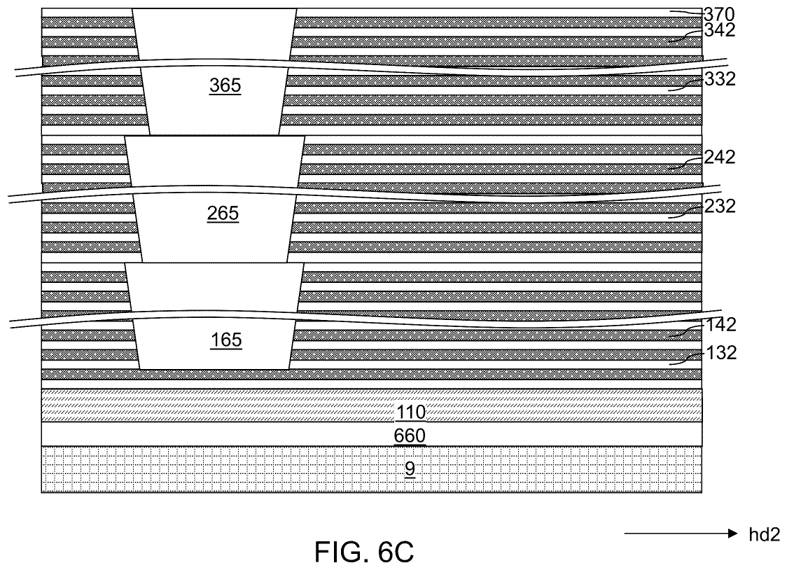

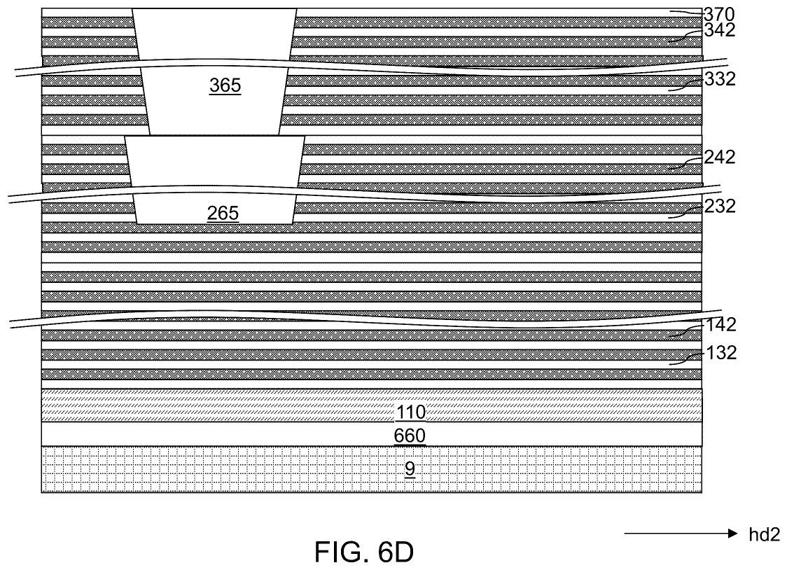

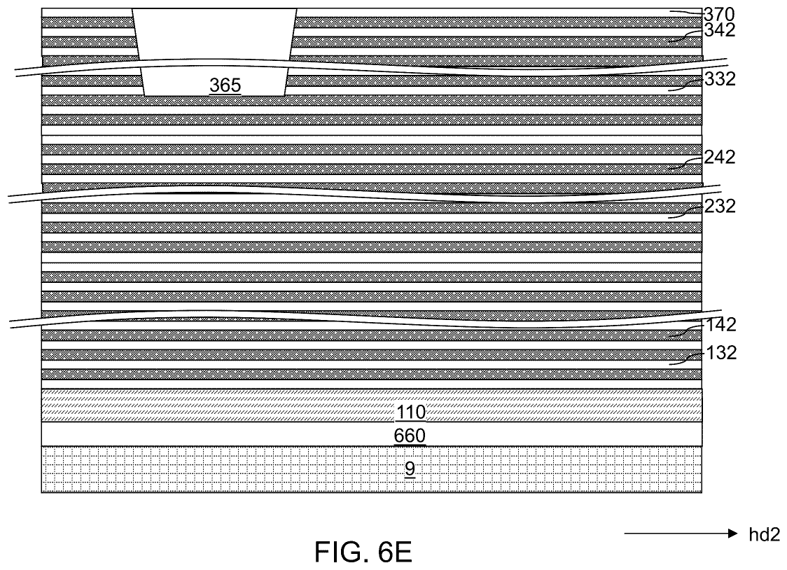

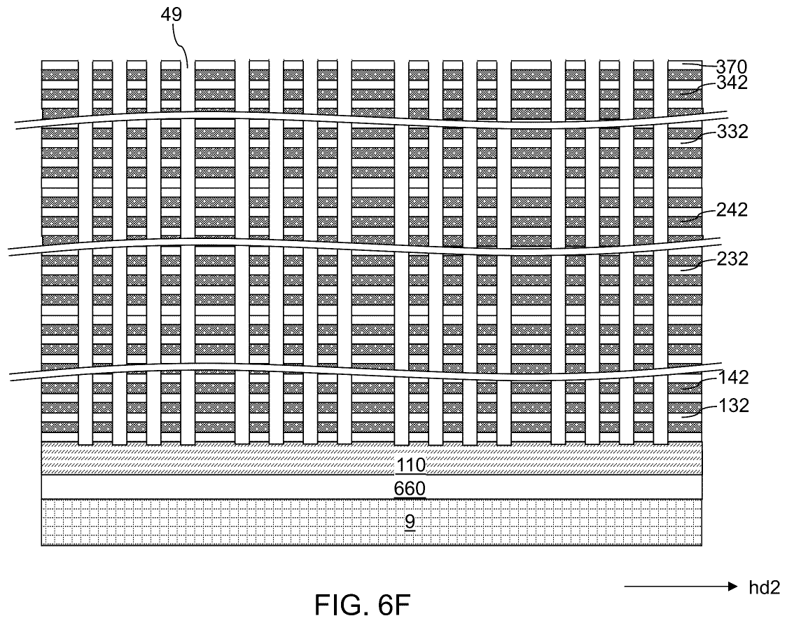

Referring to FIGS. 6A-6F, the sacrificial second-tier fill material of the sacrificial second-tier opening fill portions 248 and the sacrificial first-tier fill material of the sacrificial first-tier opening fill portions 148 may be removed using an etch process that etches the sacrificial second-tier fill material and the sacrificial first-tier fill material selective to the materials of the insulating layers (132, 232, 332) and the sacrificial material layers (142, 242, 342). A memory opening, which is also referred to as an inter-tier memory opening 49, is formed in each combination of a third-tier memory openings 349 and volumes from which a sacrificial second-tier memory opening fill portions 248 and a sacrificial first-tier memory opening fill portion 148 are removed. A support opening (not illustrated), which is also referred to as an inter-tier support opening, is formed in each combination of a third-tier support openings and volumes from which a sacrificial second-tier support opening fill portion and a sacrificial first-tier support opening fill portion are removed. The inter-tier memory opening 49 extends through the third-tier structure, the second-tier structure, and the first-tier structure. Generally, memory openings 49 can be formed within each memory array region 100, in which each layer of the first vertically alternating sequence (132, 142), the second vertically alternating sequence (232, 242), and the third vertically alternating sequence (332, 342) is present.

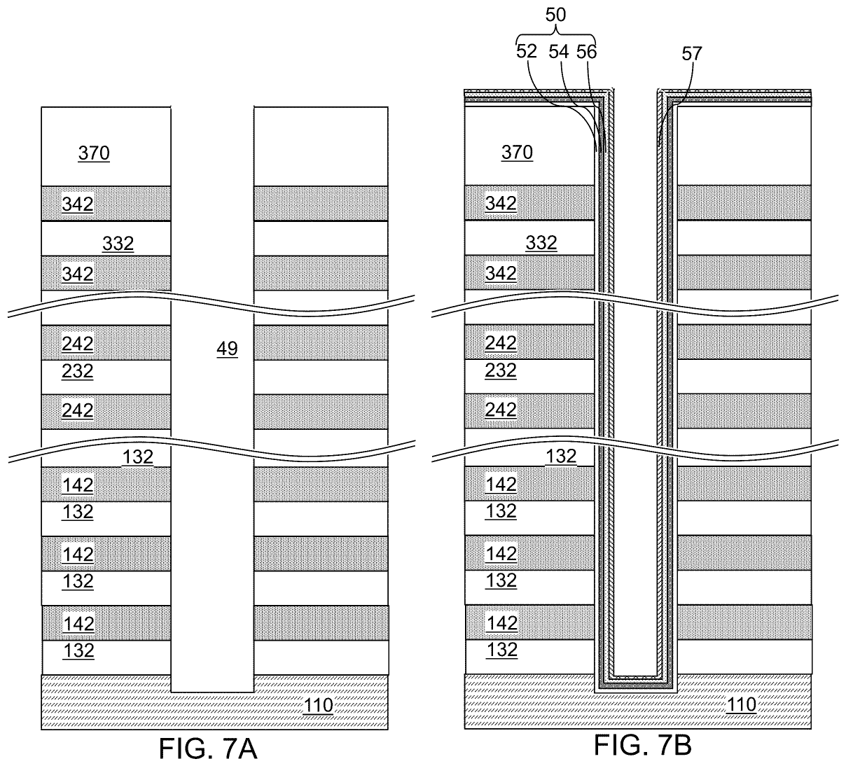

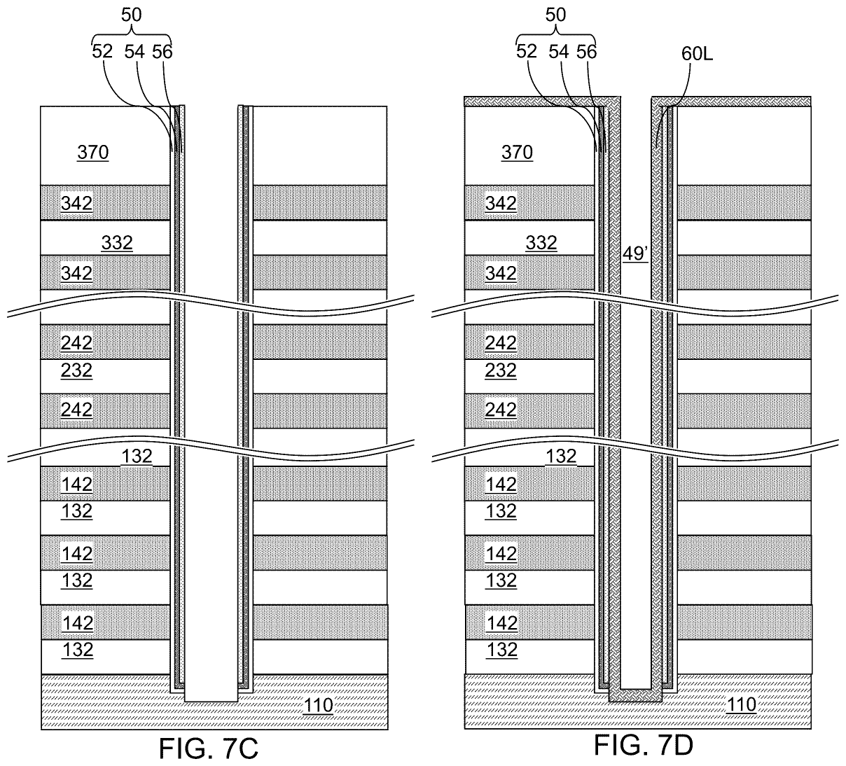

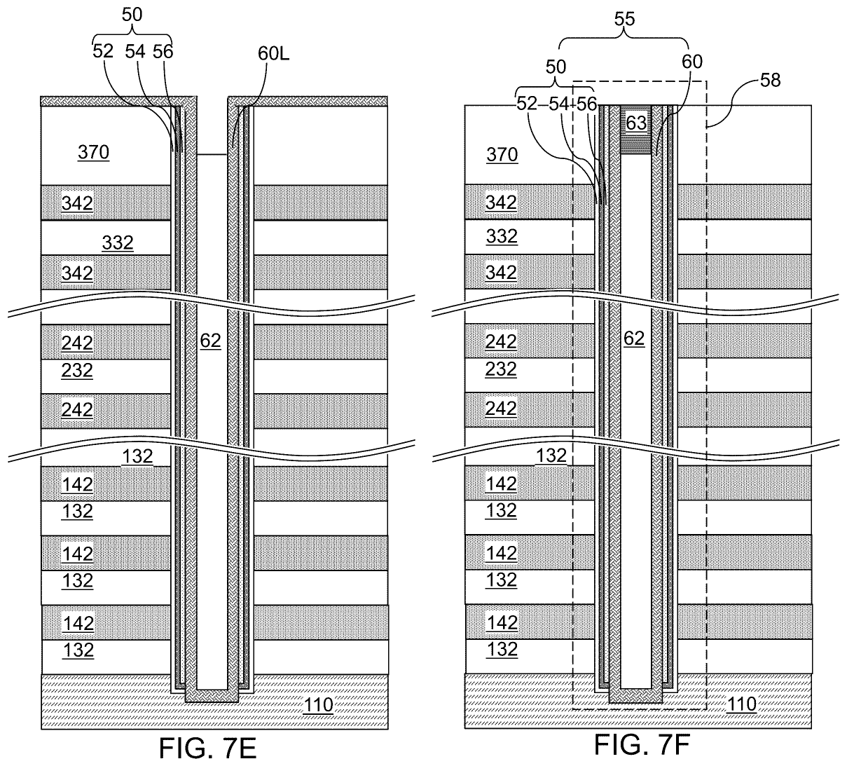

FIGS. 7A-7E illustrate sequential vertical cross-sectional views of a memory opening 49 during formation of a memory opening fill structure 58 according to an embodiment of the present disclosure.

Referring to FIG. 7A, the inter-tier memory opening 49 at the processing steps of FIG. 6C is illustrated.

Referring to FIG. 7B, a stack of layers including a blocking dielectric layer 52, a charge storage layer 54, a tunneling dielectric layer 56, and an optional sacrificial cover layer 57 may be sequentially deposited in the inter-tier memory openings 49. The blocking dielectric layer 52 may include a single dielectric material layer or a stack of a plurality of dielectric material layers. In one embodiment, the blocking dielectric layer may include a dielectric metal oxide layer consisting essentially of a dielectric metal oxide. As used herein, a dielectric metal oxide refers to a dielectric material that includes at least one metallic element and at least oxygen. The dielectric metal oxide may consist essentially of the at least one metallic element and oxygen, or may consist essentially of the at least one metallic element, oxygen, and at least one non-metallic element such as nitrogen. In one embodiment, the blocking dielectric layer 52 may include a dielectric metal oxide having a dielectric constant greater than 7.9. i.e., having a dielectric constant greater than the dielectric constant of silicon nitride. The thickness of the dielectric metal oxide layer may be in a range from 1 nm to 20 nm, although lesser and greater thicknesses may also be used. The dielectric metal oxide layer may subsequently function as a dielectric material portion that blocks leakage of stored electrical charges to control gate electrodes. In one embodiment, the blocking dielectric layer 52 includes aluminum oxide. Alternatively or additionally, the blocking dielectric layer 52 may include a dielectric semiconductor compound such as silicon oxide, silicon oxynitride, silicon nitride, or a combination thereof.

Subsequently, the charge storage layer 54 may be formed. In one embodiment, the charge storage layer 54 may be a continuous layer or patterned discrete portions of a charge trapping material including a dielectric charge trapping material, which may be, for example, silicon nitride. Alternatively, the charge storage layer 54 may include a continuous layer or patterned discrete portions of a conductive material such as doped polysilicon or a metallic material that is patterned into multiple electrically isolated portions (e.g., floating gates), for example, by being formed within lateral recesses into sacrificial material layers (142, 242, 342). In one embodiment, the charge storage layer 54 includes a silicon nitride layer. In one embodiment, the sacrificial material layers (142, 242, 342) and the insulating layers (132, 232, 332) may have vertically coincident sidewalls, and the charge storage layer 54 may be formed as a single continuous layer. Alternatively, the sacrificial material layers (142, 242, 342) may be laterally recessed with respect to the sidewalls of the insulating layers (132, 232, 332), and a combination of a deposition process and an anisotropic etch process may be used to form the charge storage layer 54 as a plurality of memory material portions that are vertically spaced apart. The thickness of the charge storage layer 54 may be in a range from 2 nm to 20 nm, although lesser and greater thicknesses may also be used.

The tunneling dielectric layer 56 includes a dielectric material through which charge tunneling may be performed under suitable electrical bias conditions. The charge tunneling may be performed through hot-carrier injection or by Fowler-Nordheim tunneling induced charge transfer depending on the mode of operation of the monolithic three-dimensional NAND string memory device to be formed. The tunneling dielectric layer 56 may include silicon oxide, silicon nitride, silicon oxynitride, dielectric metal oxides (such as aluminum oxide and hafnium oxide), dielectric metal oxynitride, dielectric metal silicates, alloys thereof, and/or combinations thereof. In one embodiment, the tunneling dielectric layer 56 may include a stack of a first silicon oxide layer, a silicon oxynitride layer, and a second silicon oxide layer, which is commonly known as an ONO stack. In one embodiment, the tunneling dielectric layer 56 may include a silicon oxide layer that is substantially free of carbon or a silicon oxynitride layer that is substantially free of carbon. The thickness of the tunneling dielectric layer 56 may be in a range from 2 nm to 20 nm, although lesser and greater thicknesses may also be used. The stack of the blocking dielectric layer 52, the charge storage layer 54, and the tunneling dielectric layer 56 constitutes a memory film 50 that stores memory bits.

The sacrificial cover layer 57 may comprise a sacrificial material that may be subsequently removed selective to the material of the tunneling dielectric layer 56. For example, the sacrificial cover layer may comprise a semiconductor material (e.g., amorphous silicon), silicon oxide, or a carbon-based material (such as amorphous carbon or diamond-like carbon). The thickness of the sacrificial cover layer may be in a range from 1 nm to 10 nm, although lesser and greater thicknesses may also be employed.

Referring to FIG. 7C, an anisotropic etch process may be performed to remove horizontal portions of the sacrificial cover layer 57, the tunneling dielectric layer 56, the charge storage layer 54, and the blocking dielectric layer 52. Remaining cylindrical portions of the sacrificial cover layer 57 may be removed selective to the material of the tunneling dielectric layer 56 during the anisotropic etch process, or by an isotropic etch process (such as a wet etch process) or by ashing. Alternatively, if the sacrificial cover layer 57 comprises a semiconductor material (e.g., amorphous silicon), then it may be retained. In alternative embodiments, the anisotropic etch process may be omitted. In these alternative embodiments, a horizontal source contact (e.g., discrete strap contact) may be formed in contact with a side of the vertical semiconductor channel or the substrate 9 may be removed and a top source contact may be formed in contact with the exposed end portion of the vertical semiconductor channel.

Referring to FIG. 7D, a semiconductor channel material layer 60L can be deposited by a conformal deposition process. The semiconductor channel material layer 60L includes an intrinsic or doped semiconductor material such as at least one elemental semiconductor material, at least one III-V compound semiconductor material, at least one II-VI compound semiconductor material, at least one organic semiconductor material, or other semiconductor materials known in the art. In one embodiment, the semiconductor channel material layer 60L may have a uniform doping. In one embodiment, the semiconductor channel material layer 60L has a p-type doping in which p-type dopants (such as boron atoms) are present at an atomic concentration in a range from 1.0×10¹²/cm³ to 1.0×10¹⁸/cm³, such as from 1.0×10¹⁴/cm³ to 1.0×10¹⁷/cm³. In one embodiment, the semiconductor channel material layer 60L includes, and/or consists essentially of, boron-doped amorphous silicon or boron-doped polysilicon. In another embodiment, the semiconductor channel material layer 60L has an n-type doping in which n-type dopants (such as phosphor atoms or arsenic atoms) are present at an atomic concentration in a range from 1.0×10¹²/cm³ to 1.0×10¹⁸/cm³, such as from 1.0×10¹⁴/cm³ to 1.0×10¹⁷/cm³. The semiconductor channel material layer 60L may be formed by a conformal deposition method such as low pressure chemical vapor deposition (LPCVD). The thickness of the semiconductor channel material layer 60L may be in a range from 2 nm to 10 nm, although lesser and greater thicknesses may also be used. A cavity 49′ is formed in the volume of each inter-tier memory opening 49 that is not filled with the deposited material layers (52, 54, 56, 60L).

Referring to FIG. 7E, in case the cavity 49′ in each memory opening is not completely filled by the semiconductor channel material layer 60L, a dielectric core layer may be deposited in the cavity 49′ to fill any remaining portion of the cavity 49′ within each memory opening. The dielectric core layer includes a dielectric material such as silicon oxide or organosilicate glass. The dielectric core layer may be deposited by a conformal deposition method such as low pressure chemical vapor deposition (LPCVD), or by a self-planarizing deposition process such as spin coating. The horizontal portion of the dielectric core layer overlying the semiconductor channel material layer 60L on the top may be removed, for example, by a recess etch. The recess etch continues until top surfaces of the remaining portions of the dielectric core layer are recessed to a height between the top and bottom surfaces of the insulating cap layer 370. Each remaining portion of the dielectric core layer constitutes a dielectric core 62.

Referring to FIG. 7F, a doped semiconductor material having a doping of a second conductivity type may be deposited in cavities overlying the dielectric cores 62. The second conductivity type is the opposite of the first conductivity type. For example, if the first conductivity type is p-type, the second conductivity type is n-type, and vice versa. Portions of the deposited doped semiconductor material, the semiconductor channel material layer 60L, the tunneling dielectric layer 56, the charge storage layer 54, and the blocking dielectric layer 52 that overlie the horizontal plane including the top surface of the insulating cap layer 370 may be removed by a planarization process such as a chemical mechanical planarization (CMP) process.

Each remaining portion of the doped semiconductor material of the second conductivity type constitutes a drain region 63. The dopant concentration in the drain regions 63 may be in a range from 5.0×10¹⁸/cm³ to 2.0×10²¹/cm³, although lesser and greater dopant concentrations may also be used. The doped semiconductor material may be, for example, doped polysilicon.

Each remaining portion of the semiconductor channel material layer 60L constitutes a vertical semiconductor channel 60 through which electrical current may flow when a vertical NAND device including the vertical semiconductor channel 60 is turned on. A tunneling dielectric layer 56 is surrounded by a charge storage layer 54, and laterally surrounds a vertical semiconductor channel 60. Each adjoining set of a blocking dielectric layer 52, a charge storage layer 54, and a tunneling dielectric layer 56 collectively constitute a memory film 50, which may store electrical charges with a macroscopic retention time. In some embodiments, a blocking dielectric layer 52 may not be present in the memory film 50 at this step, and a blocking dielectric layer may be subsequently formed after formation of lateral recesses. As used herein, a macroscopic retention time refers to a retention time suitable for operation of a memory device as a permanent memory device such as a retention time in excess of 24 hours.

Each combination of a memory film 50 and a vertical semiconductor channel 60 (which is a vertical semiconductor channel) within an inter-tier memory opening 49 constitutes a memory stack structure 55. The memory stack structure 55 is a combination of a vertical semiconductor channel 60, a tunneling dielectric layer 56, a plurality of memory elements comprising portions of the charge storage layer 54, and an optional blocking dielectric layer 52. The memory stack structures 55 can be formed through memory array regions 100 of the first and second vertically alternating sequences in which all layers of the first and second vertically alternating sequences are present. Each combination of a memory stack structure 55, a dielectric core 62, and a drain region 63 within an inter-tier memory opening 49 constitutes a memory opening fill structure 58. Generally, memory opening fill structures 58 are formed within the memory openings 49. Each of the memory opening fill structures 58 comprises a respective memory film 50 and a respective vertical semiconductor channel 60.

In one embodiment, each of the memory stack structures 55 comprises vertical NAND string including the respective vertical stack of memory elements (comprising portions of a charge storage layer 54 located at levels of the sacrificial material layers (142, 242, 342)) and a vertical semiconductor channel 60 that vertically extend through the sacrificial material layers (142, 242, 342) adjacent to the respective vertical stack of memory elements.

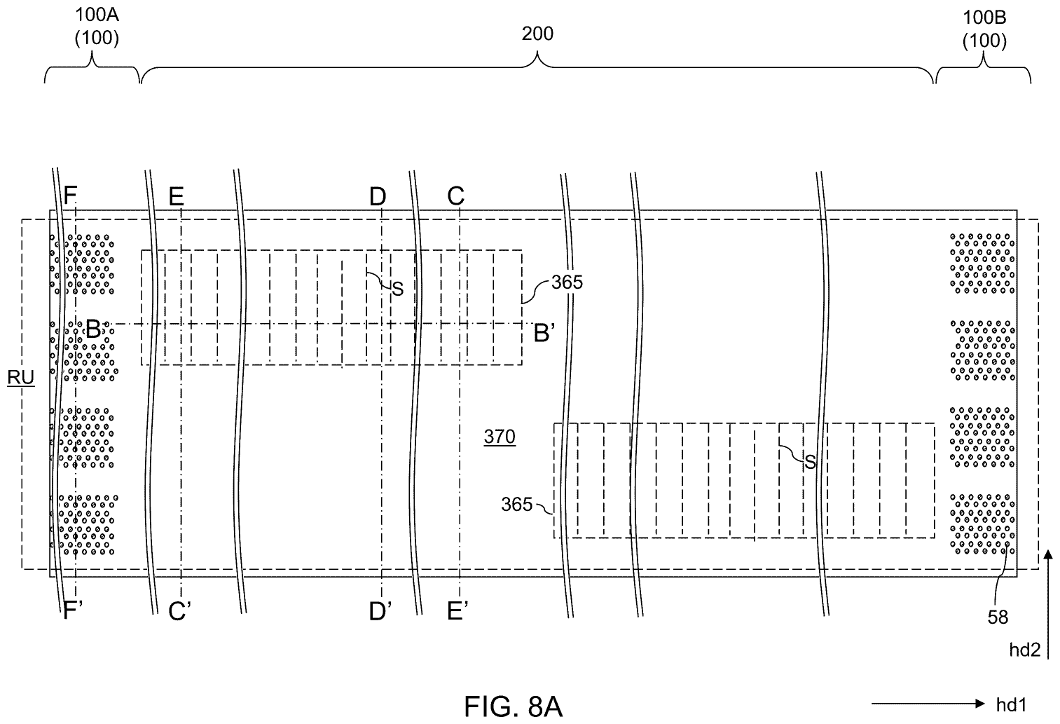

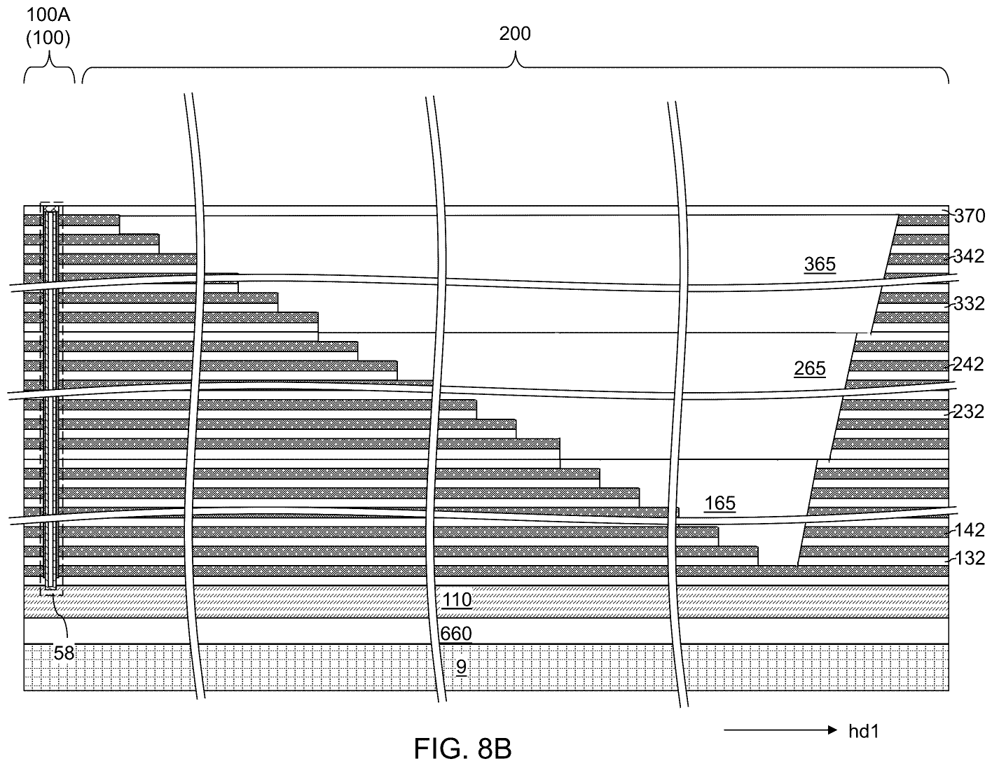

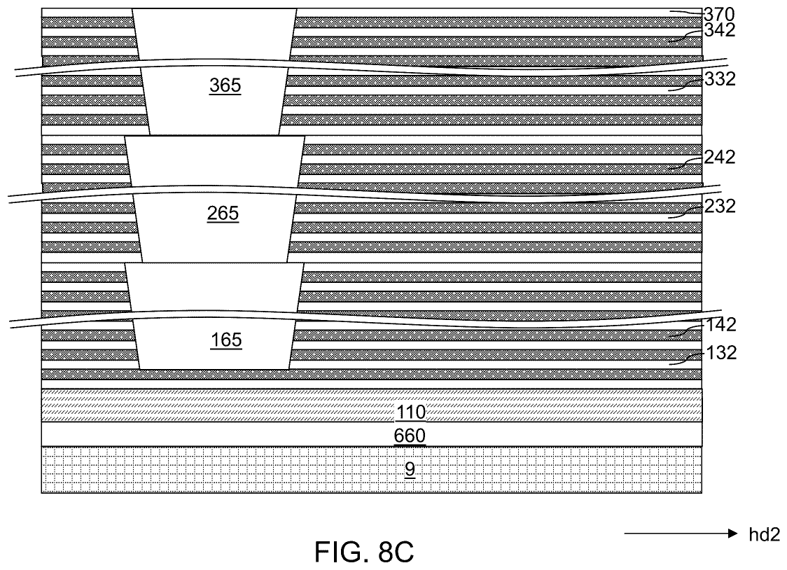

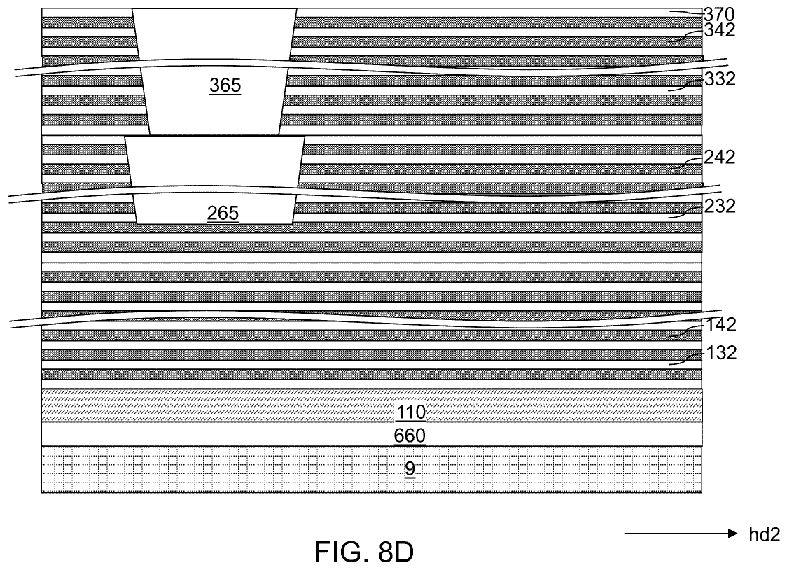

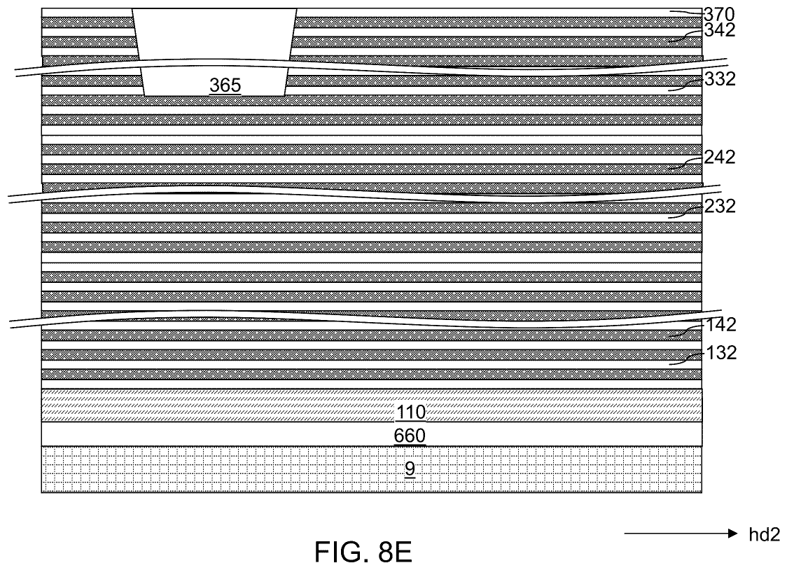

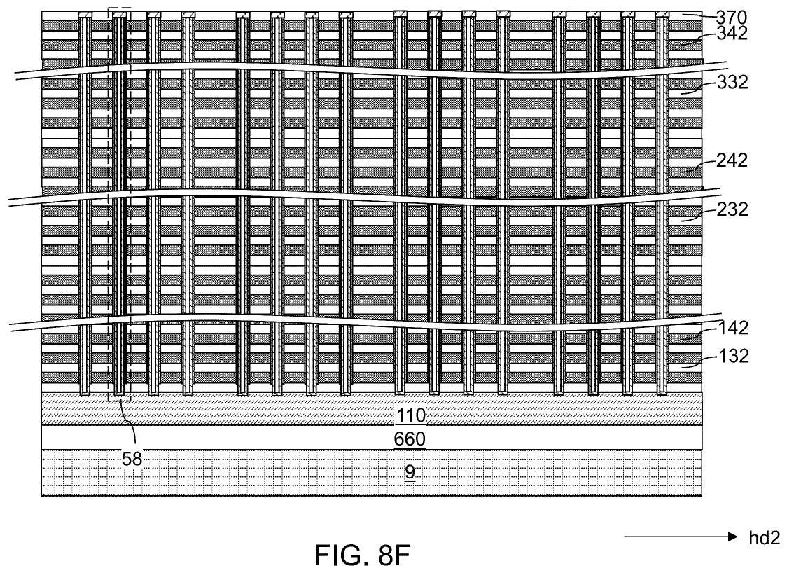

Referring to FIGS. 8A-8F, the exemplary structure is illustrated after the processing steps of FIG. 7F. i.e., after formation of the memory opening fill structures 58 in the memory openings 49. In one embodiment, support pillar structures (not shown) may be formed in the support openings. Generally, each of the memory opening fill structures 58 comprises a respective vertical stack of memory elements located at levels of the electrically conductive layers (146, 246, 346) within the plurality of tier structures, and further comprises a respective vertical semiconductor channel 60 that vertically extends through the plurality of tier structures.

While an embodiment is described in which a three tier device includes three vertically stacked vertically alternating sequences of insulating layers (132, 232, 332) and sacrificial material layers (142, 242, 342), the device may include one or more tiers of vertically alternating sequence of respective insulating layers and respective sacrificial material layers. Thus, the number of tiers of vertically alternating sequences may be 1, 2, 3, 4, etc. Further, the number of sets of stepped surfaces, and the number of at least one retro-stepped dielectric material portion that may be vertically stacked, may be the same as the number of tiers, i.e., may be 1, 2, 3, 4, etc.

Generally, at least one vertically alternating sequence of insulating layers (132, 232, 332) and sacrificial material layers (142, 242, 342) can be formed over the substrate 9. Memory openings 49 can be formed through the at least one vertically alternating sequence. Memory opening fill structures 58 can be formed in the memory openings 49. Each of the memory opening fill structures 58 comprises a respective vertical stack of memory elements (e.g., portions of the memory film 50) and a vertical semiconductor channel 60.

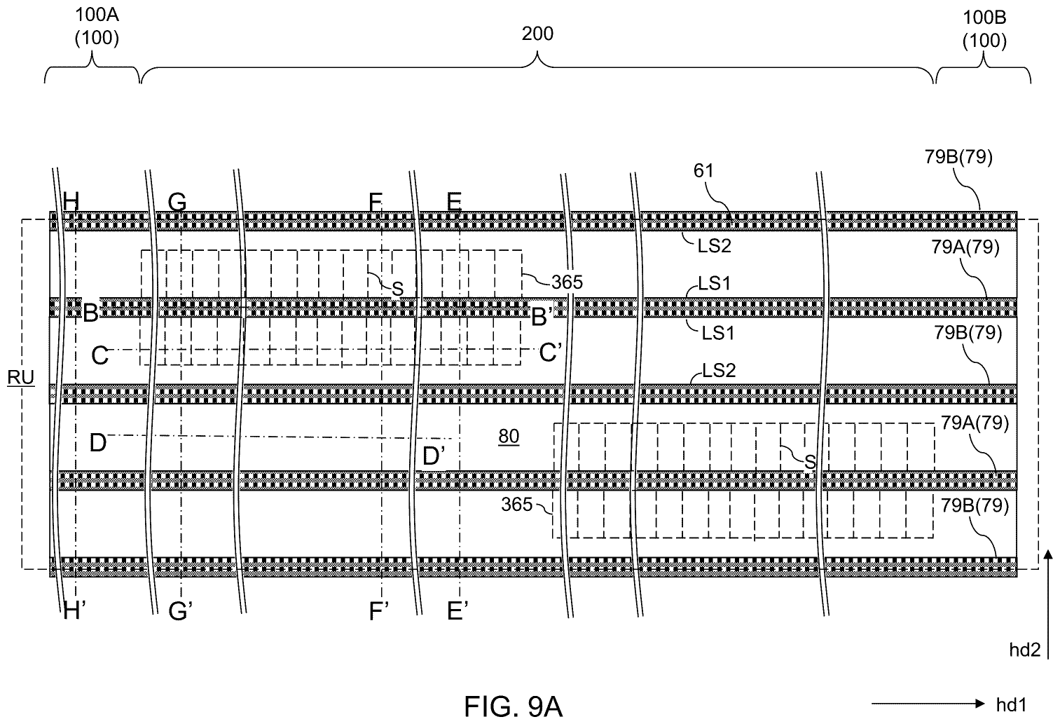

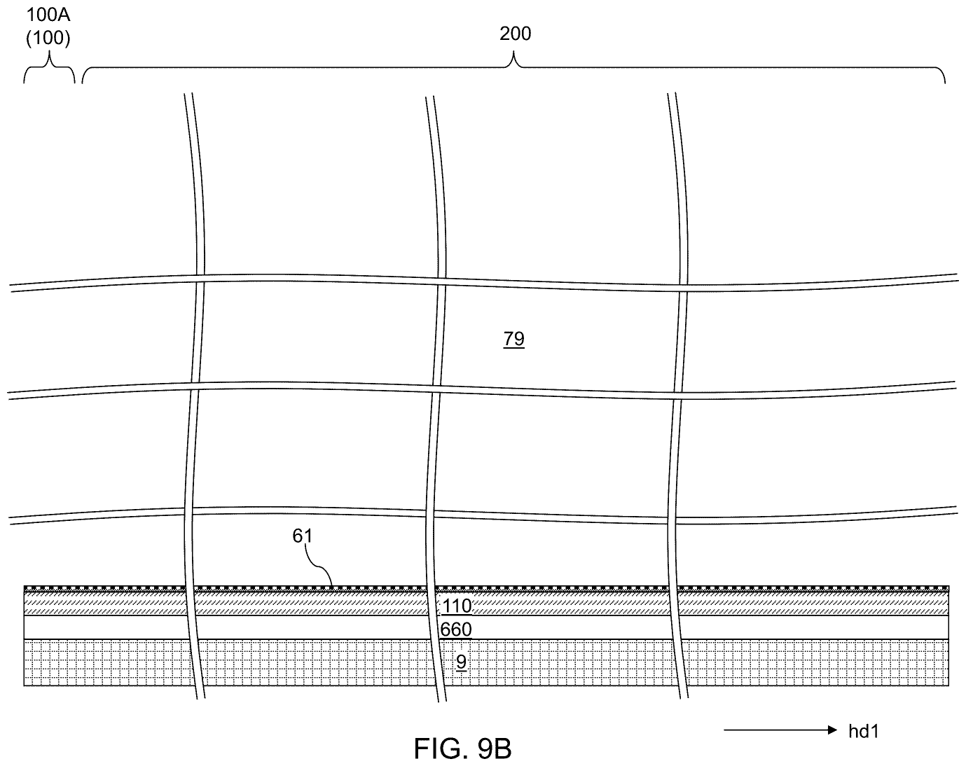

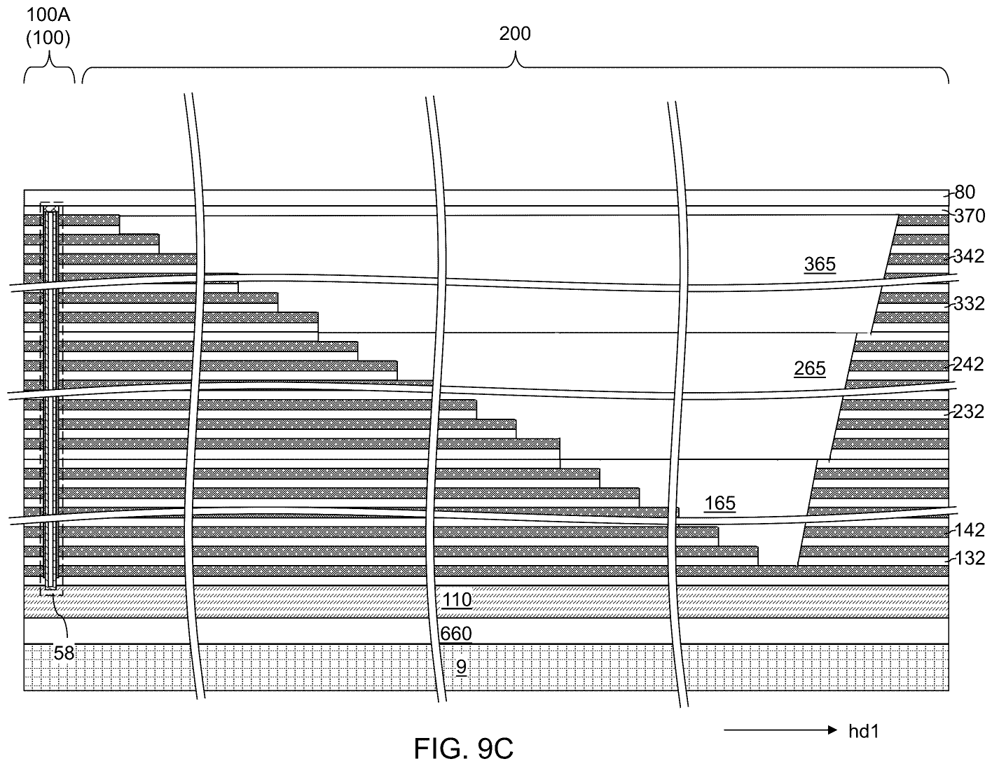

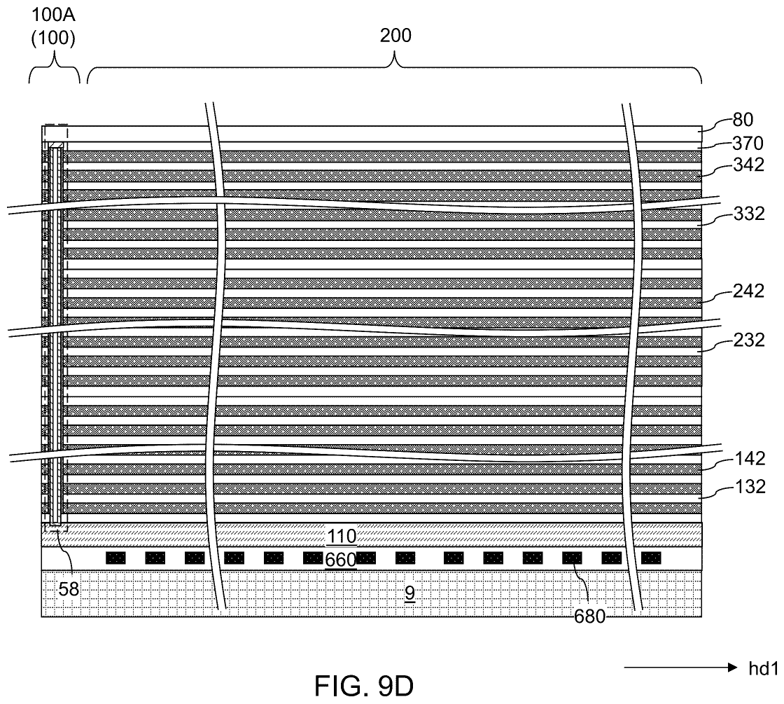

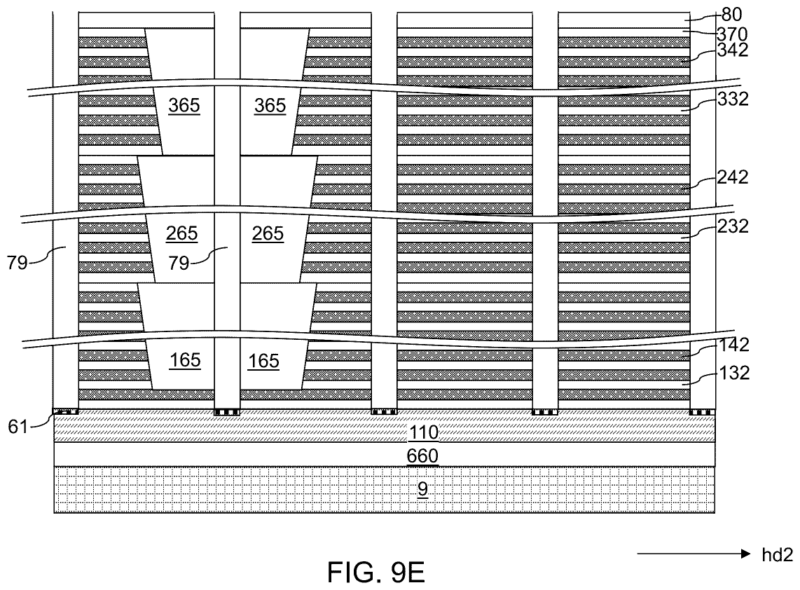

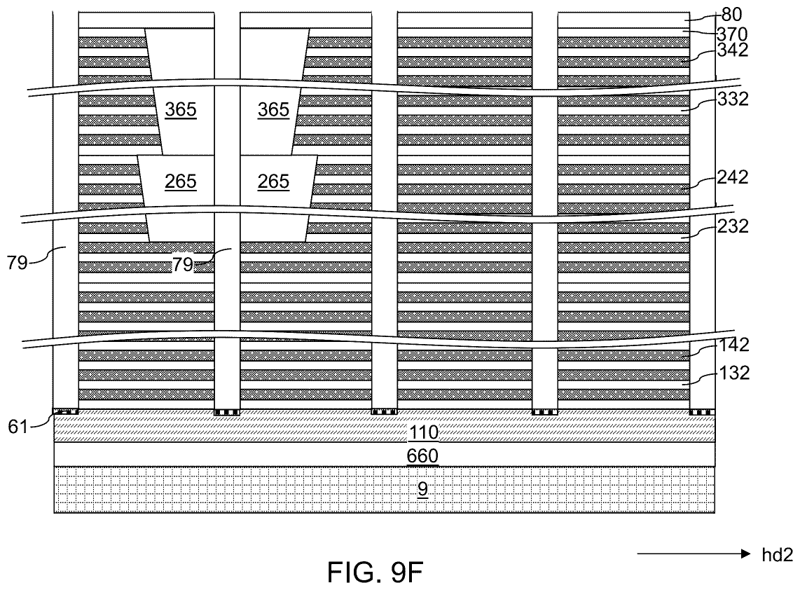

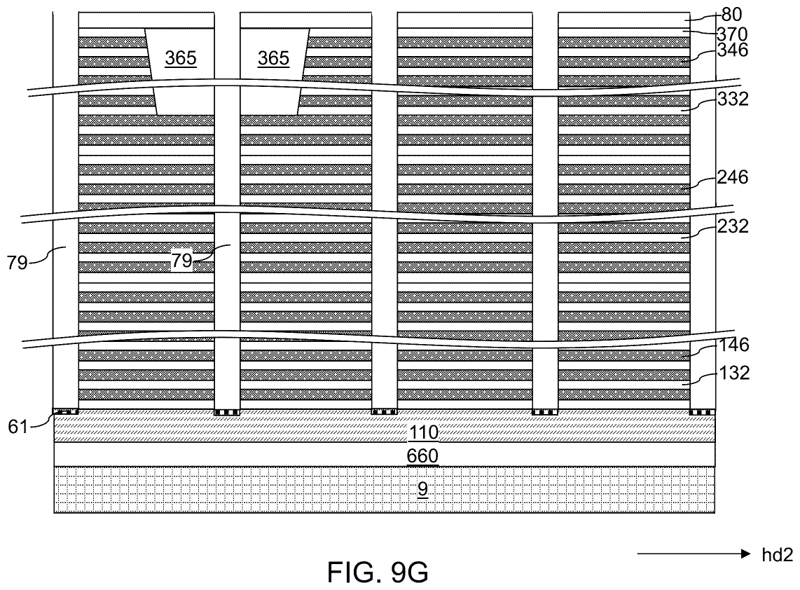

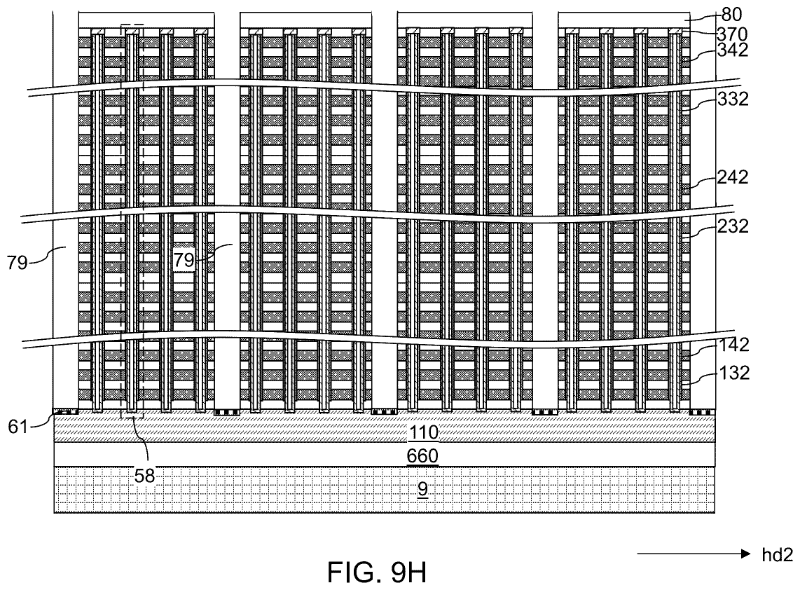

Referring to FIGS. 9A-9H, a contact-level dielectric layer 80 can be formed over the insulating cap layer 370, the memory opening fill structures 58, and the support pillar structures (not illustrated). The contact-level dielectric layer 80 comprises a dielectric material, such as silicon oxide, and can have a thickness in a range from 50 nm to 400 nm, although lesser and greater thicknesses may also be employed.

Subsequently, laterally-extending trenches 79 laterally extending along a first horizontal direction hd1 can be formed through the contact-level dielectric layer 80, the insulating cap layer 370, and each of the at least one vertically alternating sequence {(132, 142), (232, 242), (332, 342)}. The laterally-extending trenches 79 can be formed between clusters of memory opening fill structures 58 in a memory block such that an array of memory opening fill structures 58 is present within each portion (e.g., within each memory block) of a memory array region 100 located between a respective neighboring pair of laterally-extending trenches 79.

Each of the vertically alternating sequences is divided into a respective set of alternating stacks {(132, 142), (232, 242), (332, 342)} of insulating layers (132, 232, 332) and sacrificial material layers (142, 242, 342) that are laterally spaced apart along a second horizontal direction (e.g., bit line direction) hd2. For example, the third vertically alternating sequence of third insulating layers 332 and third sacrificial material layers 342 is divided into a set of third alternating stacks of third insulating layers 332 (which are patterned portions of the third insulating layers 332 of the third vertically alternating sequence) and third sacrificial material layers 342 (which are patterned portions of the third sacrificial material layers 342 of the third vertically alternating sequence); the second vertically alternating sequence of second insulating layers 232 and second sacrificial material layers 242 is divided into a set of second alternating stacks of second insulating layers 232 (which are patterned portions of the second insulating layers 232 of the second vertically alternating sequence) and second sacrificial material layers 242 (which are patterned portions of the second sacrificial material layers 242 of the second vertically alternating sequence); and the first vertically alternating sequence of first insulating layers 132 and first sacrificial material layers 142 is divided into a set of first alternating stacks of first insulating layers 132 (which are patterned portions of the first insulating layers 132 of the first vertically alternating sequence) and first sacrificial material layers 142 (which are patterned portions of the first sacrificial material layers 142 of the first vertically alternating sequence).

In one embodiment, the laterally-extending trenches 79 comprise first laterally-extending trenches 79A that divide a respective set of at least one retro-stepped dielectric material portion (165, 265, 365) into two disjoined material portions that are laterally spaced apart along the second horizontal direction hd2. Each divided portion of the at least one retro-stepped dielectric material portion (165, 265, 365) is also referred to as at least one retro-stepped dielectric material portion (165, 265, 365), albeit with a reduced area than before forming the laterally-extending trenches 79. The laterally-extending trenches 79 also comprise second laterally-extending trenches 79B that do not divide and do not contact any of the at least one retro-stepped dielectric material portions (165, 265, 365). In other words, each first laterally-extending trench 79A cuts through at least one retro-stepped dielectric material portion (165, 265, 365). In contrast, each second laterally-extending trench 79B is laterally spaced from the at least one retro-stepped dielectric material portion (165, 265, 365).

In one embodiment, the first laterally-extending trenches 79A and the second laterally-extending trenches 79B can be interlaced along the second horizontal direction hd2 such that each first laterally-extending trench 79A that is not an outermost laterally extending trench 79 is located between a pair of second laterally-extending trenches 79B that are two most proximal laterally-extending trenches 79 of the respective first laterally-extending trench 79A; and each second laterally-extending trench 79B that is not an outermost laterally extending trench 79 is located between a pair of first laterally-extending trenches 79A that are two most proximal laterally-extending trenches 79 of the respective second laterally-extending trench 79B.

As shown in FIG. 9A, the at least one alternating stack {(132, 142), (232, 242), (332, 342)} vertically extending between the semiconductor material layer 110 and a patterned portion of the insulating cap layer 370 comprises a pair of lengthwise sidewalls, which include a first lengthwise sidewall LS1 that is physically exposed to a respective first laterally-extending trench 79A and a second lengthwise sidewall LS2 that is physically exposed to a respective second laterally-extending trench 79B.

At least one alternating stack {(132, 142), (232, 242), (332, 342)} is provided between each neighboring pair of a first laterally-extending trench 79A and a second laterally-extending trench 79B. The at least one alternating stack {(132, 142), (232, 242), (332, 342)} overlies the substrate 9, includes insulating layers (132, 232, 332) and sacrificial material layers (142, 242, 342) that alternate along the vertical direction, and has a first lengthwise sidewall LS1 and a second lengthwise sidewall LS2 that laterally extend along the first horizontal direction (e.g., word line direction) hd1. At least one retro-stepped dielectric material portion (165, 265, 365) is embedded within the alternating stack {(132, 142), (232, 242), (332, 342)}, and comprises a respective dielectric material.

In case the semiconductor material layer 110 is present in the exemplary structure and is employed as a horizontal semiconductor channel, the semiconductor material layer 110 may have a doping of a first conductivity type, i.e., the same conductivity type as the conductivity type of the vertical semiconductor channels 60. In this case, an ion implantation process can be performed to implant dopants of the second conductivity type (i.e., the opposite of the first conductivity type) to form source regions 61 in surface portions of the semiconductor material layer 110 (or the substrate 9 if layer 110 is omitted) that underlie the laterally-extending trenches 79. In some embodiments, metallic landing pads 680 may be provided as a subset of the lower-level metal interconnect structures in the at least one lower-level dielectric material layers 660. The metallic landing pads 680 may be subsequently employed to provide vertical electrical connections through insulating layers and electrically conductive layers within a three-dimensional memory array.

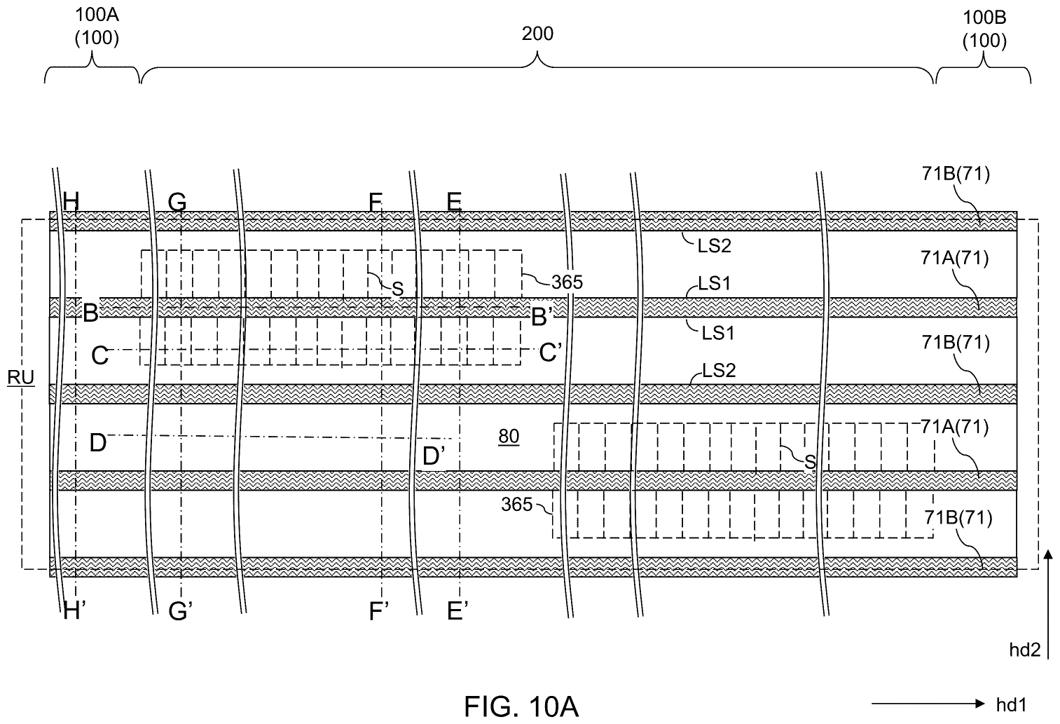

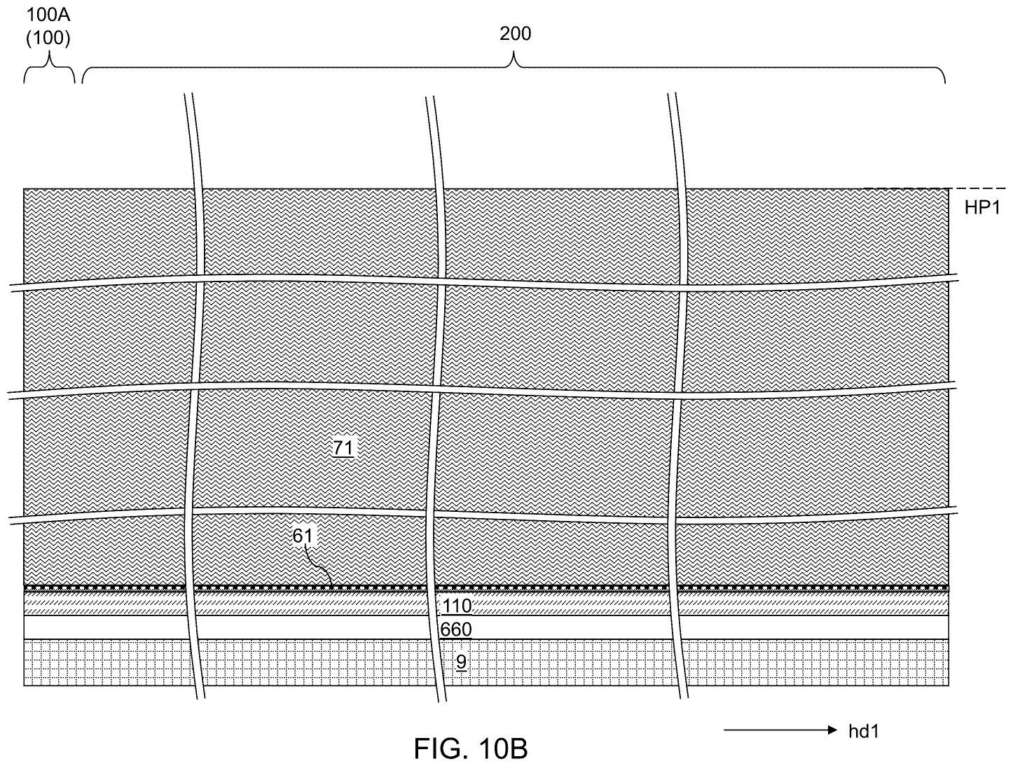

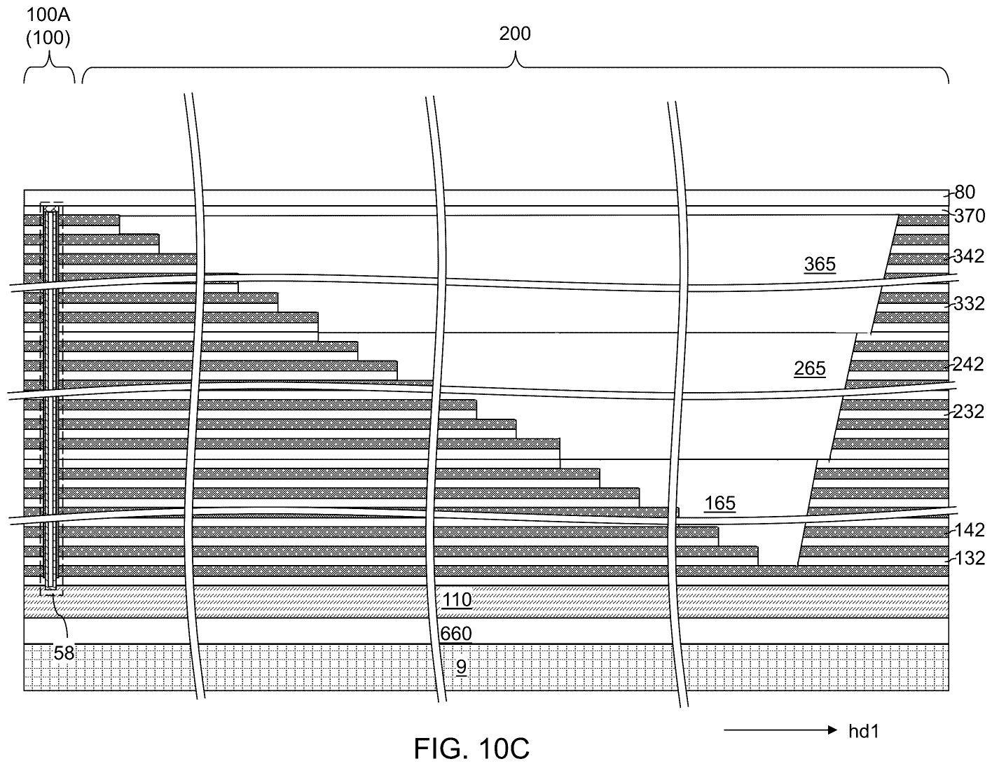

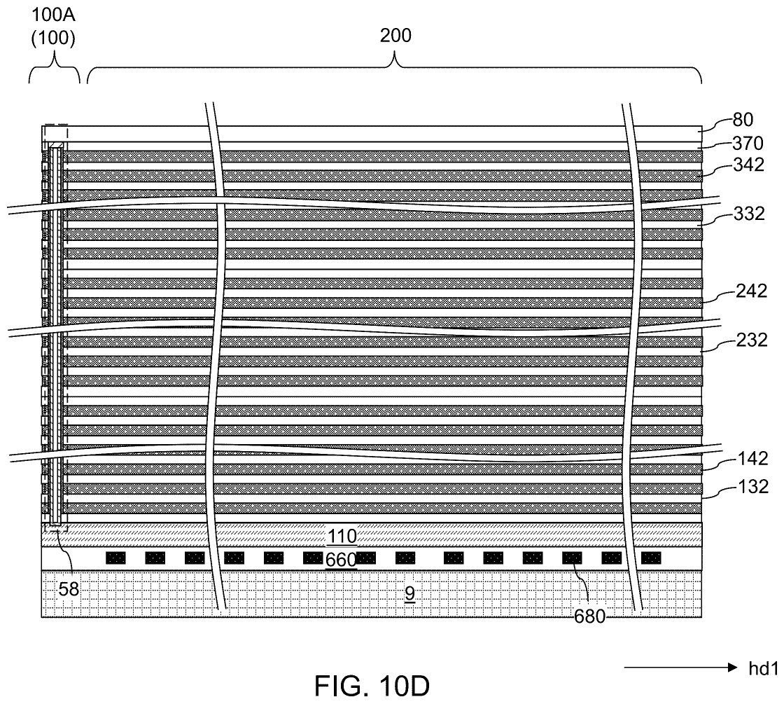

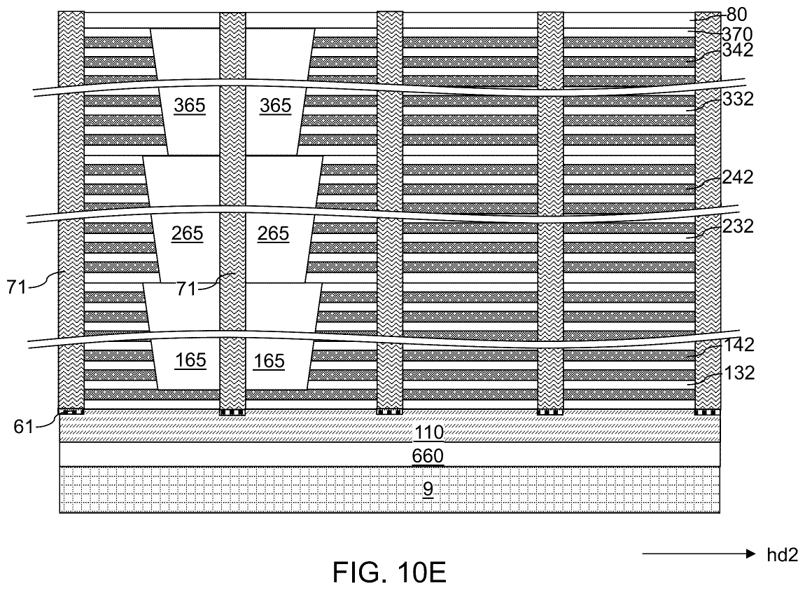

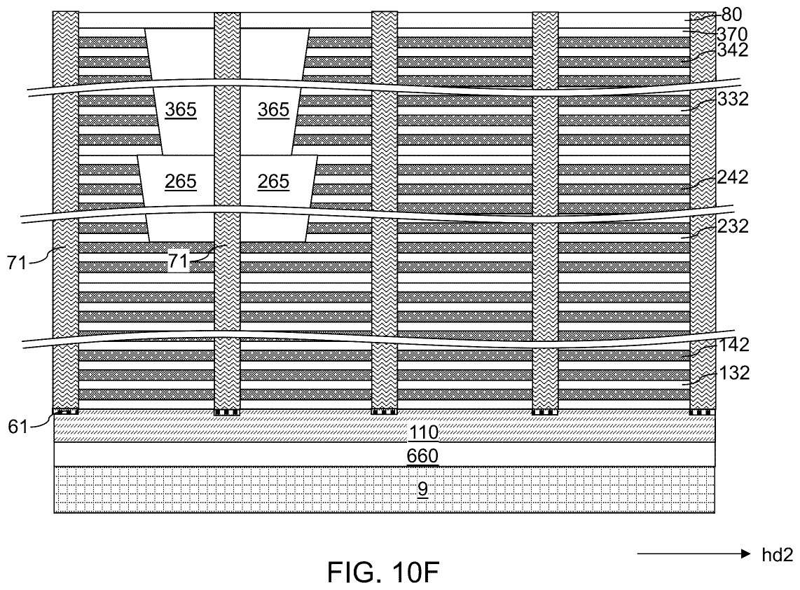

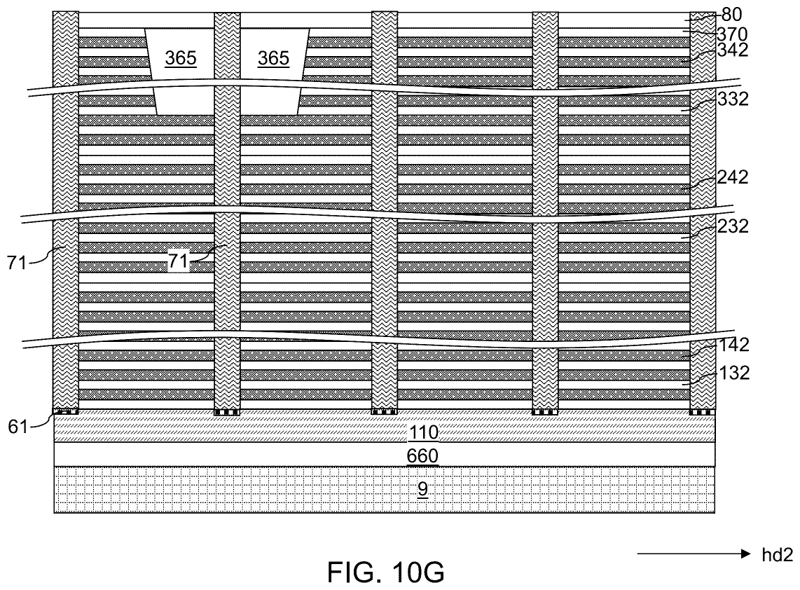

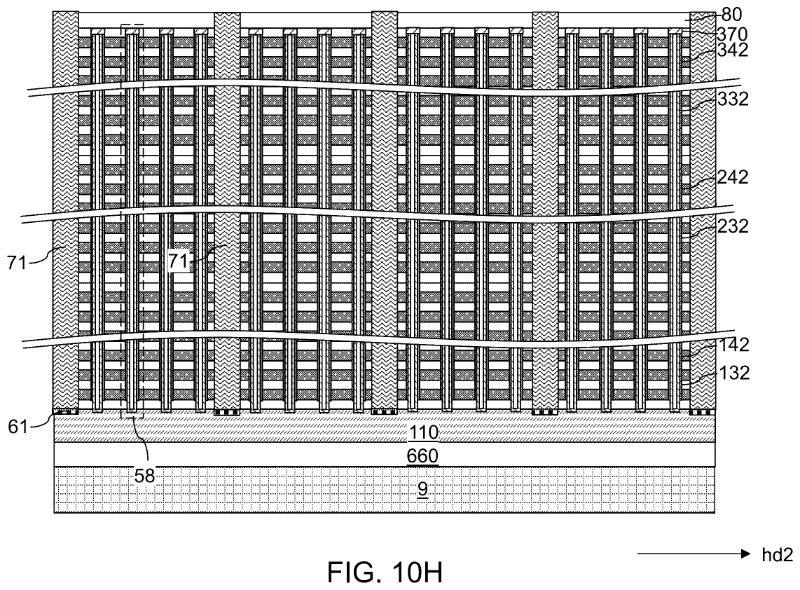

Referring to FIGS. 10A-10H, an optional etch stop liner (such as a silicon oxide liner; not shown) may be formed in peripheral regions of the laterally-extending trenches 79. A sacrificial fill material may be deposited in the laterally-extending trenches 79. Excess portions of the sacrificial fill material can be removed from above a first horizontal plane HP1 including the top surface of the contact-level dielectric layer 80 by a planarization process. The planarization process may comprise a chemical mechanical polishing (CMP) process and/or a recess etch process. Each remaining portion of the sacrificial fill material that fill the laterally-extending trench 79 constitutes sacrificial laterally-extending trench fill structures 71. The sacrificial laterally-extending trench fill structures 71 comprise first sacrificial laterally-extending trench fill structures 71A that fill the first laterally-extending trenches 79A, and second sacrificial laterally-extending trench fill structures 71B that fill the second laterally-extending trenches 79B. In an embodiment in which etch stop liners are not employed, each first lengthwise sidewall LS1 of at least one alternating stack {(132, 142), (232, 242), (332, 342)} and a sidewall of each at least one retro-stepped dielectric material portion (165, 265, 365) contacts a first sacrificial laterally-extending trench fill structure 71A; and each second lengthwise sidewall LS2 of at least one alternating stack {(132, 142), (232, 242), (332, 342)} contacts a second sacrificial laterally-extending trench fill structure 71B.

The sacrificial fill material of the sacrificial laterally-extending trench fill structures 71 may comprise any material that may be subsequently removed selective to the etch stop liner (if employed) or selective to the materials of the insulating layers (132, 232, 332), the sacrificial material layers (142, 242, 342), and the semiconductor material layer 110. For example, the sacrificial fill material may comprise a carbon-based fill material such as amorphous carbon, diamond-like carbon, or a mixture of carbon and at least another element (such as boron or silicon); a semiconductor fill material, such as a silicon-germanium alloy or amorphous silicon (in case the etch stop liner is employed); a dielectric material, such as organosilicate glass or borosilicate glass; or a polymer material.

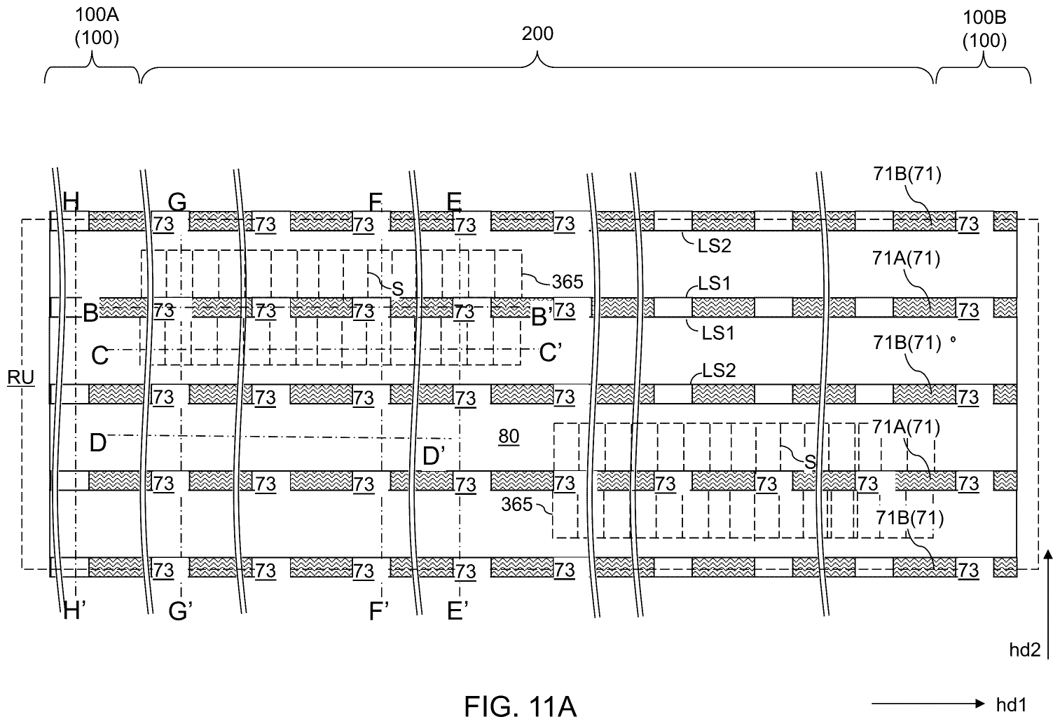

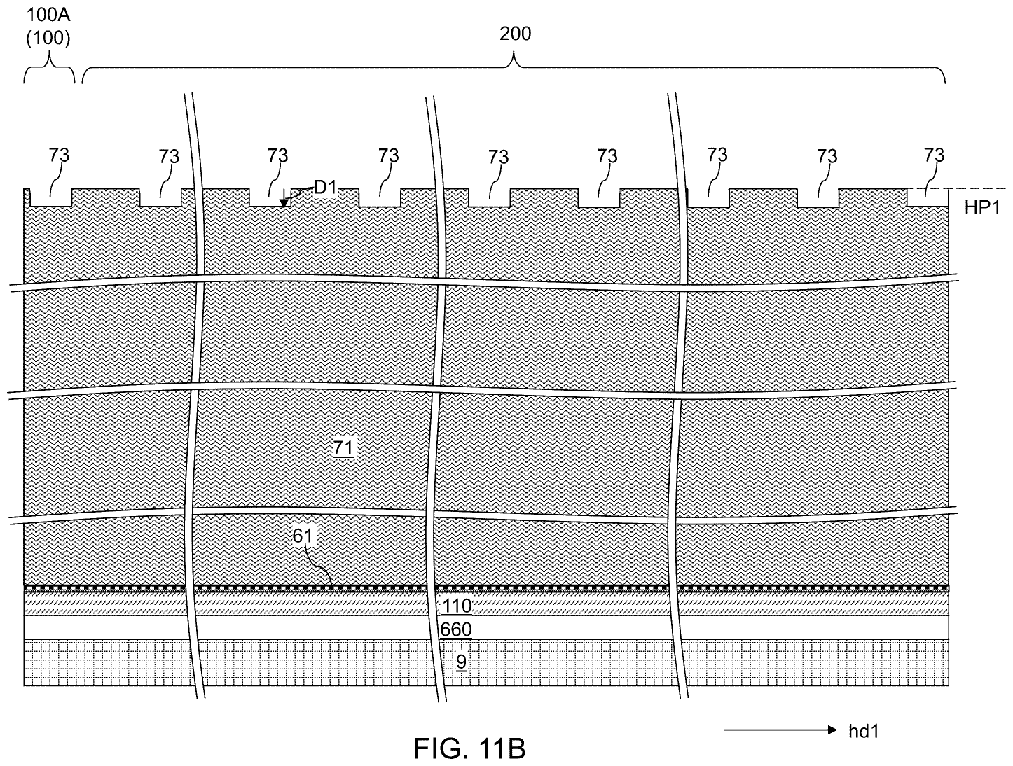

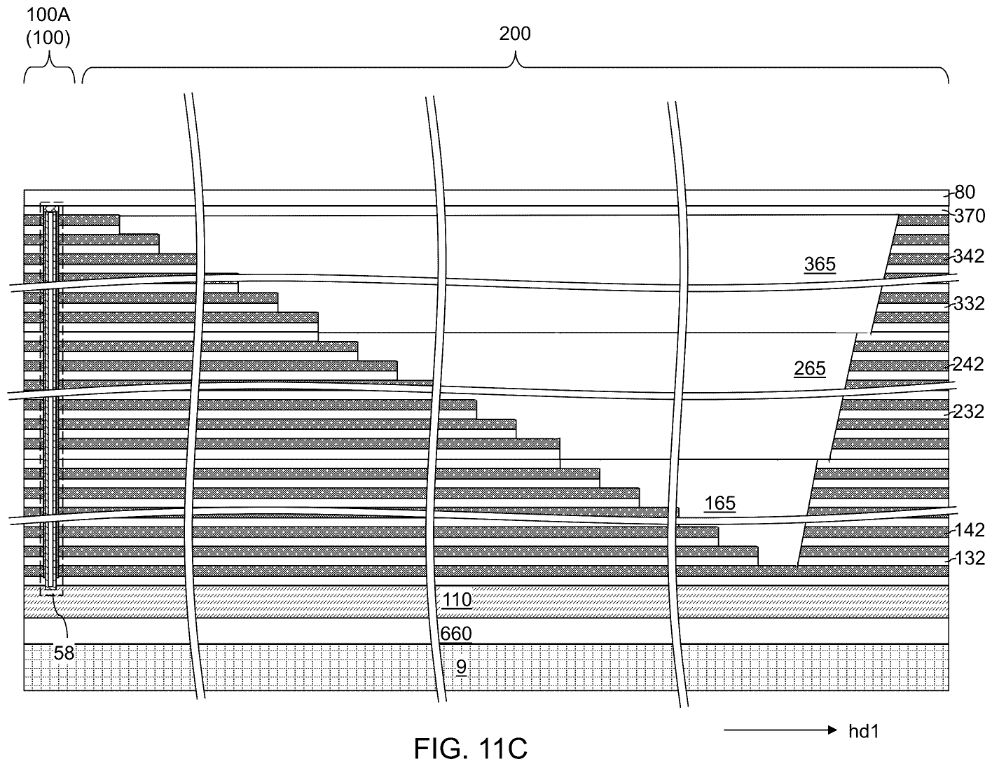

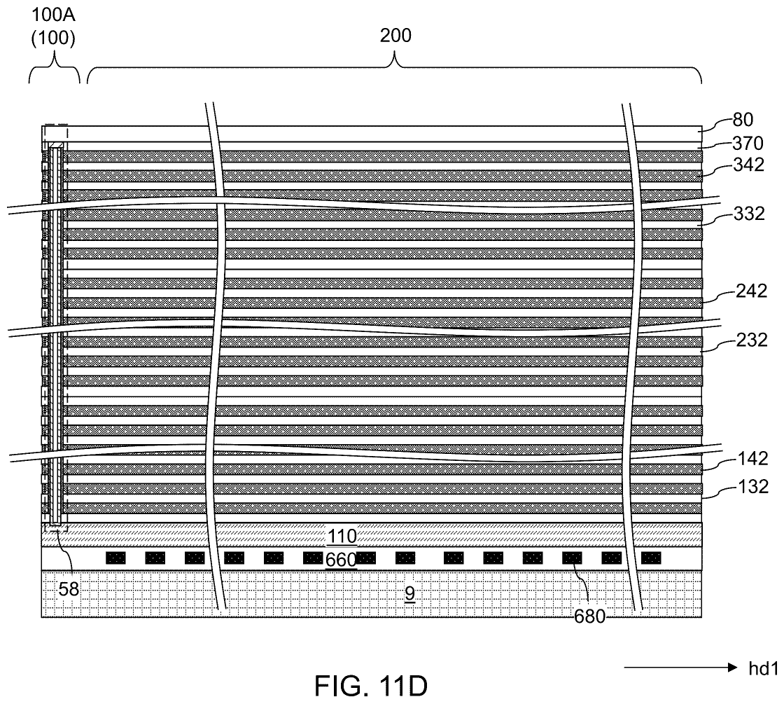

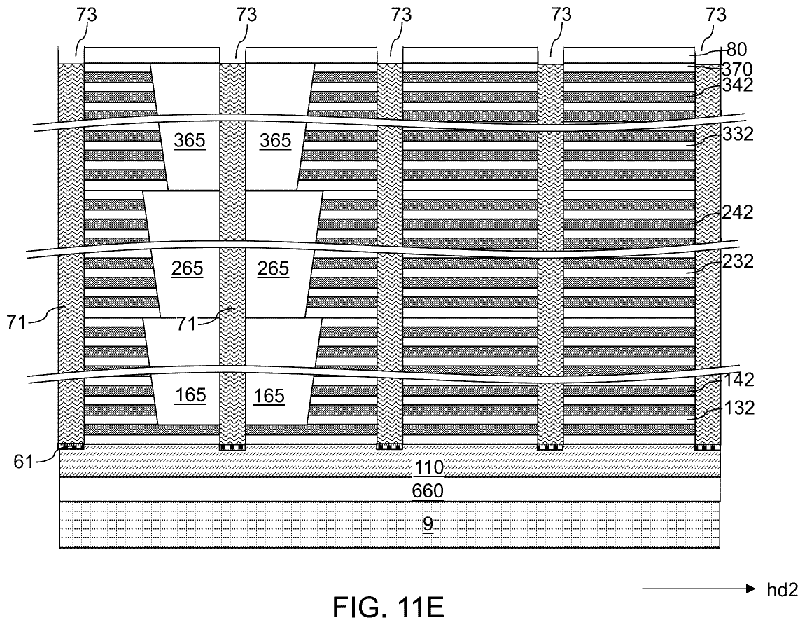

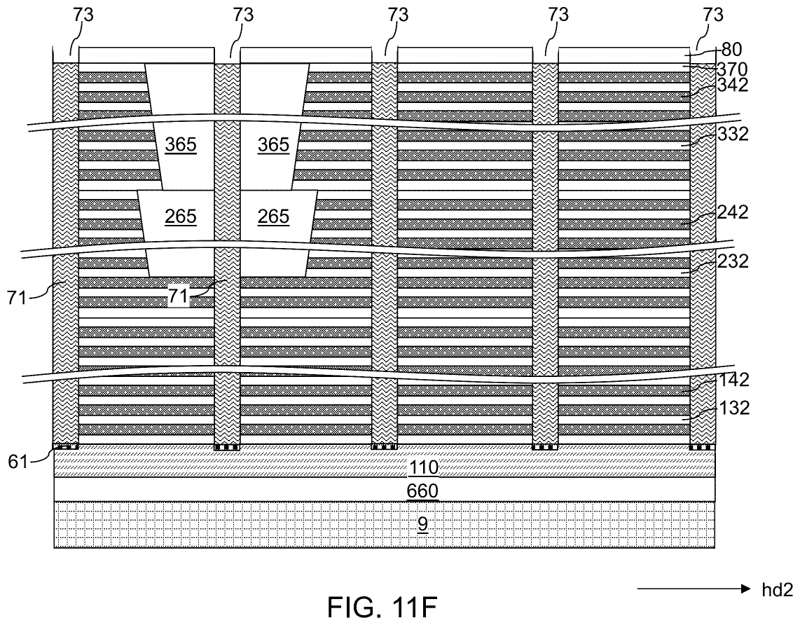

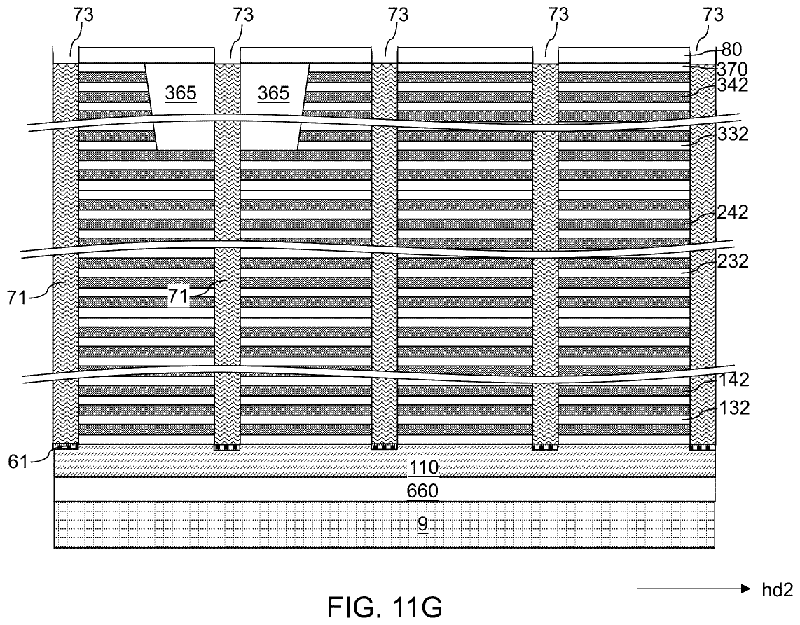

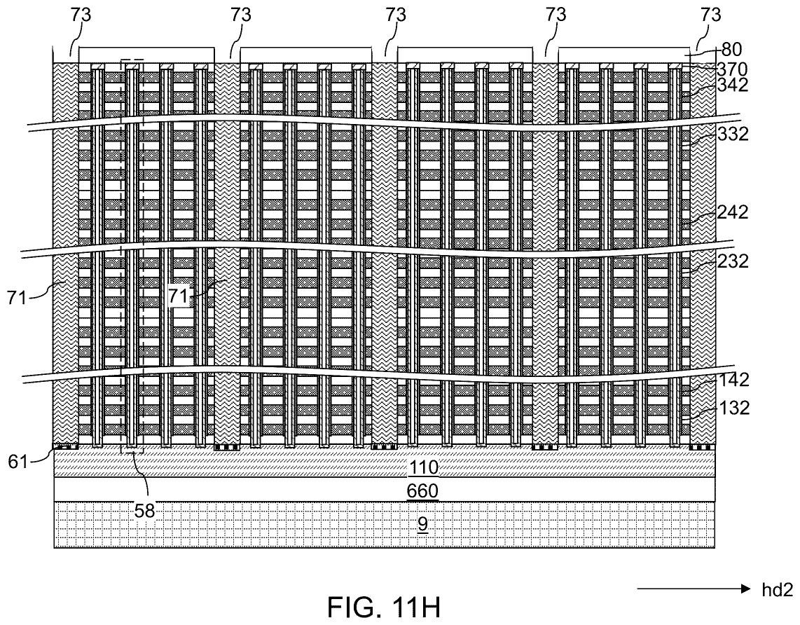

Referring to FIGS. 11A-11H, a first photoresist layer (not shown) can be applied over the contact-level dielectric layer 80 and the sacrificial laterally-extending trench fill structures 71, and can be lithographically patterned to form a two-dimensional array of openings therein. Each row of openings in the first photoresist layer may overlie a respective one of the sacrificial laterally-extending trench fill structures 71.

In one embodiment, the two-dimensional array of opening may be arranged as a two-dimensional periodic array of openings. Each opening in the first photoresist layer can have a greater width than the width of an underlying sacrificial laterally-extending trench fill structure 71. In one embodiment, each opening in the first photoresist layer may have a greater length along the first horizontal direction hd1 than the width along the second horizontal direction hd2.

In one embodiment, at least one opening can be formed in the first photoresist layer between stepped bottom surfaces of a respective neighboring pair of first retro-stepped dielectric material layers 165 around each first sacrificial laterally-extending trench fill structure 71A; at least one opening can be formed in the first photoresist layer between stepped bottom surfaces of a respective neighboring pair of second retro-stepped dielectric material layers 265 around each first sacrificial laterally-extending trench fill structure 71A; and at least one opening can be formed in the first photoresist layer between stepped bottom surfaces of a respective neighboring pair of third retro-stepped dielectric material layers 365 around each first sacrificial laterally-extending trench fill structure 71A.

A first selective recess etch process can be performed to vertically recess portions of the sacrificial laterally-extending trench fill structures 71 that are not masked by the first photoresist layer. The first selective recess etch process may comprise an anisotropic etch process such as a reactive ion etch process. The first selective recess etch process may remove the unmasked portions of the sacrificial laterally-extending trench fill structures 71 selective to the material of the contact-level dielectric layer 80. Recess cavities 73 are formed in volumes from which the material of the sacrificial laterally-extending trench fill structures 71 by the first selective recess etch process.

The duration of the first selective recess etch process can be selected such that each of the recess cavities 73 has a first depth D1 along the vertical direction, as shown in FIG. 11B. Thus, each of the recess cavities 73 may have a respective planar bottom surface that is vertically offset from the first horizontal plane HP1 including the top surface of the contact-level dielectric layer 80 by the first depth D1. In one embodiment, the first depth D1 is less than the sum of the thickness of the contact-level dielectric layer 80 and the thickness of the insulating cap layer 370, and may be the same as, greater than, or less than, the thickness of the contact-level dielectric layer 80. In one embodiment, the first depth D1 may be less than the thickness of the contact-level dielectric layer 80. Each of the sacrificial laterally-extending trench fill structures 71 may embed a respective row of recess cavities 73. The first photoresist layer can be subsequently removed, for example, by ashing.

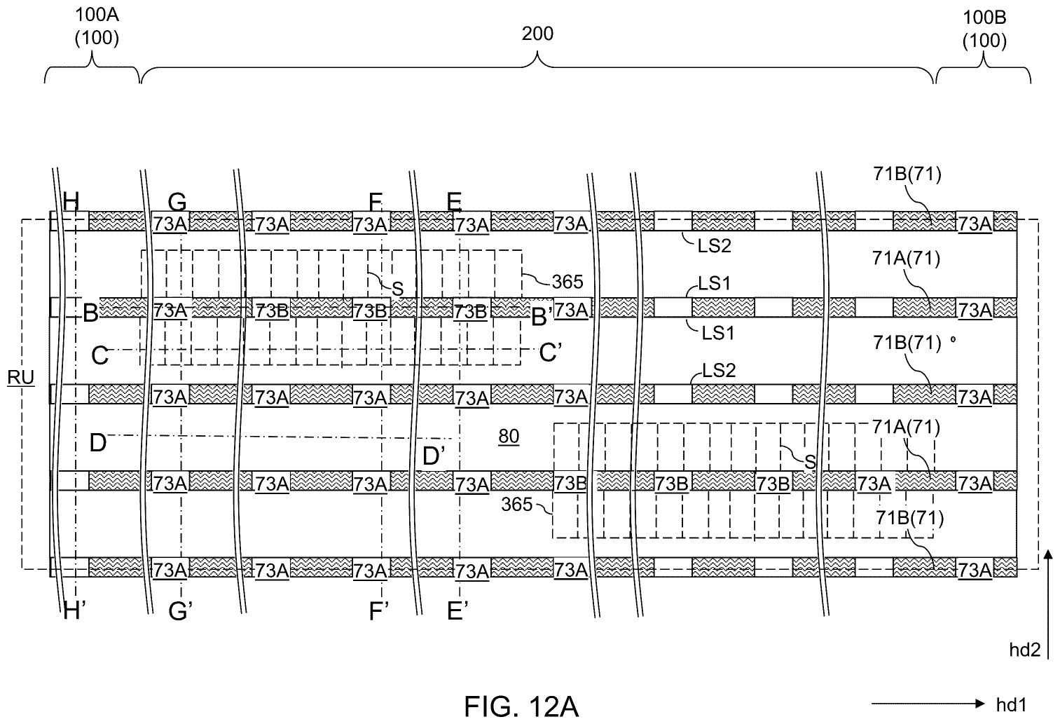

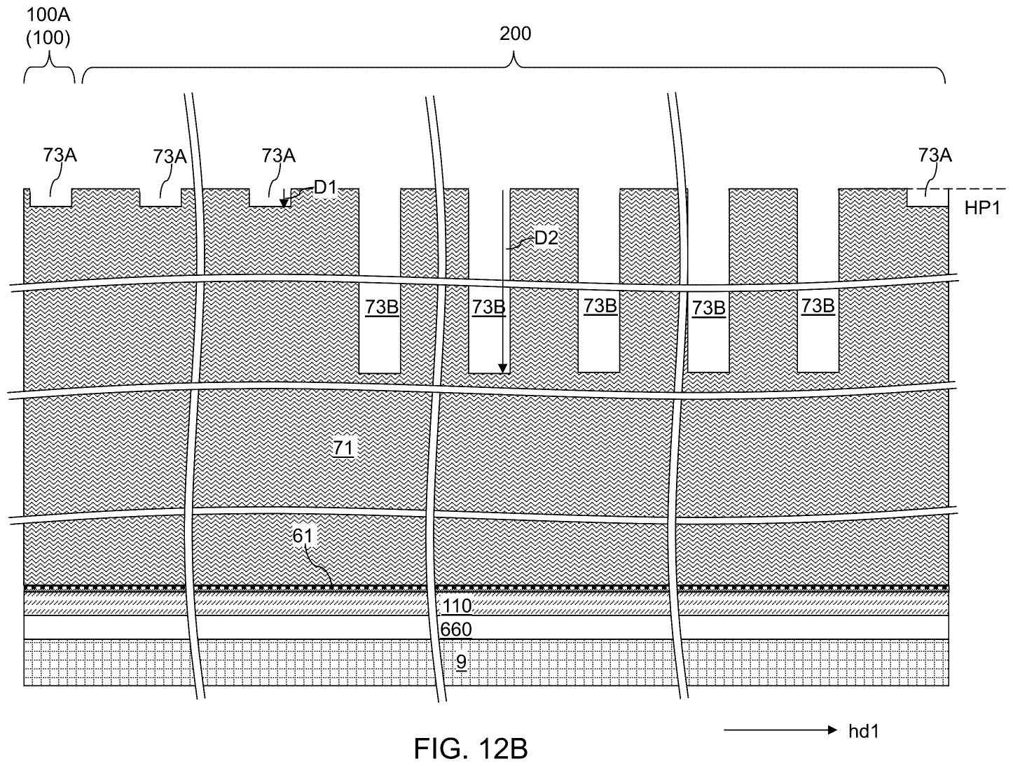

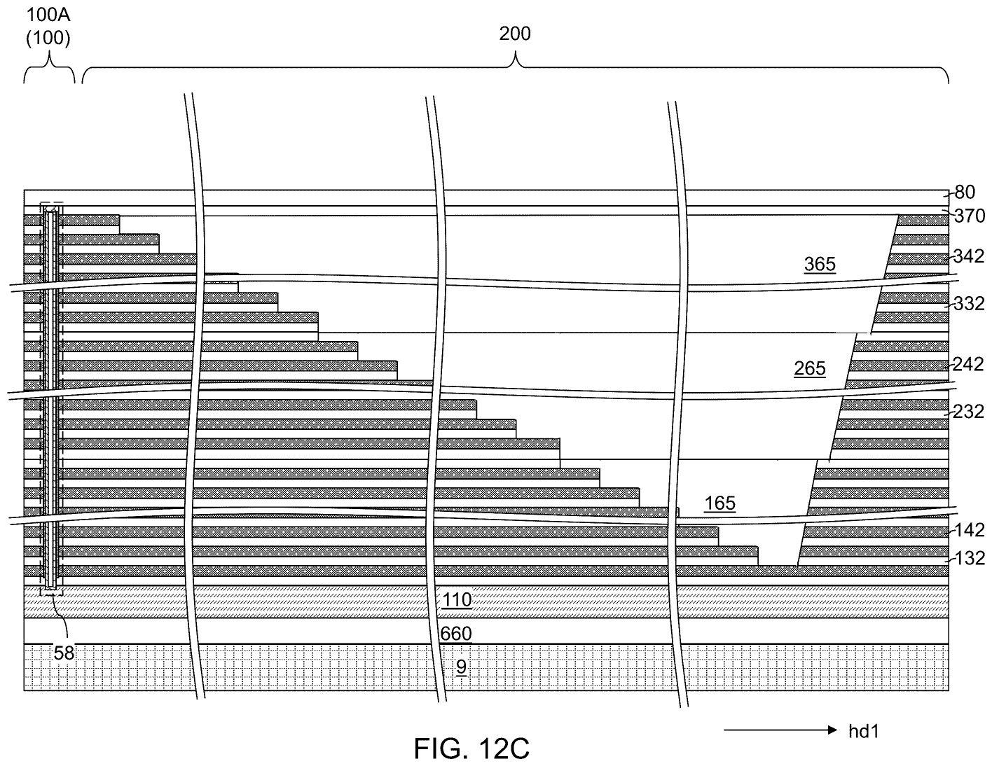

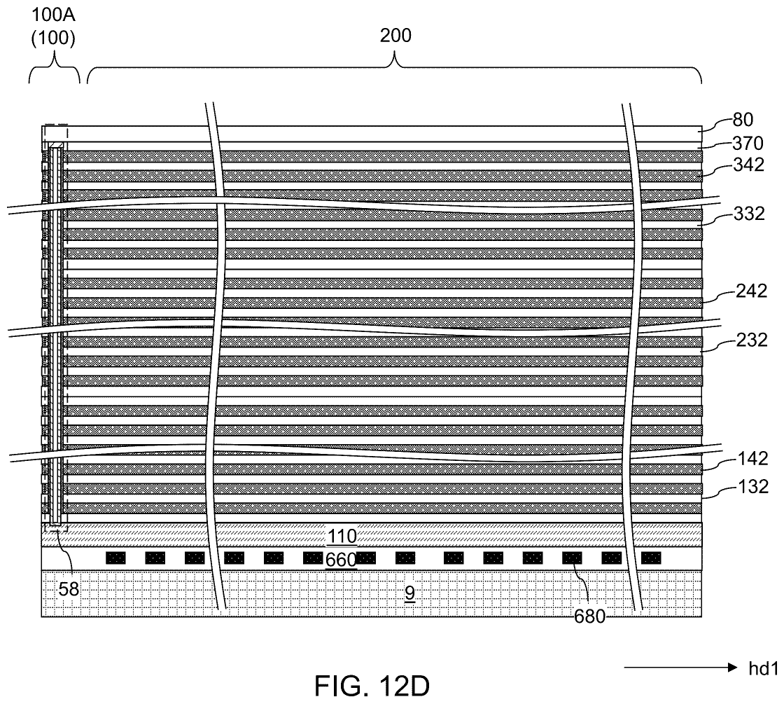

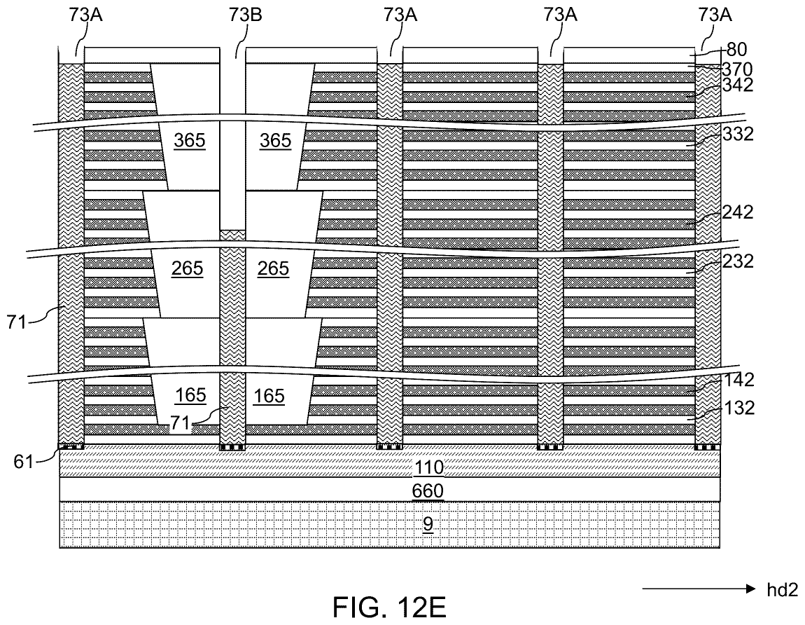

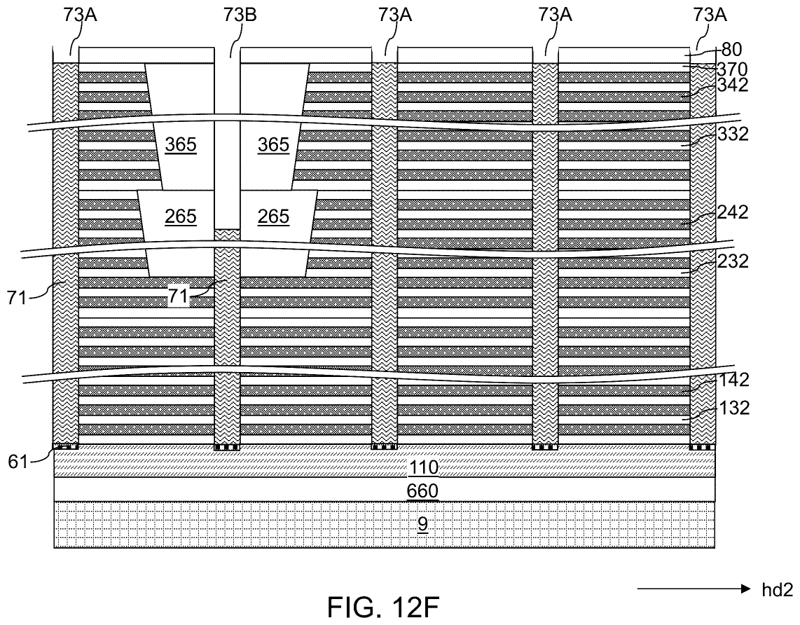

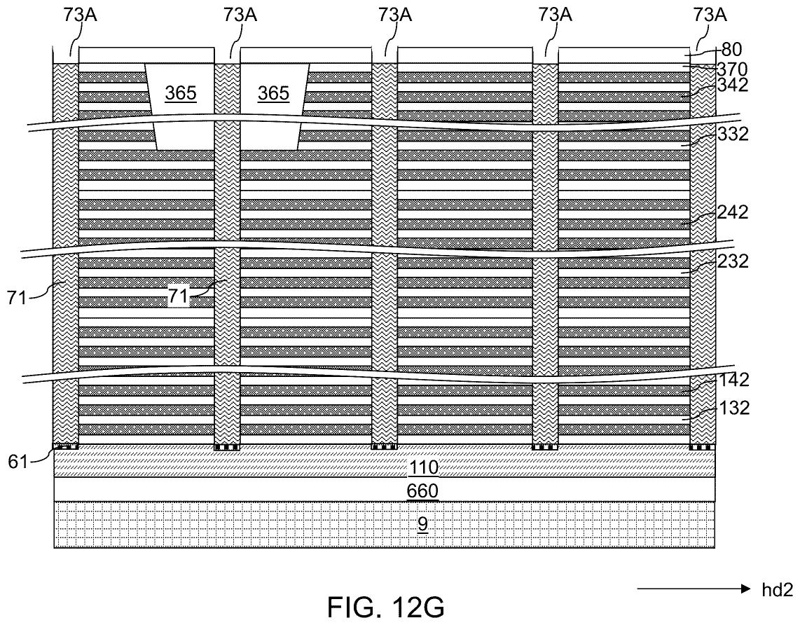

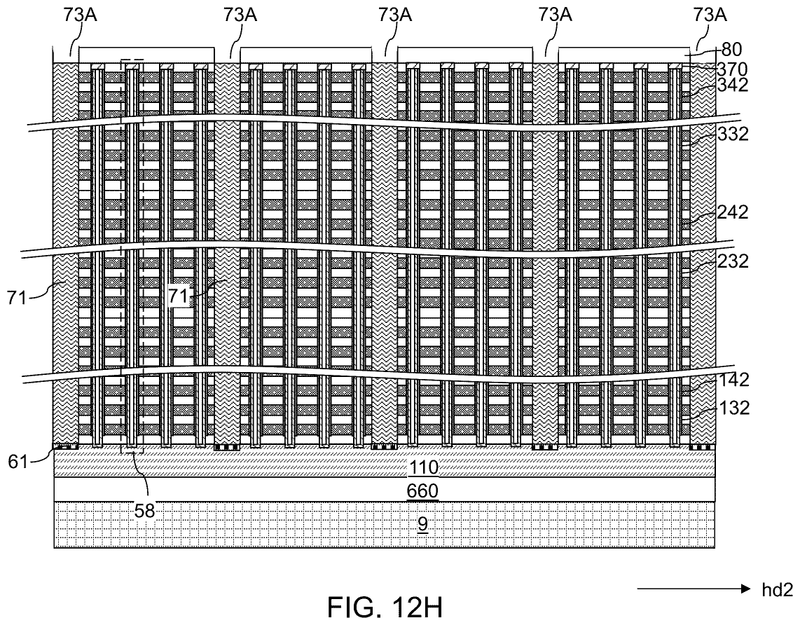

Referring to FIGS. 12A-12H, a second photoresist layer (not shown) can be applied over the contact-level dielectric layer 80 and the sacrificial laterally-extending trench fill structures 71, and can be lithographically patterned to form openings therein. Each opening in the second photoresist layer may overlie an area of a respective recess cavity 73 that is located between stepped bottom surfaces of a respective neighboring pair of first retro-stepped dielectric material layers 165, or is located between stepped bottom surfaces of a respective neighboring pair of second retro-stepped dielectric material portions 265. All recess cavities 73 that are located in the memory array regions 100 can be covered by the second photoresist layer. Further, all recess cavities 73 that are not located between a neighboring pair of first retro-stepped dielectric material portions 165 or between a neighboring pair of second retro-stepped dielectric material portions 265 can be covered by the second photoresist layer.

A second selective recess etch process can be performed to vertically recess a subset of the recess cavities 73 that is not masked by the second photoresist layer. The second selective recess etch process may comprise an anisotropic etch process such as a reactive ion etch process. The second selective recess etch process may vertically extend the unmasked subset of the recess cavities 73 to a depth below the horizontal plane including the top surfaces of the second retro-stepped dielectric material portions 265. Each recess cavity 73 that is covered by the second photoresist layer is hereafter referred to as a first-type recess cavity 73A. Each recess cavity 73 that is vertically extended by the second selective recess etch process is hereafter referred to as a second-type recess cavity 73B.

The duration of the second selective recess etch process can be selected such that each of the second-type recess cavities 73B has a second depth D2 along the vertical direction, as shown in FIG. 12B. Thus, each of the second-type recess cavities 73B may have a respective planar bottom surface that is vertically offset from the first horizontal plane HP1 including the top surface of the contact-level dielectric layer 80 by the second depth D2 which is greater than the first depth D1.

In one embodiment, the second depth D2 may be greater than the sum of the thickness of the contact-level dielectric layer 80, the thickness of the insulating cap layer 370, and the thickness of a third alternating stack of third insulating layers 332 and third sacrificial material layers 342. Each of the first sacrificial laterally-extending trench fill structures 71A embeds a respective set of first-type recess cavities 73A and a respective set of second-type recess cavities 73B. Each of the second sacrificial laterally-extending trench fill structures 71B embeds a respective set of additional first-type recess cavities 73A, but does not embed any second-type recess cavity 73B. Sidewalls of a pair of third retro-stepped dielectric material portions 365 and upper segments of sidewalls of a pair of second retro-stepped dielectric material portions 265 can be physically exposed to each second-type recess cavity 73B. The second photoresist layer can be subsequently removed, for example, by ashing.

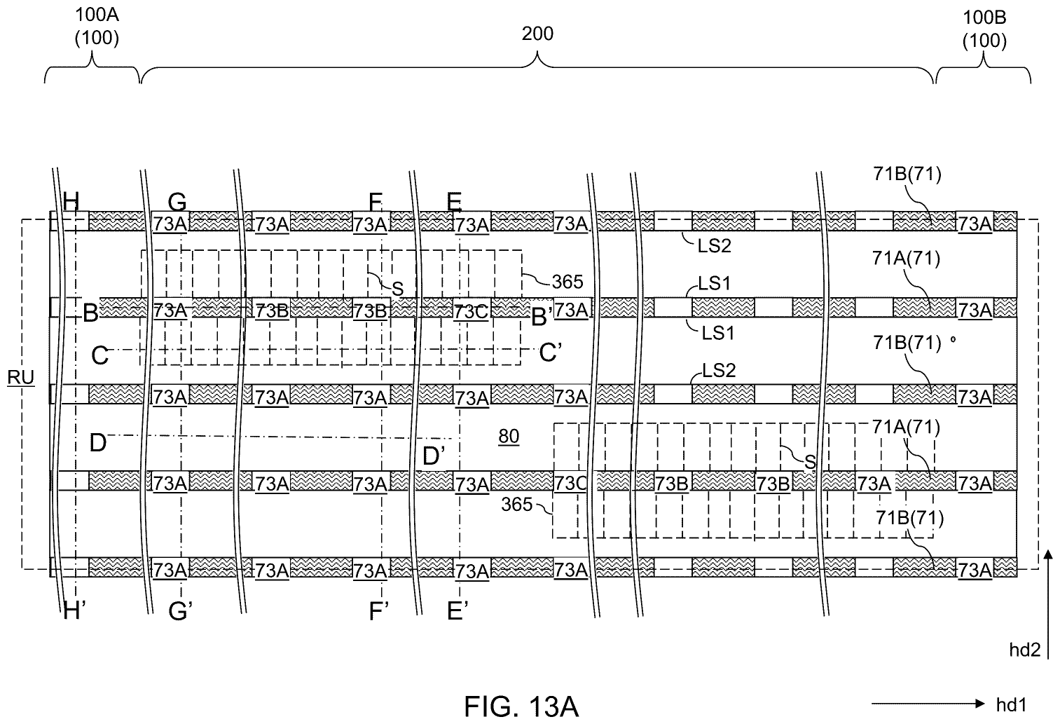

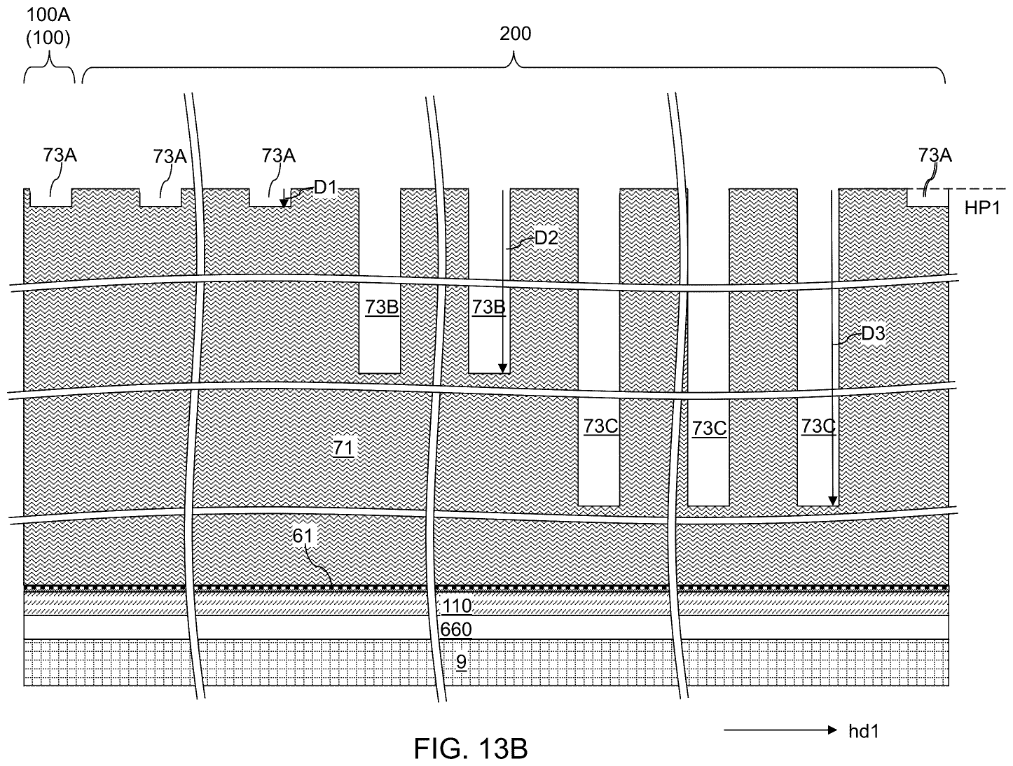

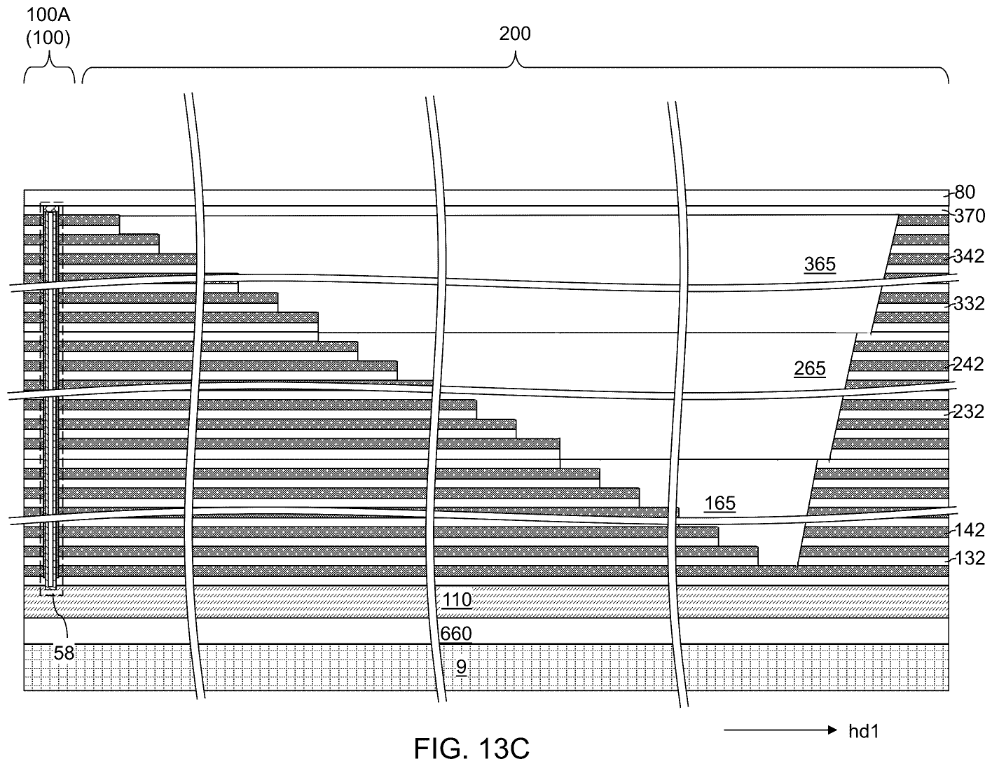

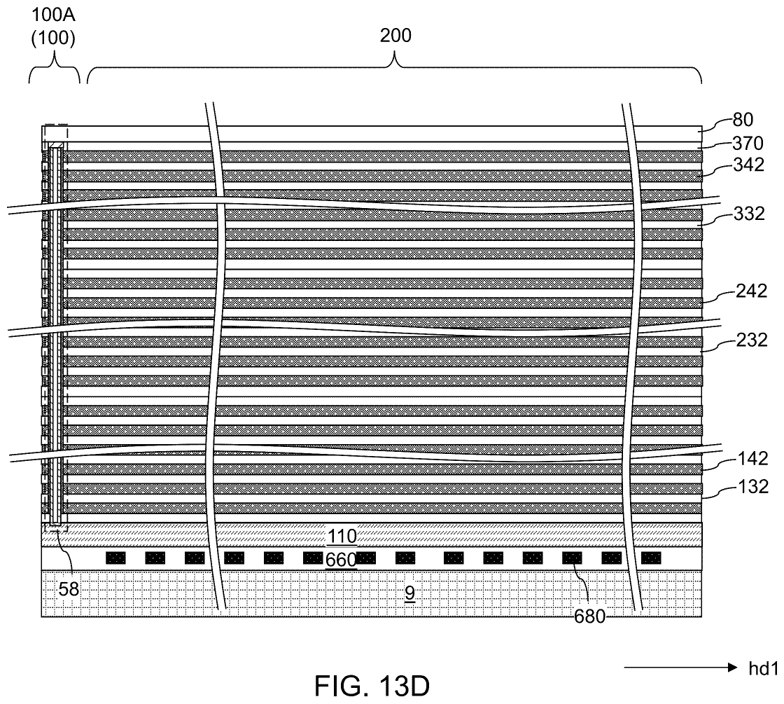

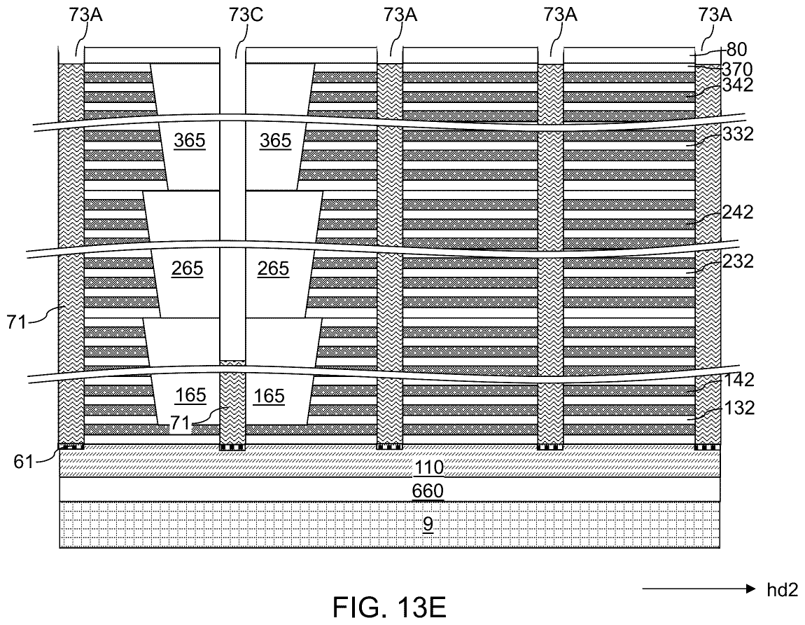

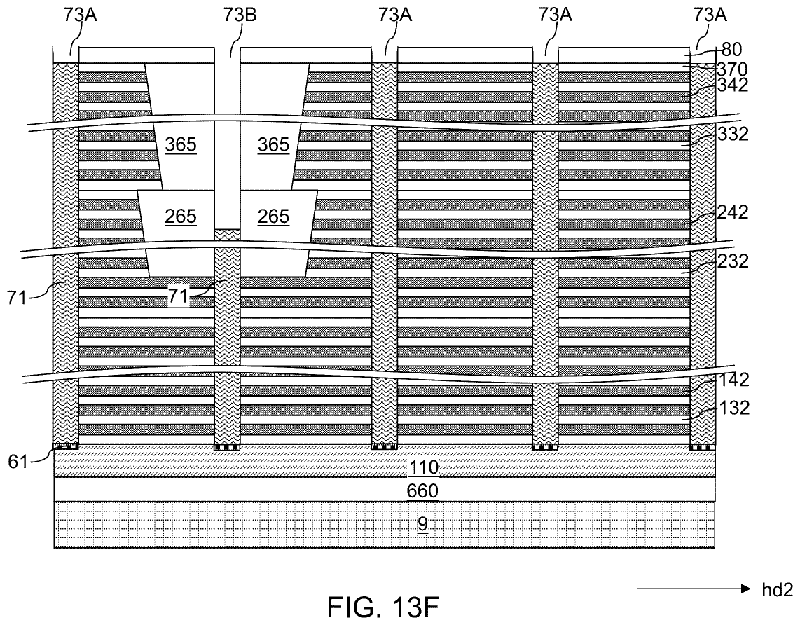

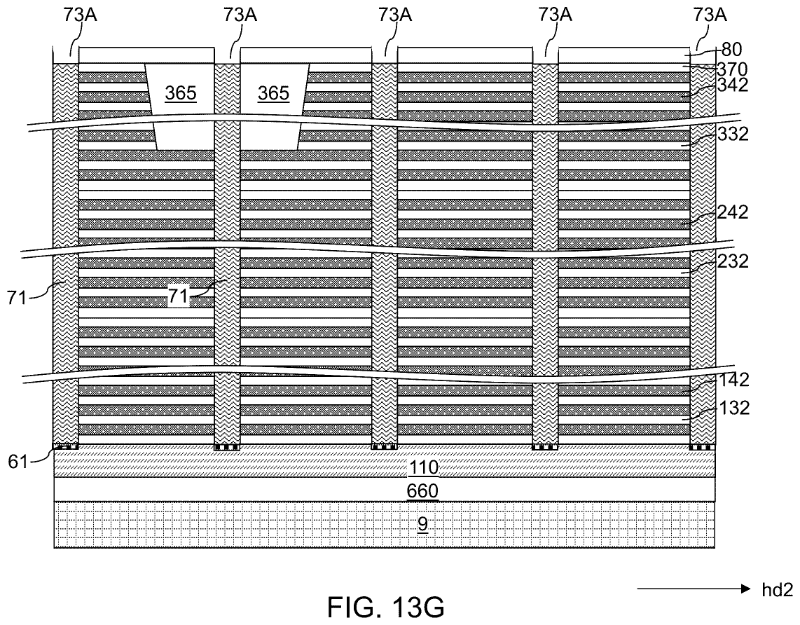

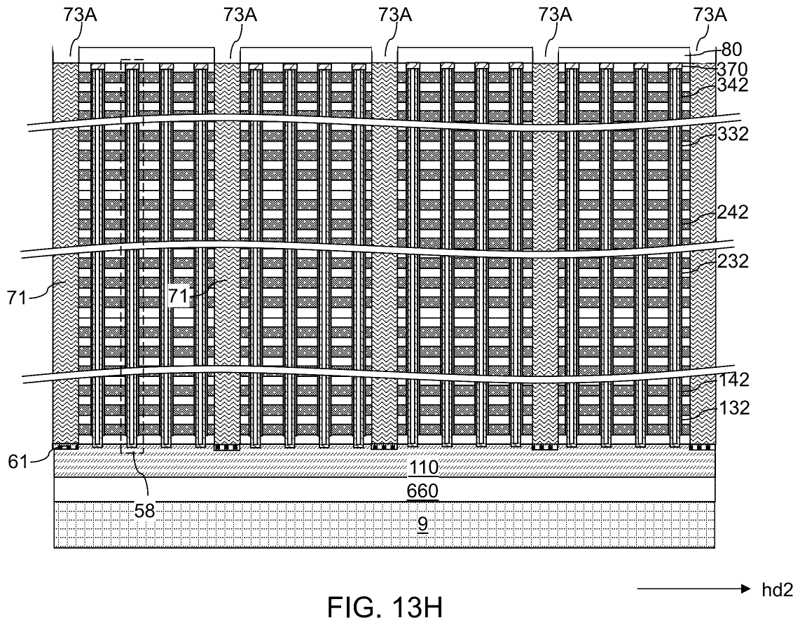

Referring to FIGS. 13A-13H, a third photoresist layer (not shown) can be applied over the contact-level dielectric layer 80 and the sacrificial laterally-extending trench fill structures 71, and can be lithographically patterned to form openings therein. Each opening in the third photoresist layer may overlie an area of a respective second-type recess cavity 73B that is located between stepped bottom surfaces of a respective neighboring pair of first retro-stepped dielectric material layers 165. All recess cavities 73 that are located in the memory array regions 100 can be covered by the third photoresist layer. Further, all recess cavities 73 that are not located between a neighboring pair of first retro-stepped dielectric material portions 165 can be covered by the third photoresist layer.

A third selective recess etch process can be performed to vertically recess a subset of the second-type recess cavities 73B that is not masked by the third photoresist layer. The third selective recess etch process may comprise an anisotropic etch process such as a reactive ion etch process. The third selective recess etch process may vertically extend the unmasked subset of the second-type recess cavities 73B to a depth below the horizontal plane including the top surfaces of the first retro-stepped dielectric material portions 165. Each second-type recess cavity 73B that is vertically extended during the third selective recess etch process is hereafter referred to as a third-type recess cavity 73C.

The duration of the third selective recess etch process can be selected such that each of the third-type recess cavities 73C has a third depth D3 along the vertical direction, as shown in FIG. 13B. Thus, each of the third-type recess cavities 73C may have a respective planar bottom surface that is vertically offset from the first horizontal plane HP1 including the top surface of the contact-level dielectric layer 80 by the third depth D3, which is greater than the second depth D2 and the first depth D1.

In one embodiment, the third depth D3 may be greater than the sum of the thickness of the contact-level dielectric layer 80, the thickness of the insulating cap layer 370, the thickness of a third alternating stack of third insulating layers 332 and third sacrificial material layers 342, and the thickness of a second alternating stack of second insulating layers 232 and second sacrificial material layers 242. Each of the first sacrificial laterally-extending trench fill structures 71A embeds a respective set of first-type recess cavities 73A, at least one second-type recess cavity 73B, and at least one third-type recess cavities 73C. Each of the second sacrificial laterally-extending trench fill structures 71B embeds a respective set of additional first-type recess cavities 73A, but does not embed any second-type recess cavity 73B or any third-type recess cavity 73C. Sidewalls of a pair of third retro-stepped dielectric material portions 365, sidewalls of a pair of second retro-stepped dielectric material portions 265, and upper segments of sidewalls of a pair of first retro-stepped dielectric material portions 165 can be physically exposed to each third-type recess cavity 73C. The third photoresist layer can be subsequently removed, for example, by ashing.

FIGS. 11A-13H illustrate an exemplary embodiment for forming first-type recess cavities 73A, second-type recess cavities 73B, and third-type recess cavities 73C. Generally speaking, any combination of lithographic patterning steps and selective recess etch processes may be employed to provide the exemplary structure illustrated in FIGS. 13A-13H. In a non-limiting example of an alternating sequence of processing steps that provides the exemplary structure of FIGS. 13A-13H from the exemplary structure of FIGS. 10A-10H, the first-type recess cavities 73A may be formed employing a combination of a first lithographic patterning step and a first selective recess etch process that etches only the first-type recess cavities 73A illustrated in FIGS. 13A-13H, the second-type recess cavities 73B may be formed employing a combination of a second lithographic patterning step and a second selective recess etch process that etches only the second-type recess cavities 73B illustrated in FIGS. 13A-13H, and the third-type recess cavities 73C may be formed employing a combination of a third lithographic patterning step and a third selective recess etch process that etches only the third-type recess cavities 73C illustrated in FIGS. 13A-13H. Various other alternative patterning schemes may be employed to form the exemplary structure illustrated in FIGS. 13A-13H.

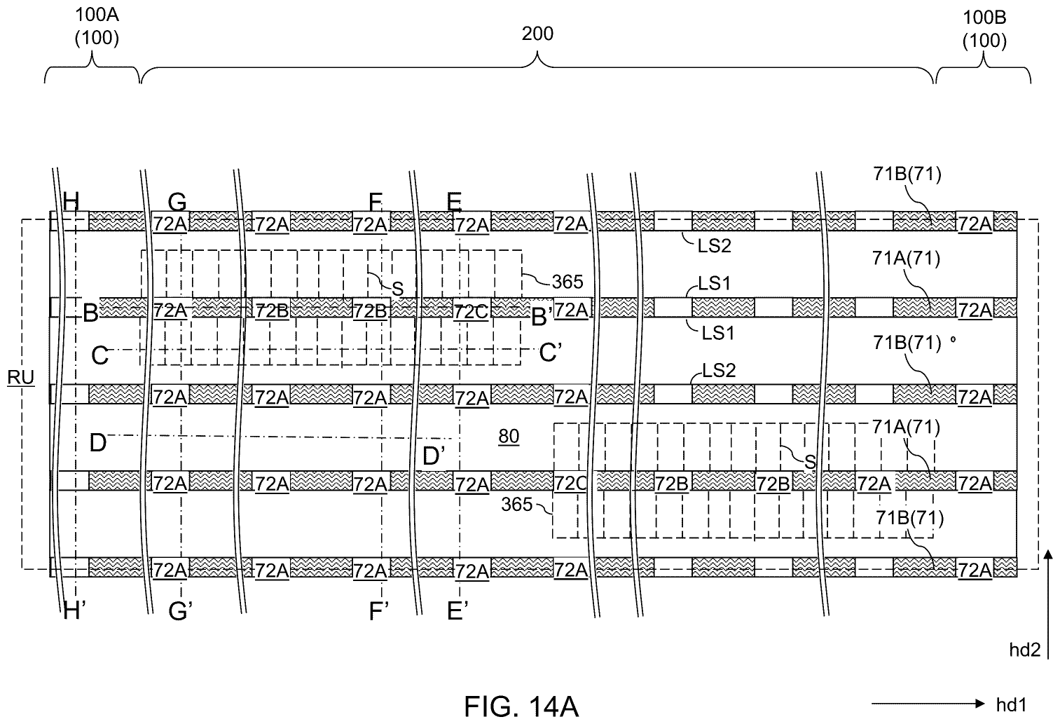

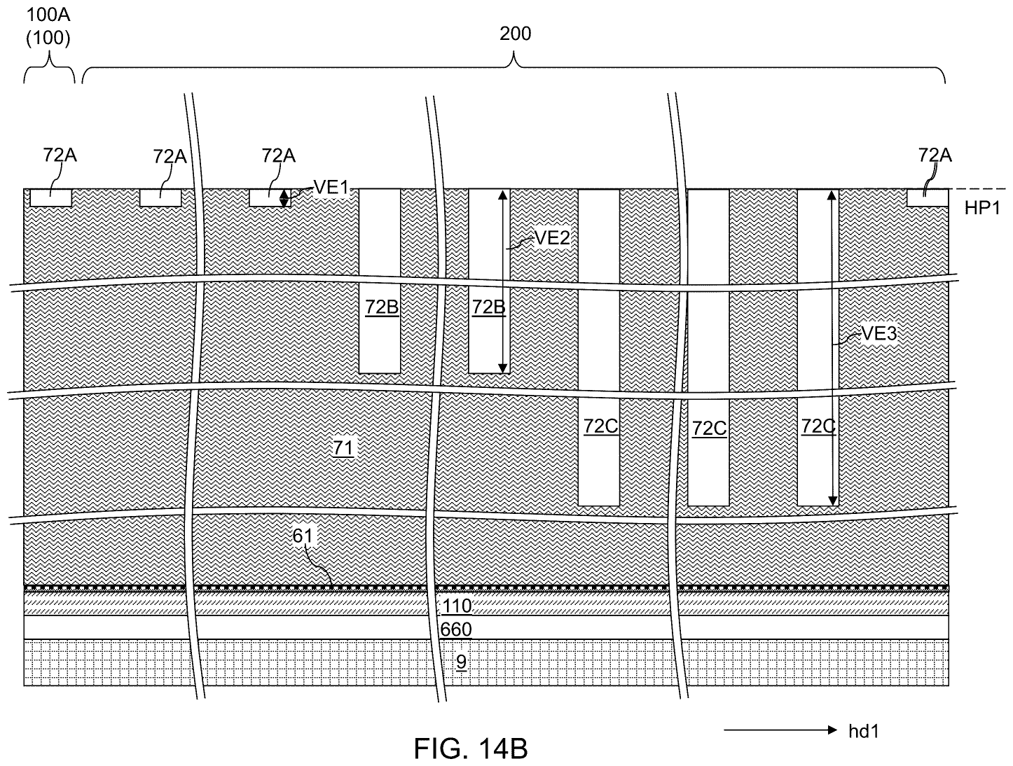

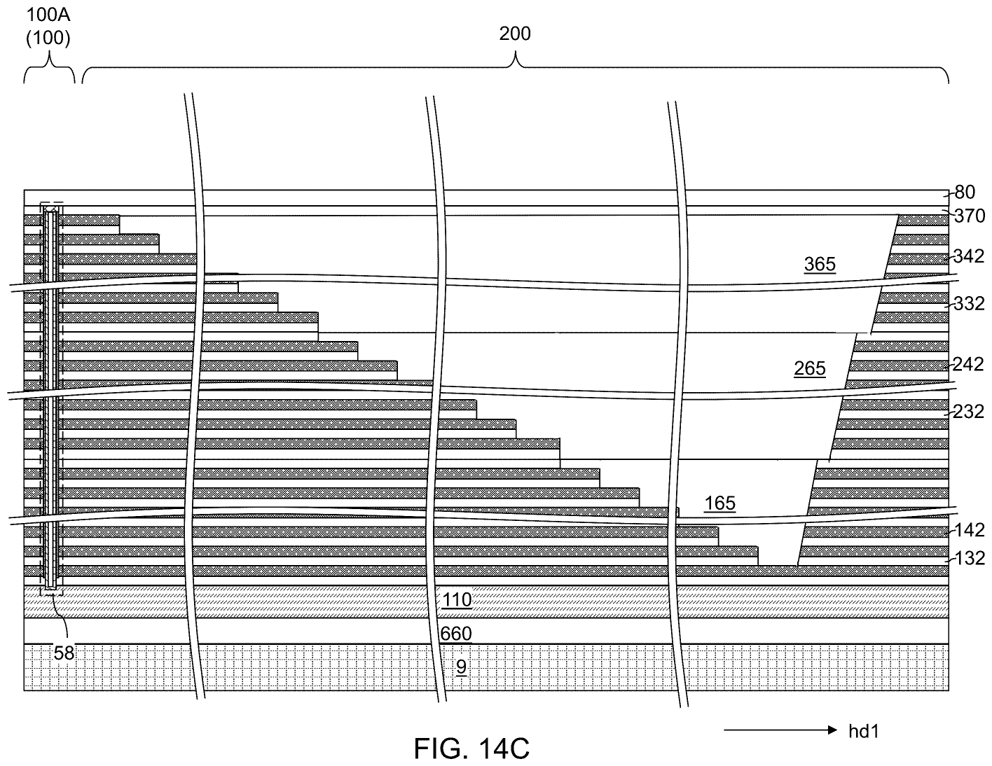

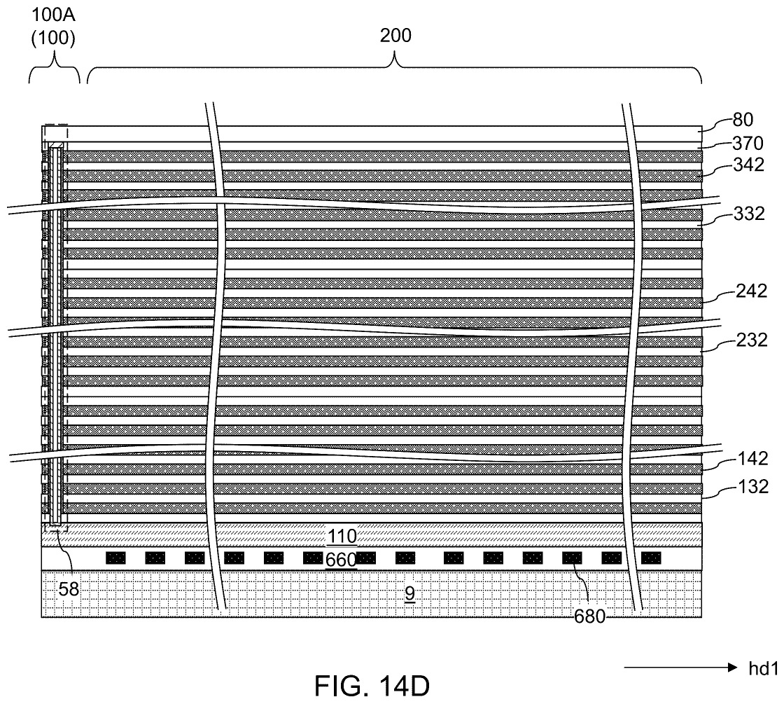

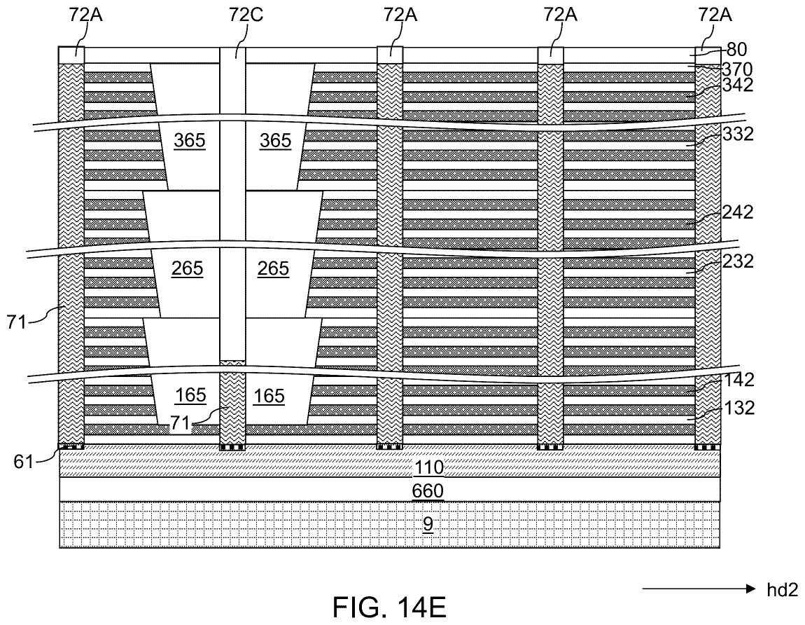

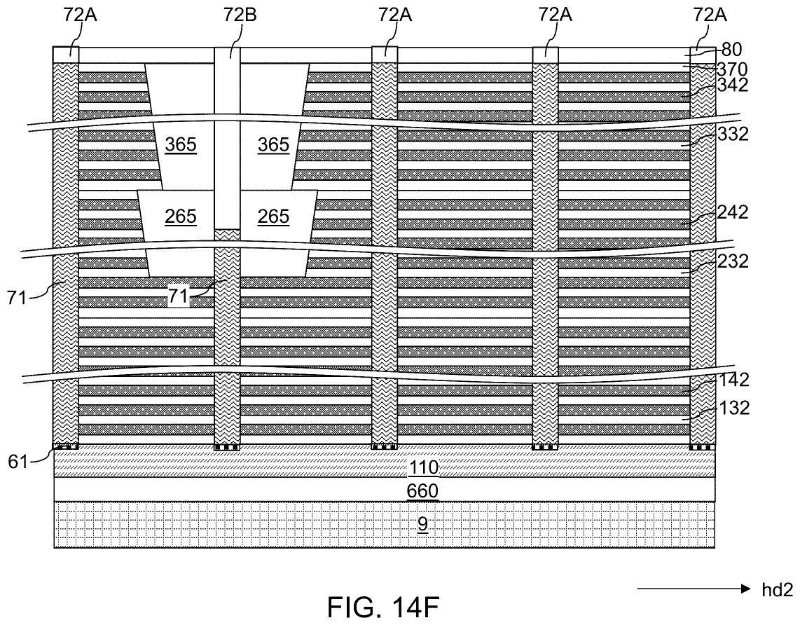

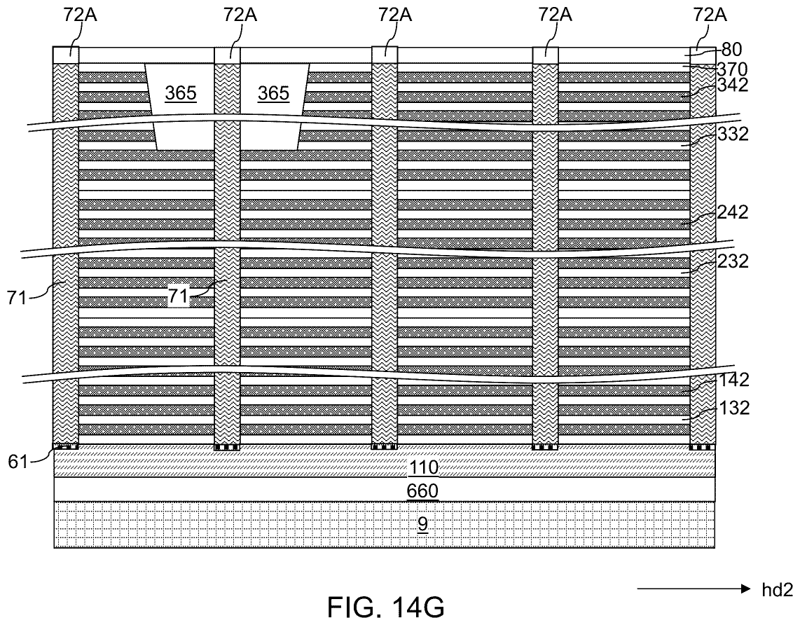

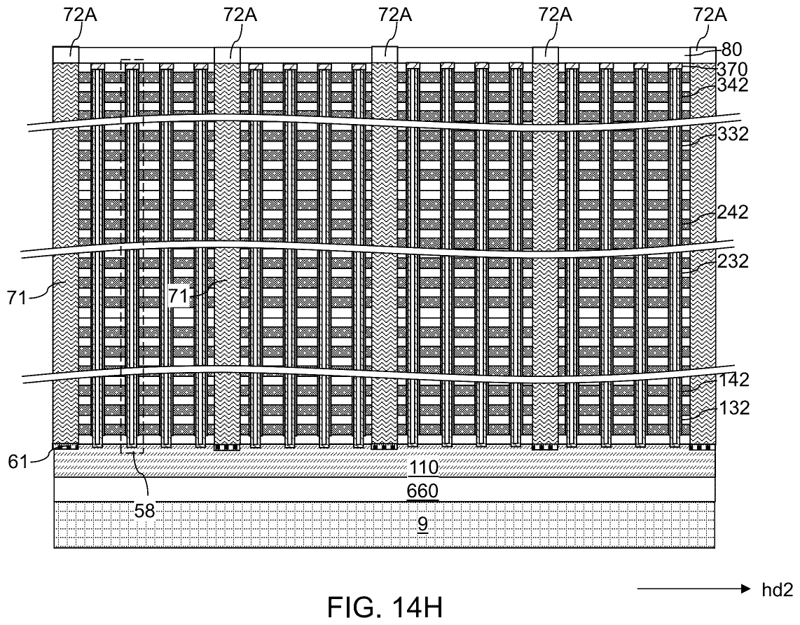

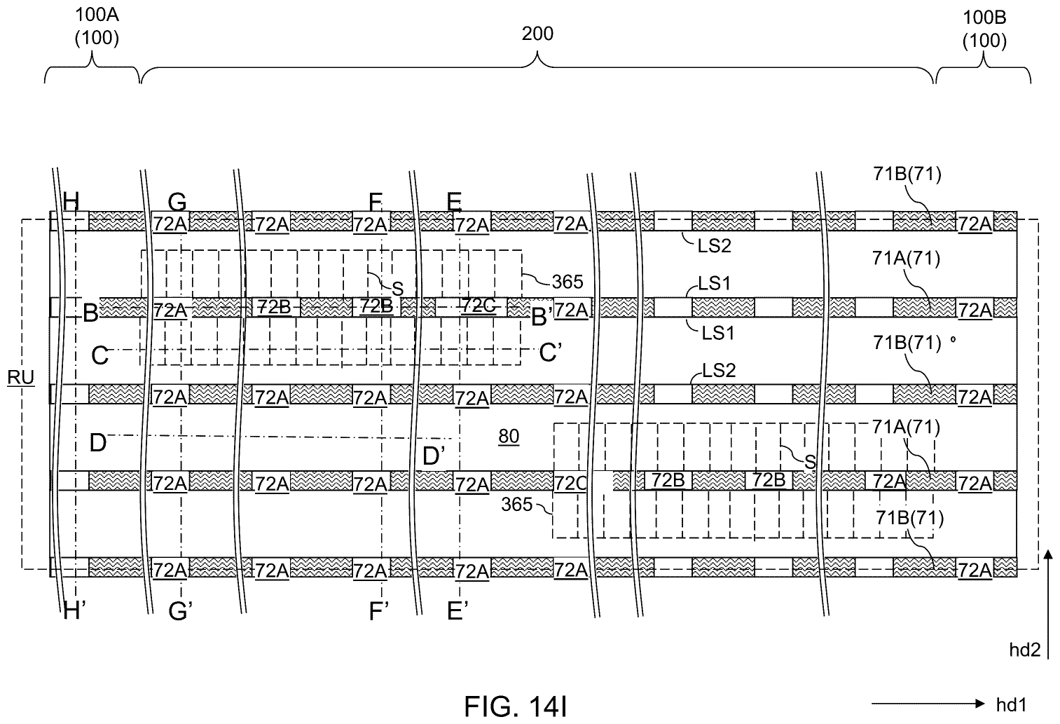

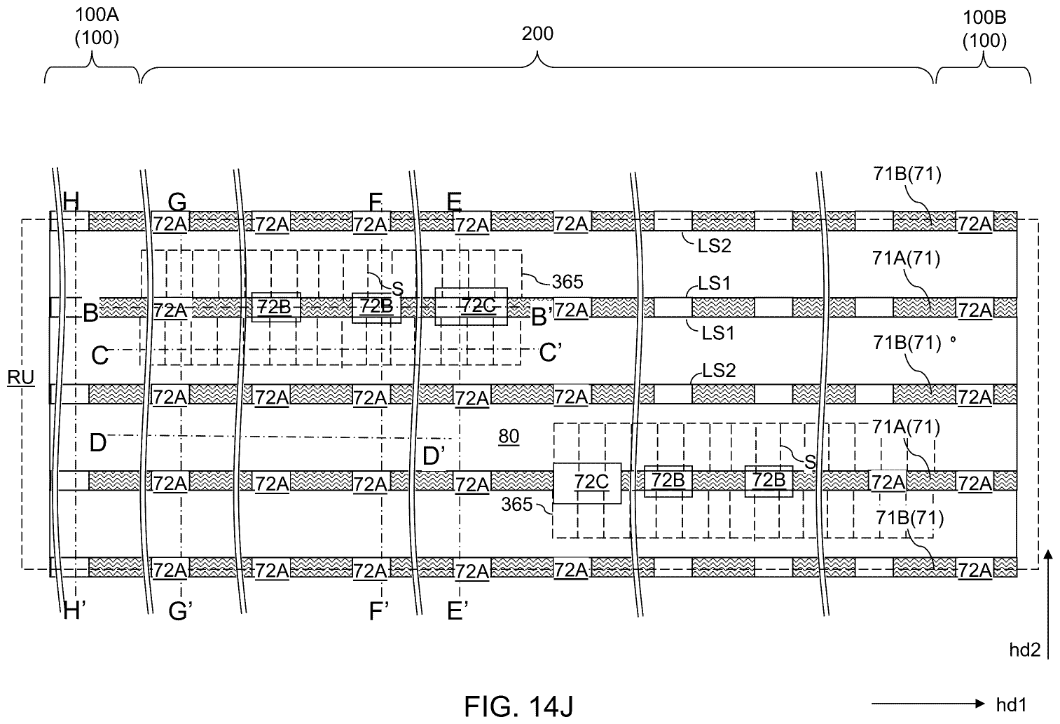

Referring to FIGS. 14A-14H, a dielectric fill material, such as undoped silicate glass (i.e., silicon oxide) or a doped silicate glass, can be deposited in the various recess cavities (73A, 73B, 73C). An optional reflow process may be performed to facilitate gap fill by the dielectric fill material within each of the recess cavities (73A, 73B, 73C). A planarization process can be performed to remove portions of the dielectric fill material that are deposited outside the volumes of the various recess cavities (73A, 73B, 73C). The planarization process may comprise a chemical mechanical polishing (CMP) process and/or a recess etch process. Each remaining portion of the dielectric fill material constitutes a dielectric bridge structure (72A, 72B, 72C).

The dielectric bridge structures (72A, 72B, 72C) comprise first-type dielectric bridge structures 72A that are formed in the first-type recess cavities 73A; second-type dielectric bridge structures 72B that are formed in the second-type recess cavities 73B; and third-type dielectric bridge structures 72C that are formed in the third-type recess cavities 73B. The top surfaces of the dielectric bridge structures (72A, 72B, 72C) may be formed within the first horizontal plane HP1 that contains the top surface of the contact-level dielectric layer 80. Each first-type dielectric bridge structure 72A may have a first vertical extent VE1 that is the same as the first depth D1 of the first-type recess cavities 73A; each second-type dielectric bridge structure 72B may have a second vertical extent VE2 that is the same as the second depth D2 of the second-type recess cavities 73B; and each third-type dielectric bridge structure 72C may have a third vertical extent VE3 that is the same as the third depth D3 of the third-type recess cavities 73C. Thus, the third vertical extent VE3 is greater than the first and second vertical extents (VE1, VE2), and the second vertical extent VE2 may be greater than the first vertical extent VE1. In other words, the third-type dielectric bridge structures 72C are thicker than the first-type and the second-type dielectric bridge structures (72A, 72B) in the vertical direction, and the second-type dielectric bridge structures 72B are thicker than the first-type dielectric bridge structures 72A in the vertical direction.

In an alternative embodiment shown in FIG. 14I, the third-type dielectric bridge structures 72C are longer than the first-type and the second-type dielectric bridge structures (72A, 72B) along the first horizontal direction (e.g., word line direction) hd1, in addition to or instead of being thicker than the first-type and the second-type dielectric bridge structures (72A, 72B). The second-type dielectric bridge structures 72B are longer than the first-type dielectric bridge structures 72A along the first horizontal direction hd1, in addition to or instead of being thicker than the first-type dielectric bridge structures 72A.

In another alternative embodiment shown in FIG. 14J, the third-type dielectric bridge structures 72C are wider than the first-type and the second-type dielectric bridge structures (72A, 72B) along the second horizontal direction (e.g., bit line direction) hd2, in addition to or instead of being thicker and/or longer than the first-type and the second-type dielectric bridge structures (72A, 72B). The second-type dielectric bridge structures 72B are wider than the first-type dielectric bridge structures 72A along the second horizontal direction hd2, in addition to or instead of being thicker and/or longer than the first-type dielectric bridge structures 72A.

Generally, the third-type dielectric bridge structures 72C have a greater volume than the first-type and the second-type dielectric bridge structures (72A, 72B). The second-type dielectric bridge structures 72B have a greater volume than the first-type dielectric bridge structures 72A. The greater volume may be due to any combination of at least one of a greater thickness, length and/or width.

In one embodiment, each of the first-type dielectric bridge structure 72A, the second-type dielectric bridge structure 72B, and the third-type dielectric bridge structure 72C contacts a respective pair of sidewalls of the contact-level dielectric layer 80. The first-type dielectric bridge structures 72A may optionally contact sidewalls of the insulating cap layer 370. In one embodiment, the first-type dielectric bridge structures 72A do not contact any of the sacrificial material layers (142, 242, 342) or the insulating layers (132, 232, 332).

Each of the second-type dielectric bridge structures 72B and the third-type dielectric bridge structures 72C contacts a respective pair of sidewalls of the insulating cap layer 370, a respective pair of sidewalls of the third retro-stepped dielectric material portions 365, and a respective pair of sidewalls of the second retro-stepped dielectric material portions 265. The second-type dielectric bridge structures 72B do not contact any of the first retro-stepped dielectric material portions 165. Each of the third-type dielectric bridge structure 72C contacts a respective pair of sidewalls of the first retro-stepped dielectric material portions 165.

Generally, the bottom surface of each first-type dielectric bridge structure 72A is formed above a horizontal plane including a top surface of a topmost sacrificial material layer of the sacrificial material layers (142, 242, 342). The bottom surface of each second-type dielectric bridge structure 72B is formed below the horizontal plane including the top surface of the topmost sacrificial material layer 242. The bottom surface of each third-type dielectric bridge structure 72C is formed below the horizontal plane including the top surface of the topmost sacrificial material layer 142. The first-type dielectric bridge structures 72A do not contact any of the at least one retro-stepped dielectric material portion (165, 265, 365). The second-type dielectric bridge structures 72B and the third-type dielectric bridge structures 72C can be formed directly on sidewalls of a pair of contiguous dielectric portions including at least one retro-stepped dielectric material portion (165, 265, 365) (such as a respective vertical stack of a first retro-stepped dielectric material portion 165, a second retro-stepped dielectric material portion 265, and a third retro-stepped dielectric material portion 365).

In one embodiment, each first-type dielectric bridge structure 72A can have a first top surface located within the first horizontal plane HP1 and having a first bottom surface that is vertically spaced from the first horizontal plane HP1 by a first vertical distance (such as the first vertical extent VE1); each second-type dielectric bridge structure 72B can have a second top surface located within the first horizontal plane HP1 and having a second bottom surface that is vertically spaced from the first horizontal plane HP1 by a second vertical distance (such as the second vertical extent VE2) greater than the first vertical distance; and each third-type dielectric bridge structure 72C can have a third top surface located within the first horizontal plane HP1 and having a third bottom surface that is vertically spaced from the first horizontal plane HP1 by a third vertical distance (such as the third vertical extent VE3) greater than the first and second vertical distances.

While three different type of dielectric bridge structures for a three-tier memory device are described in the above embodiment, in alternative embodiments, the memory device may contain only two types or more than three types of dielectric bridge structures. It should be noted that the boundary between different type of dielectric bridge structures can vary and does not necessarily correspond to the boundary of stair tier, and can varied within each tier, as long as the bottom of surface does not extend over an active word line. In another embodiment, the pitch (e.g., the bridge length and space between bridges) can also vary.

Each sacrificial laterally-extending trench fill structure 71 located within a first laterally-extending trench 79A embeds a row of first-type dielectric bridge structures 72A, at least one second-type dielectric bridge structure 72B, and optionally at least one third-type dielectric bridge structure 72C. Each first-type dielectric bridge structure 72A is not in direct contact with any of the retro-stepped dielectric material portions (165, 265, 365). Each sacrificial laterally-extending trench fill structure 71 located within a second laterally-extending trench 79B embeds a respective set of additional first-type dielectric bridge structures 72A, but does not embed any second-type dielectric bridge structure 72B or any third-type dielectric bridge structure 72C. Each additional first-type dielectric bridge structure 72A is not in direct contact with any of the retro-stepped dielectric material portions (165, 265, 365).

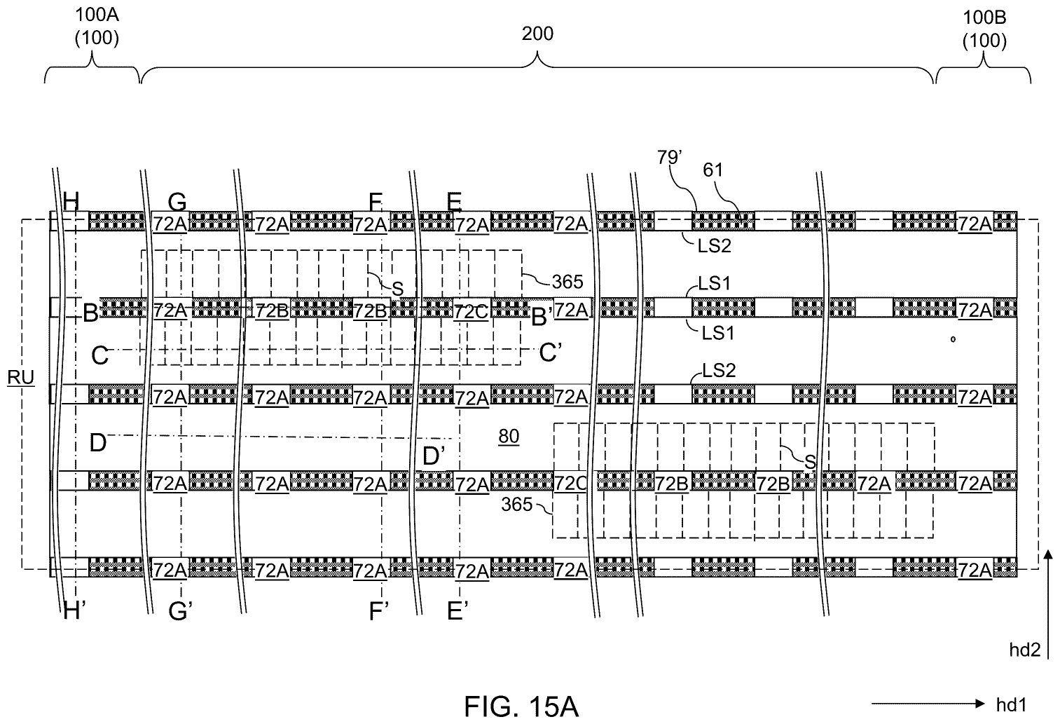

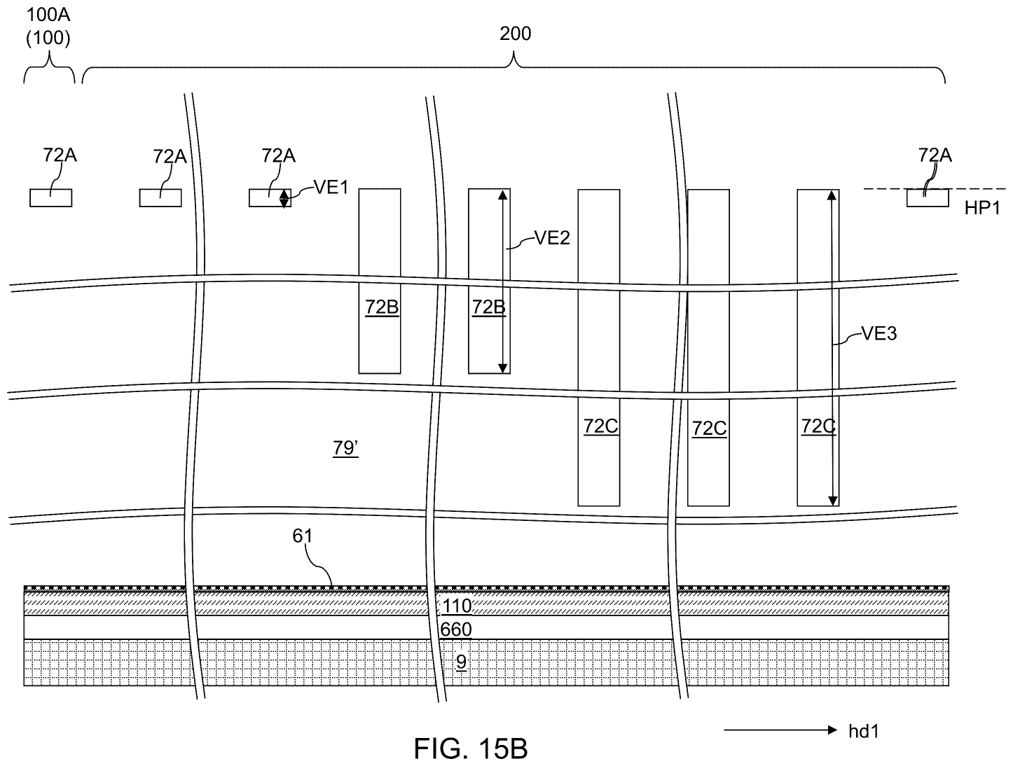

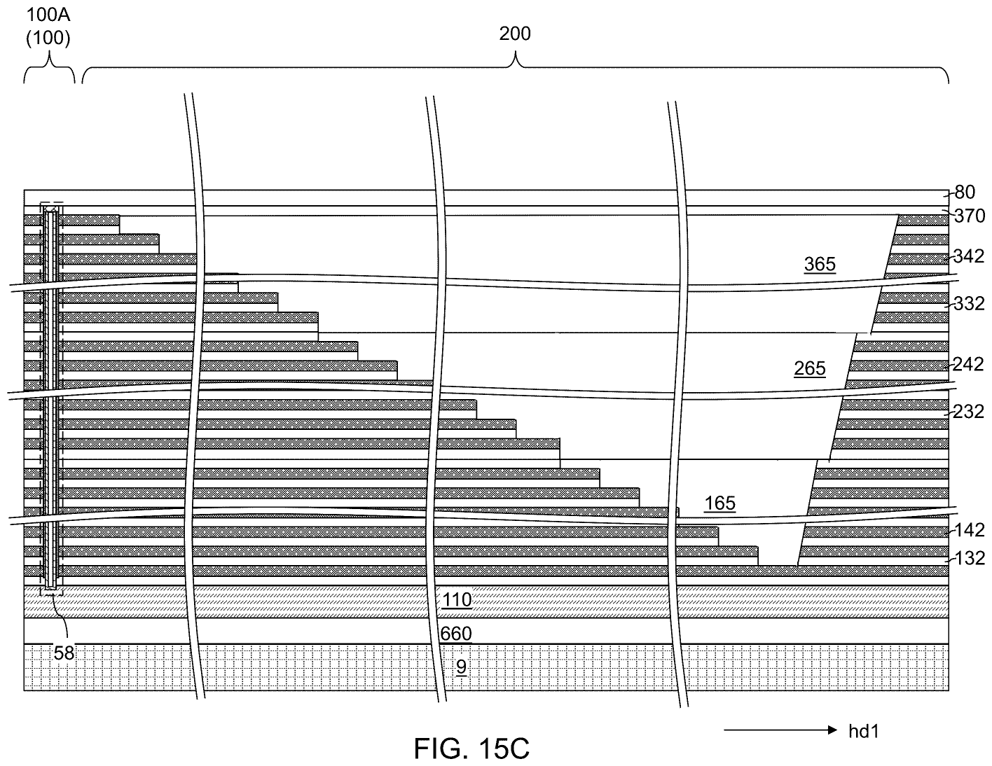

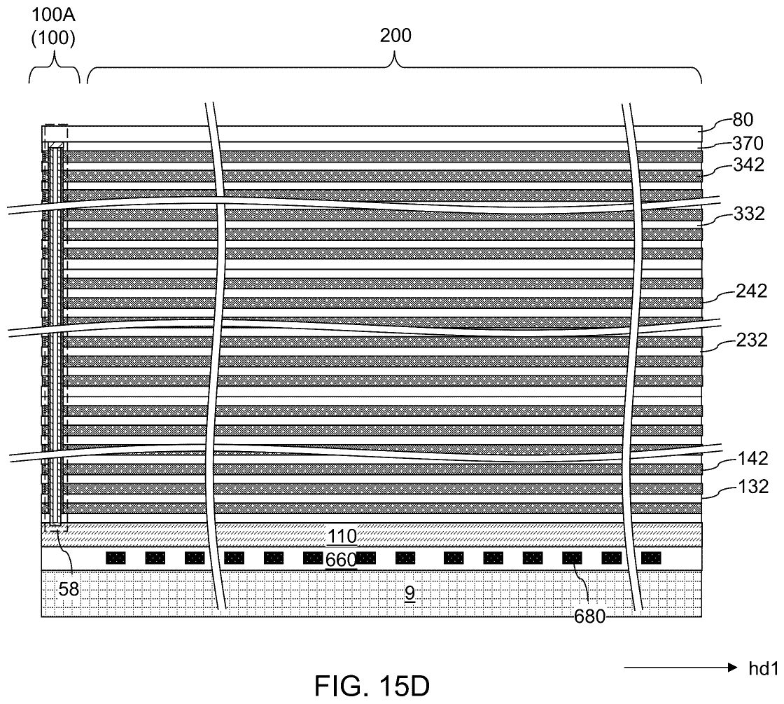

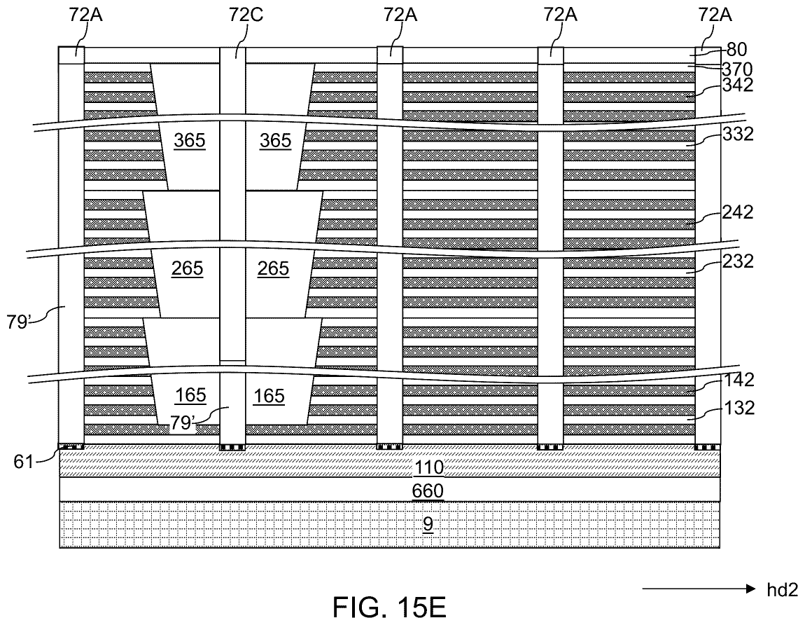

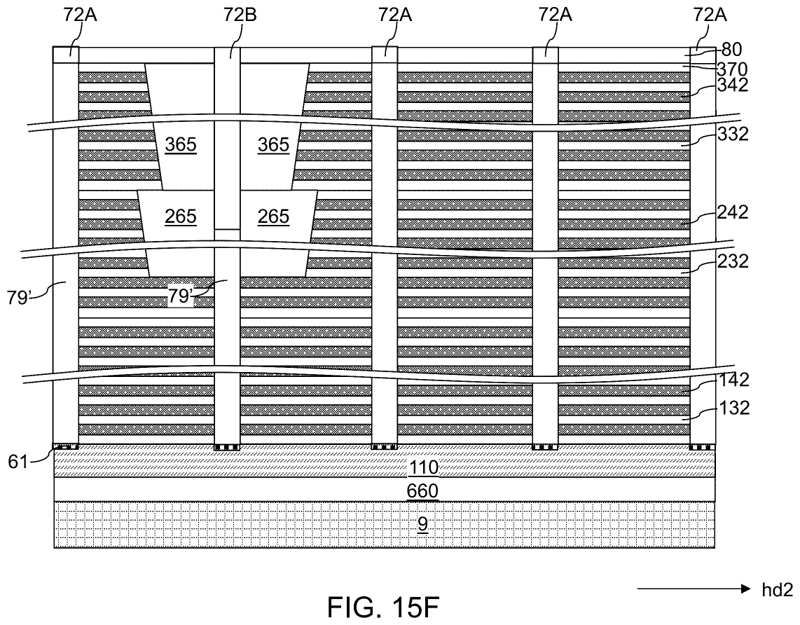

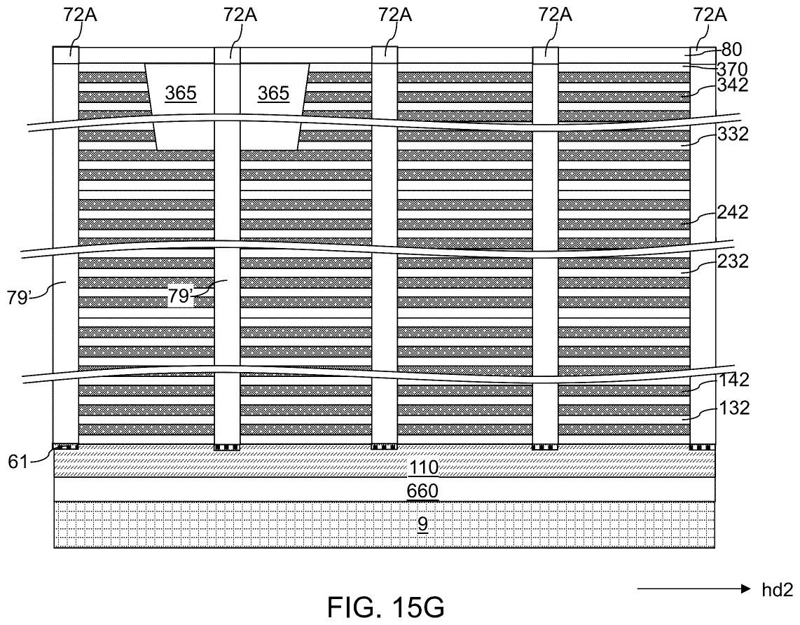

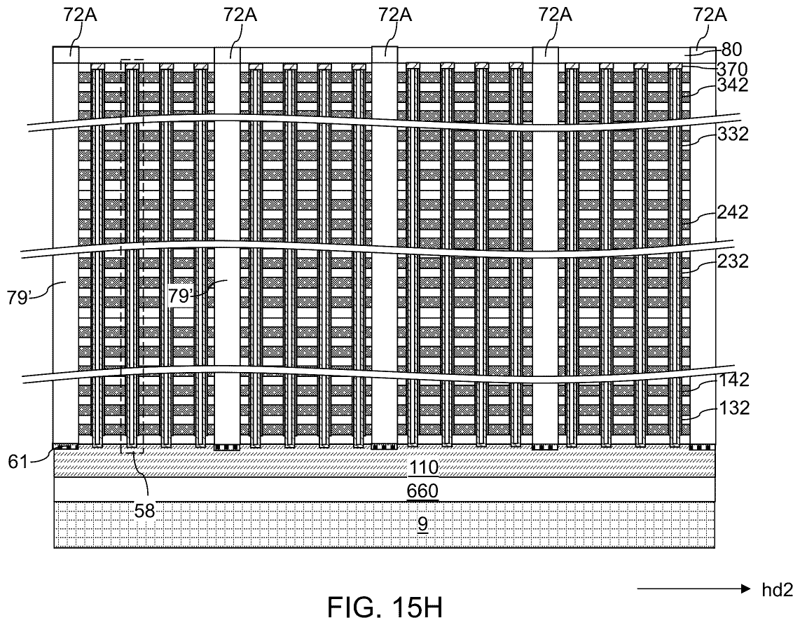

Referring to FIGS. 15A-15H, the sacrificial fill material of the sacrificial laterally-extending trench fill structures 71 can be removed selective to the materials of the various dielectric bridge structures (72A, 72B, 72C), the alternating stacks {(132, 142), (232, 242), (332, 342)}, and the semiconductor material layer 110 (if present) (and the source regions 61 if present) by performing an isotropic removal process. For example, if the sacrificial fill material comprises a carbon-based material, the isotropic removal process may comprise an ashing process. If the sacrificial fill material comprises a semiconductor material, a dielectric material, or a polymer material, the isotropic removal process may comprise an isotropic etch process such as a wet etch process. For example, if the sacrificial laterally-extending trench fill structures 71 comprise a semiconductor material, such as amorphous silicon, the isotropic etch process may include a wet etch process employing hot trimethyl-2 hydroxyethyl ammonium hydroxide (“hot TMY”) or tetramethyl ammonium hydroxide (TMAH). In one embodiment, the sacrificial laterally-extending trench fill structures 71 can include an undoped semiconductor material or a lightly doped semiconductor material, and the wet etch process employing hot TMY or TMAH can etch the undoped or lightly doped semiconductor material of the sacrificial laterally-extending trench fill structures 71 selective to the heavily doped semiconductor material of the source regions 61. A laterally-extending cavity 79′ is present within the volume of each laterally-extending trench 79 that is not filled by the dielectric bridge structures (72A, 72B, 72C). The dielectric bridge structures (72A, 72B, 72C) are suspended over the laterally-extending cavities 79′.

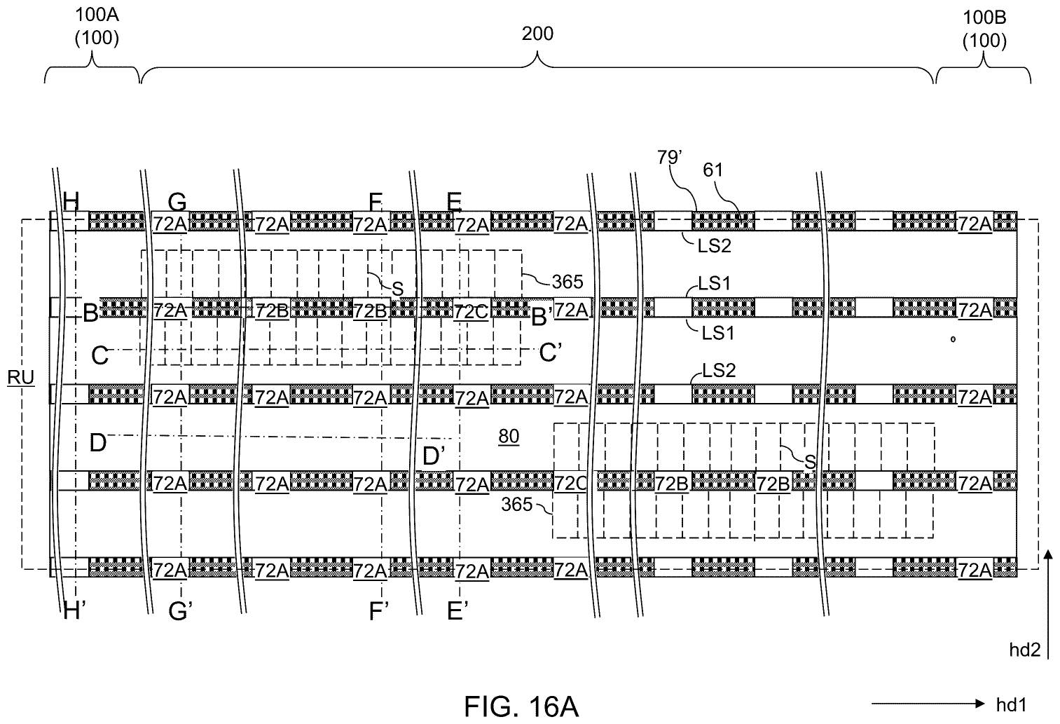

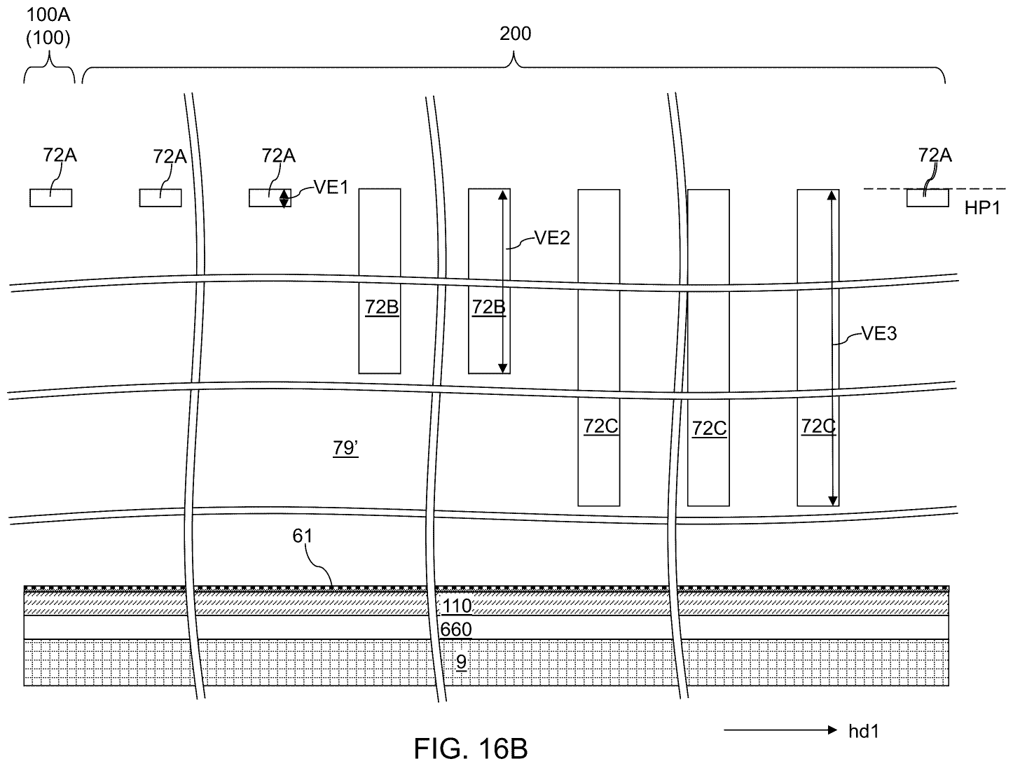

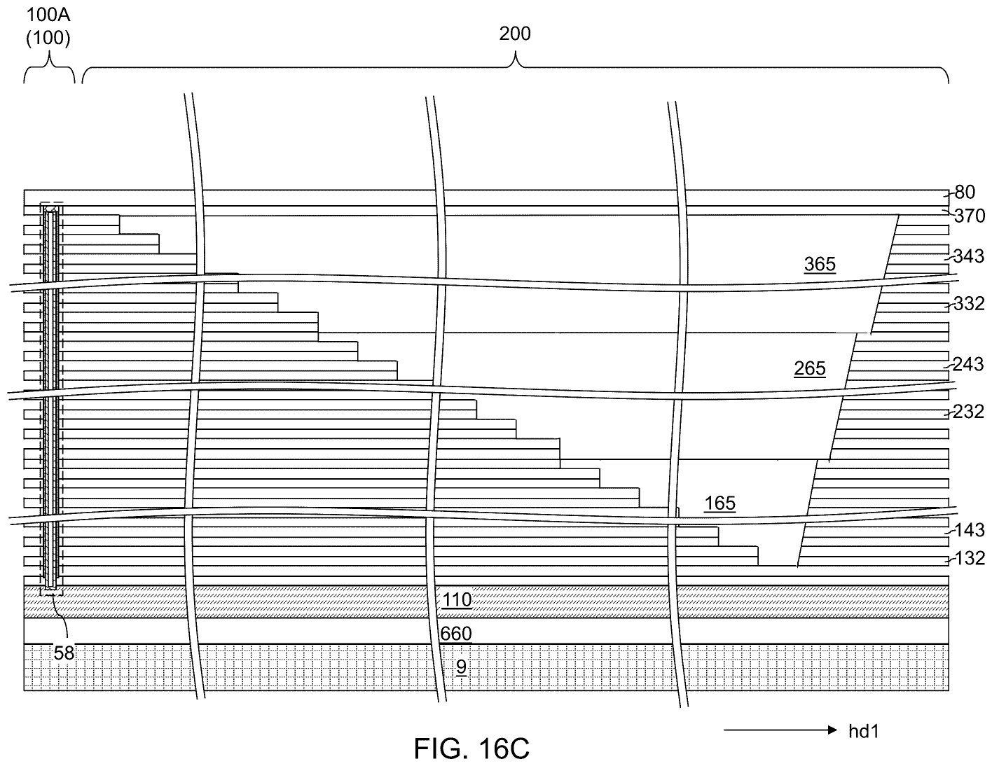

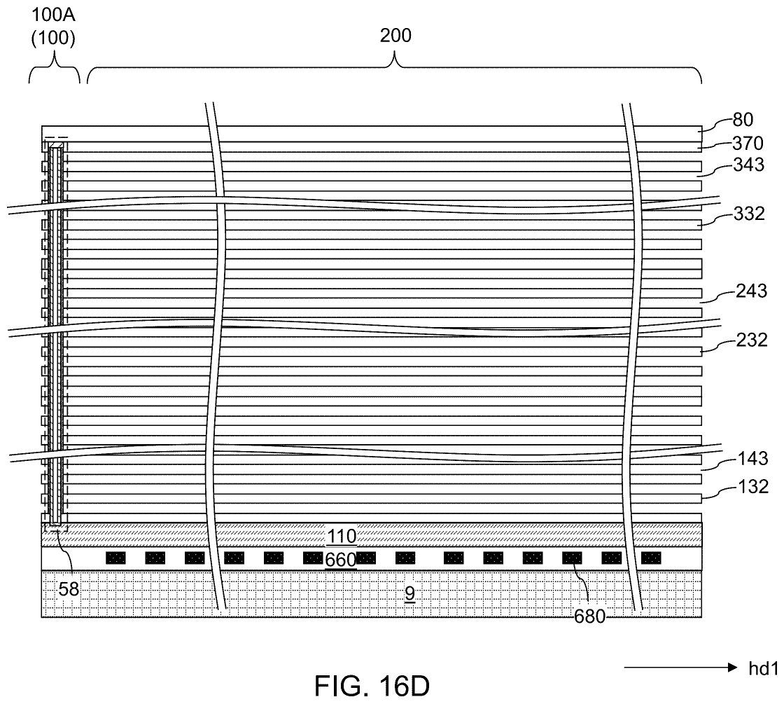

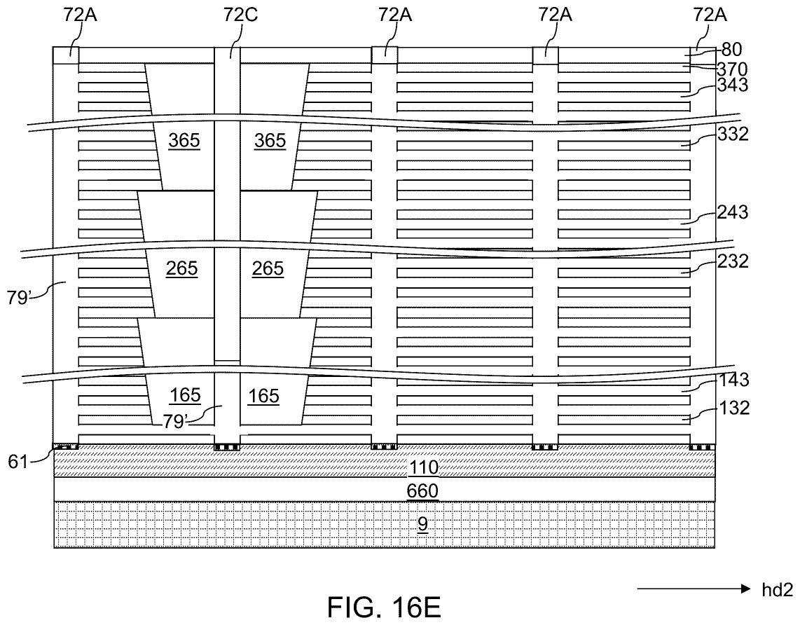

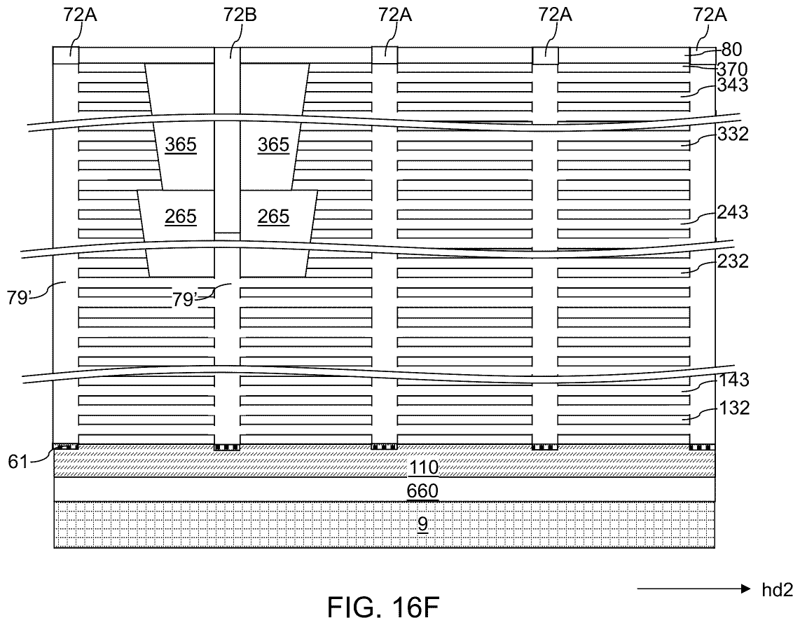

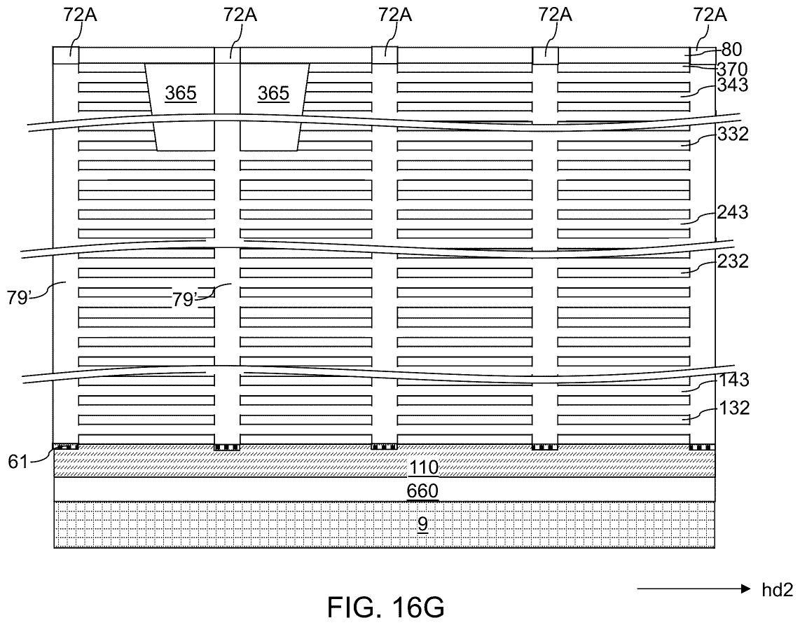

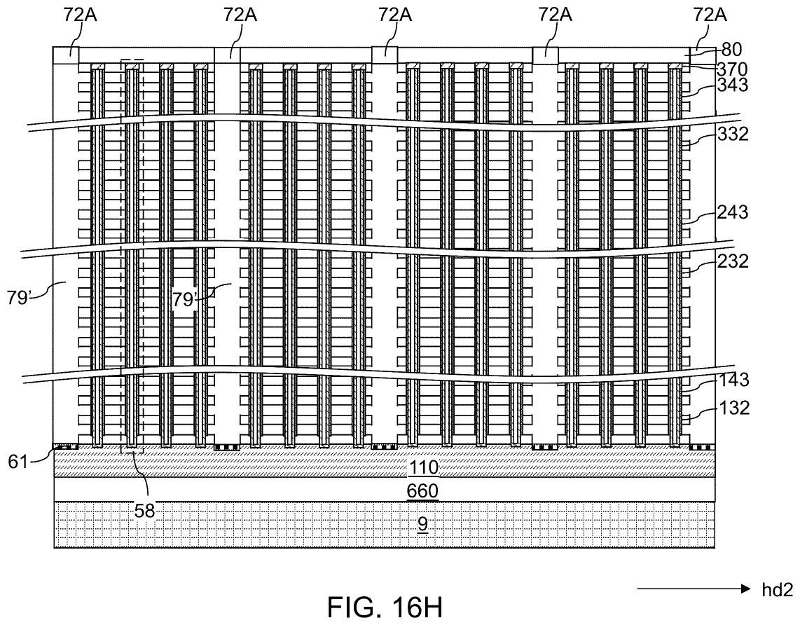

Referring to FIGS. 16A-16H, the sacrificial material layers (142, 242, 342) may be isotropically etched selective to the insulating layers (132, 232, 332), the dielectric bridge structures (72A, 72B, 72C), and the retro-stepped dielectric material portions (165, 265, 365) (and the semiconductor material layer 110 and the source regions 61 if present) by supplying an isotropic etchant into the laterally-extending trenches 79.

For example, an etchant that selectively etches the materials of the sacrificial material layers (142, 242, 342) with respect to the materials of the insulating layers (132, 232, 332), the retro-stepped dielectric material portions (165, 265, 365), the dielectric bridge structures (72A, 72B, 72C), and the material of the outermost layer of the memory films 50 may be introduced into the laterally-extending trenches, for example, using an isotropic etch process.

The isotropic etch process may be a wet etch process using a wet etch solution, or may be a gas phase (dry) etch process in which the etchant is introduced in a vapor phase into the laterally-extending trench. For example, if the sacrificial material layers (142, 242, 342) comprise silicon nitride, the materials of the insulating layers (132, 232, 332), the retro-stepped dielectric material portions (165, 265, 365), the dielectric bridge structures (72A, 72B, 72C), and the outermost layer of the memory films 50 comprise silicon oxide, then the etch process may be a wet etch process in which the exemplary structure is immersed within a wet etch tank including phosphoric acid, which etches silicon nitride selective to silicon oxide, silicon, and various other materials used in the art.

Lateral recesses (143, 243, 343) are formed in volumes from which the sacrificial material layers (142, 242, 342) are removed. The lateral recesses (143, 243, 343) include first lateral recesses 143 that are formed in volumes from which the first sacrificial material layers 142 are removed, second lateral recesses 243 that are formed in volumes from which the second sacrificial material layers 242 are removed, and third lateral recesses 343 that are formed in volumes from which the third sacrificial material layers 342 are removed. Each of the lateral recesses (143, 243, 343) may be a laterally extending cavity having a lateral dimension that is greater than the vertical extent of the cavity. In other words, the lateral dimension of each of the lateral recesses (143, 243, 343) may be greater than the height of the respective lateral recess. A plurality of lateral recesses (143, 243, 343) may be formed in the volumes from which the material of the sacrificial material layers (142, 242, 342) is removed. Each of the lateral recesses (143, 243, 343) may extend substantially parallel to the top surface of the semiconductor material layer 110 (if present, or another underlying layer or the substrate 9). A lateral recess (143, 243, 343) may be vertically bounded by a top surface of an underlying insulating layer (132, 232, 332) and a bottom surface of an overlying insulating layer (132, 232, 332). In one embodiment, each of the lateral recesses (143, 243, 343) may have a uniform height throughout.

The dielectric bridge structures (72A, 72B, 72C) provide lateral structural support between neighboring pairs of contiguous structures including the insulating layers (132, 232, 332) and the memory opening fill structures 58 that are laterally spaced from each other by a respective laterally-extending trench 79. The smaller volume first-type dielectric bridge structures 72A provide lateral support along the second horizontal direction at the level of the contact-level dielectric layer 80. In one embodiment, the larger volume second-type dielectric bridge structures 72B and the third-type dielectric bridge structures 72C directly contact sidewalls of a respective neighboring pair of retro-stepped dielectric material portions (165, 265, 365).

The larger volume second-type dielectric bridge structures 72B and the third-type dielectric bridge structures 72C provide additional structural support at the levels the deeper portions of the stepped surfaces (i.e., staircases), where tilting and incline of the insulating layers (132, 232, 332) into the laterally-extending trenches 79 is more likely, especially in an asymmetric structure shown in FIG. 16A, where the staircases are located on both sides of some but not other laterally-extending trenches 79. Furthermore, since the stresses on the dielectric bridge structures may be greater at the deeper portions of the staircases, the larger volume of the second-type dielectric bridge structures 72B and the third-type dielectric bridge structures 72C reduce the likelihood that such bridge structures crack under the stresses. Still further, since only the lower sacrificial material layers (e.g., 142) have to be replaced with electrically conductive layers at the deeper portions of the staircases, the larger volumes of the second-type dielectric bridge structures 72B and the third-type dielectric bridge structures 72C do not significantly interfere with the replacement process.

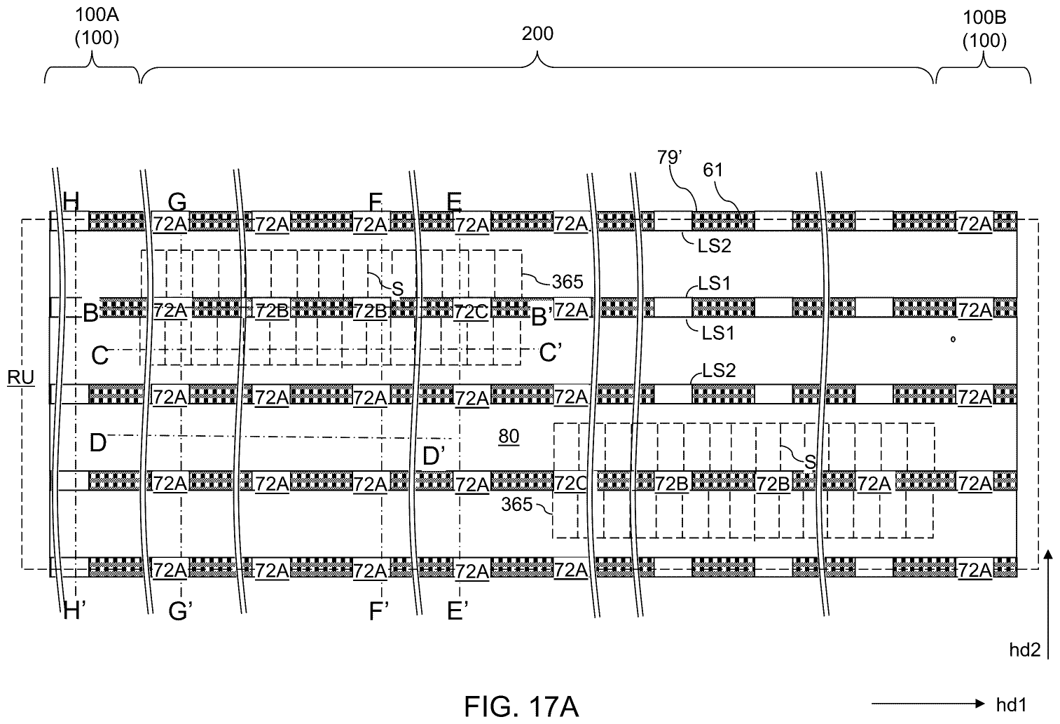

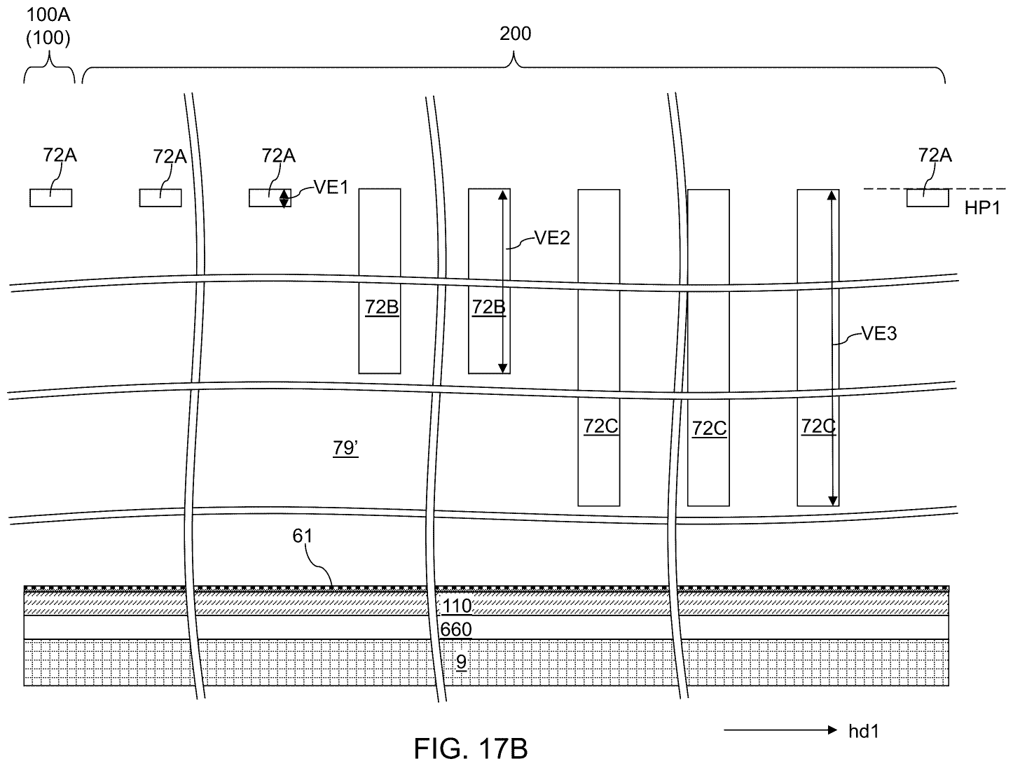

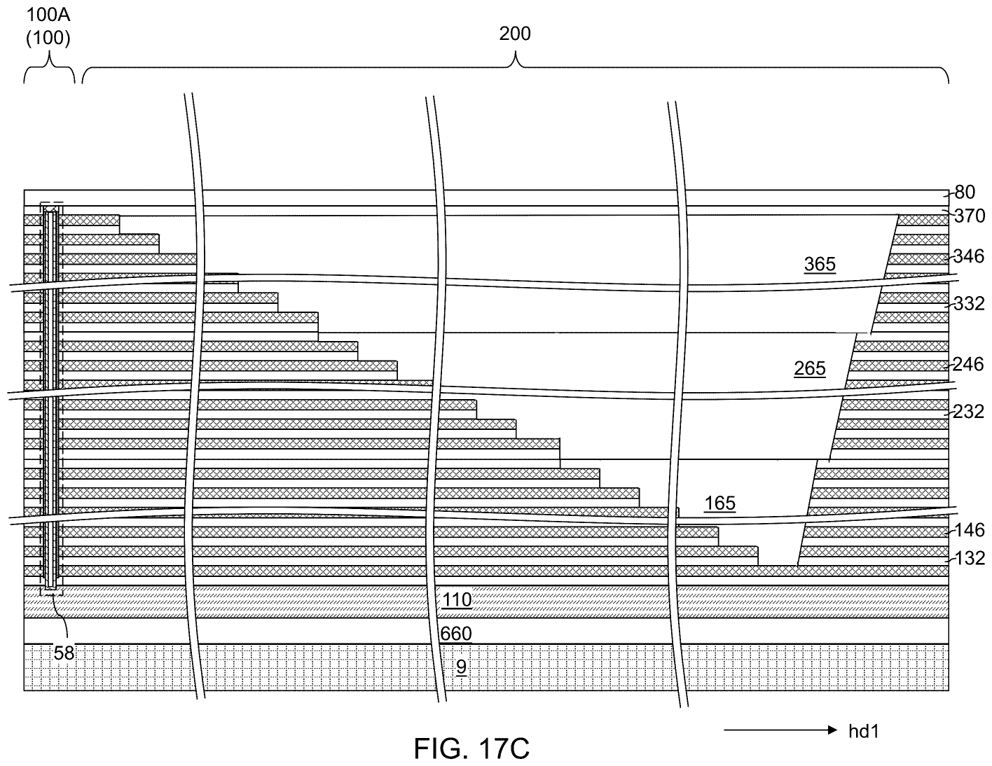

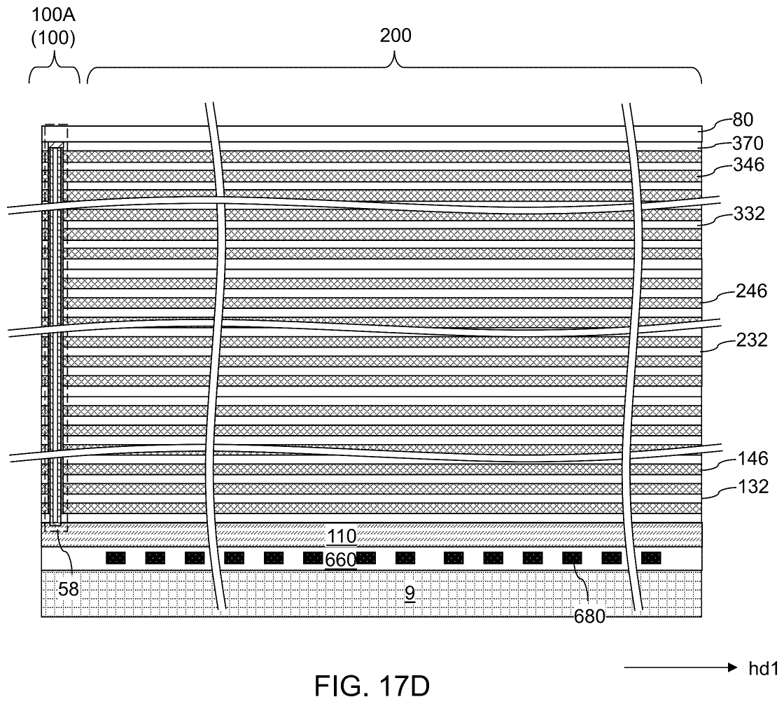

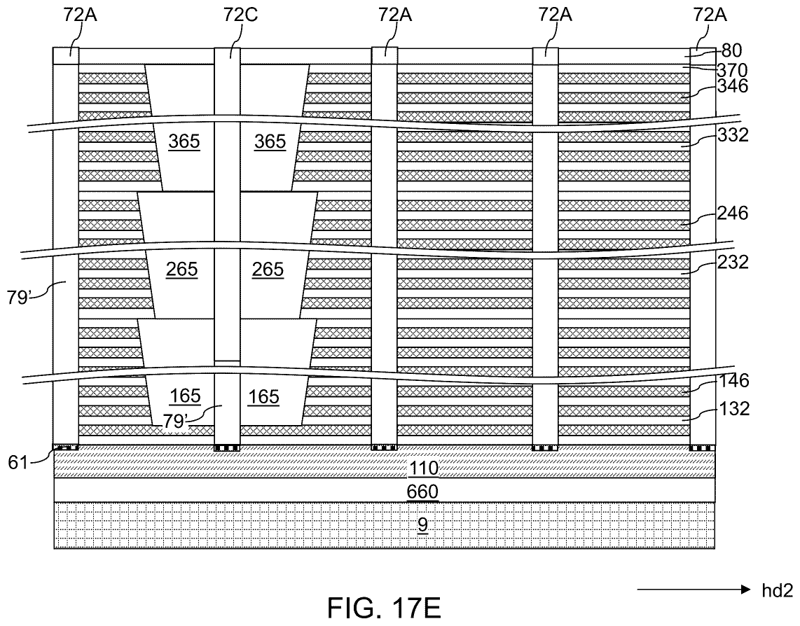

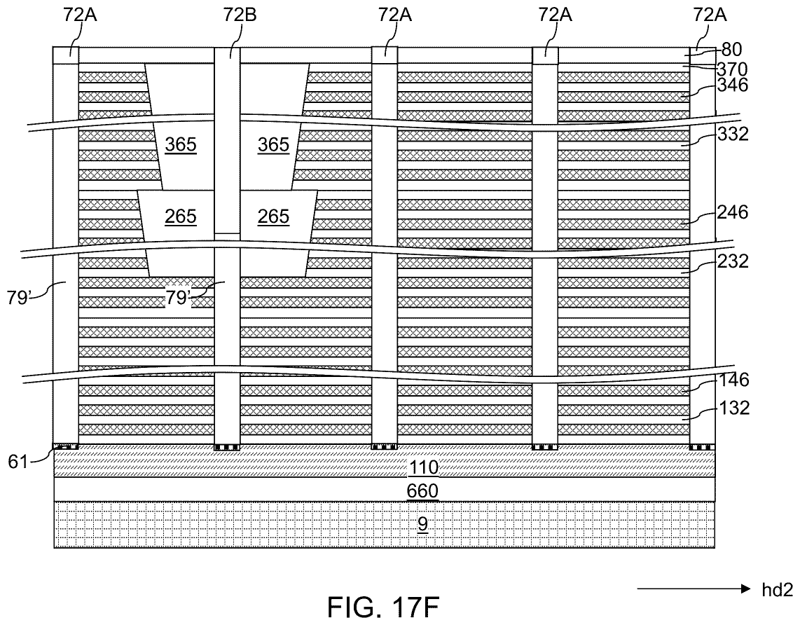

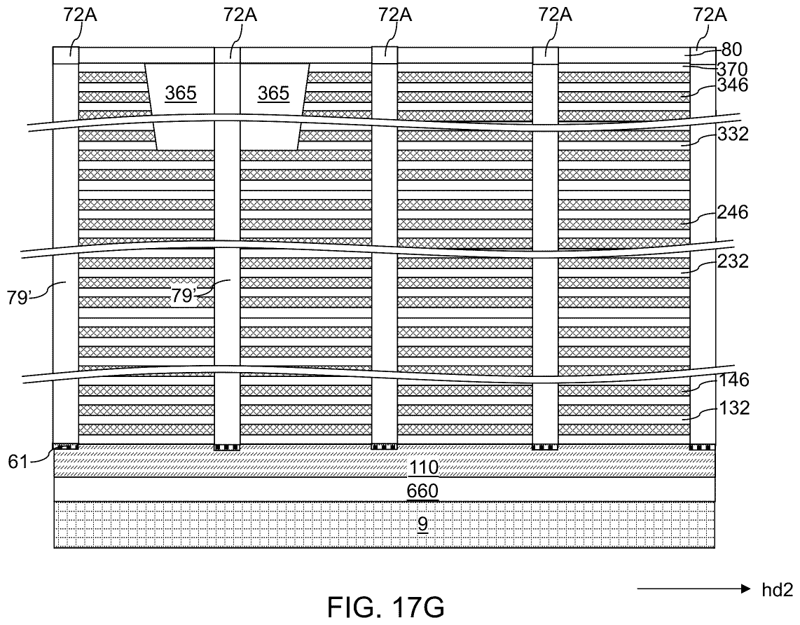

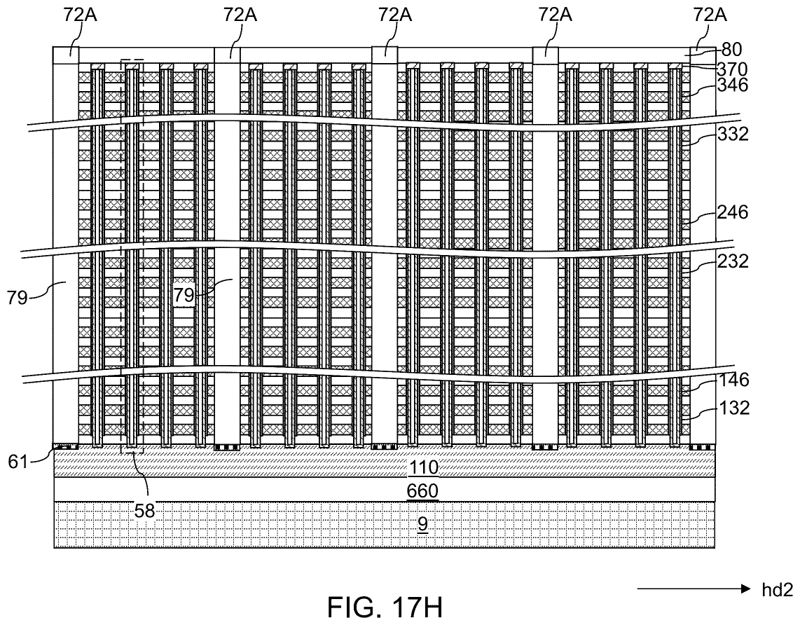

Referring to FIGS. 17A-17H, an optional backside blocking dielectric layer (not shown) may be optionally deposited in the lateral recesses (143, 243, 343) and the laterally-extending trenches. The backside blocking dielectric layer includes a dielectric material such as a dielectric metal oxide (e.g., aluminum oxide), silicon oxide, or a combination thereof.

Electrically conductive layers (146, 246, 346) may be deposited in remaining volumes of the lateral recesses (143, 243, 343) by performing a conformal deposition process in which a precursor gas for a conductive material of the electrically conductive layers (146, 246, 346) is supplied into the lateral recesses (143, 243, 343) through the laterally-extending trenches 79. At least one conductive material may be deposited in the plurality of lateral recesses (143, 243, 343), on the sidewalls of the laterally-extending trenches, and over the topmost tier structure. The at least one conductive material may be deposited by a conformal deposition method, which may be, for example, chemical vapor deposition (CVD), atomic layer deposition (ALD), electroless plating, electroplating, or a combination thereof. The at least one conductive material may include an elemental metal, an alloy of at least two elemental metals, a conductive nitride of at least one elemental metal, a conductive metal oxide, a conductive doped semiconductor material, a conductive metal-semiconductor compound such as a metal silicide, and combinations or stacks thereof.

In one embodiment, the at least one conductive material may include at least one metal element, such as include tungsten, tungsten nitride, titanium, titanium nitride, tantalum, tantalum nitride, molybdenum, cobalt, or ruthenium. For example, the at least one conductive material may include a conductive metallic nitride liner that includes a conductive metallic nitride material such as TiN, TaN, WN, MON or a combination thereof, and a conductive fill material such as W, Co, Ru, Mo, Cu, or combinations thereof. In one embodiment, the at least one conductive material for filling the lateral recesses (143, 243, 343) may be a combination of titanium nitride layer and a tungsten fill material.

A plurality of first electrically conductive layers 146 may be formed in the plurality of first lateral recesses 143, a plurality of second electrically conductive layers 246 may be formed in the plurality of second lateral recesses 243, a plurality of third electrically conductive layers 346 may be formed in the plurality of third lateral recesses 343, and a continuous electrically conductive material layer (not shown) may be formed on the sidewalls of each laterally-extending trench and over the topmost tier structure. Each of the electrically conductive layers (146, 246, 346) may include a respective conductive metallic nitride liner and a respective conductive fill material. Thus, the sacrificial material layers (142, 242, 342) may be replaced with the electrically conductive layers (146, 246, 346), respectively. Specifically, each first sacrificial material layer 142 may be replaced with an optional portion of the backside blocking dielectric layer and a first electrically conductive layer 146, each second sacrificial material layer 242 may be replaced with an optional portion of the backside blocking dielectric layer and a second electrically conductive layer 246, and each third sacrificial material layer 342 may be replaced with an optional portion of the backside blocking dielectric layer and a third electrically conductive layer 346. A backside cavity is present in the portion of each laterally-extending trench that is not filled with the continuous metallic material layer.

Residual conductive material may be removed from inside the laterally-extending trenches 79 and from above the plurality of tier structures. Specifically, the deposited conductive material may be etched back from the sidewalls of each laterally-extending trench and from above the topmost tier structure, for example, by performing an isotropic etch process. Each remaining portion of the deposited conductive material in the first lateral recesses constitutes a first electrically conductive layer 146. Each remaining portion of the deposited conductive material in the second lateral recesses constitutes a second electrically conductive layer 246. Each remaining portion of the deposited conductive material in the third lateral recesses constitutes a third electrically conductive layer 346. Sidewalls of the electrically conductive layers (146, 246, 346) may be physically exposed to a respective laterally-extending trench 79.

Each electrically conductive layer (146, 246, 346) may be a conductive sheet including openings therein. A first subset of the openings through each electrically conductive layer (146, 246, 346) may be filled with memory opening fill structures 58. A second subset of the openings through each electrically conductive layer (146, 246, 346) may be filled with the support pillar structures 20.

At least one uppermost electrically conductive layer 346 may comprise a drain side select gate electrode, and at least one lowermost electrically conductive layer 146 may comprise a source side select gate electrode. A middle subset of the electrically conductive layers (146, 246, 346) located between the select gate electrodes may comprise word lines for the memory elements (e.g., memory cells). If a peripheral circuit 920 is located on the substrate 9 below or next to the memory-level assembly, then it may comprise word line switch devices configured to control a bias voltage to respective word lines, and/or bit line driver devices, such as sense amplifiers. The memory-level assembly is located over the substrate semiconductor layer 9. The memory-level assembly includes at least one alternating stack {(132, 146), (232, 246), (332, 346)} of insulating layers (132, 232, 332) and electrically conductive layers (146, 246, 346), and memory stack structures 55 vertically extending through the at least one alternating stack {(132, 146, 232, 246, 332, 346)}. Each of the memory stack structures 55 comprises a vertical stack of memory elements (e.g., portions of the memory film 50) located at each level of the electrically conductive layers (146, 246, 346).

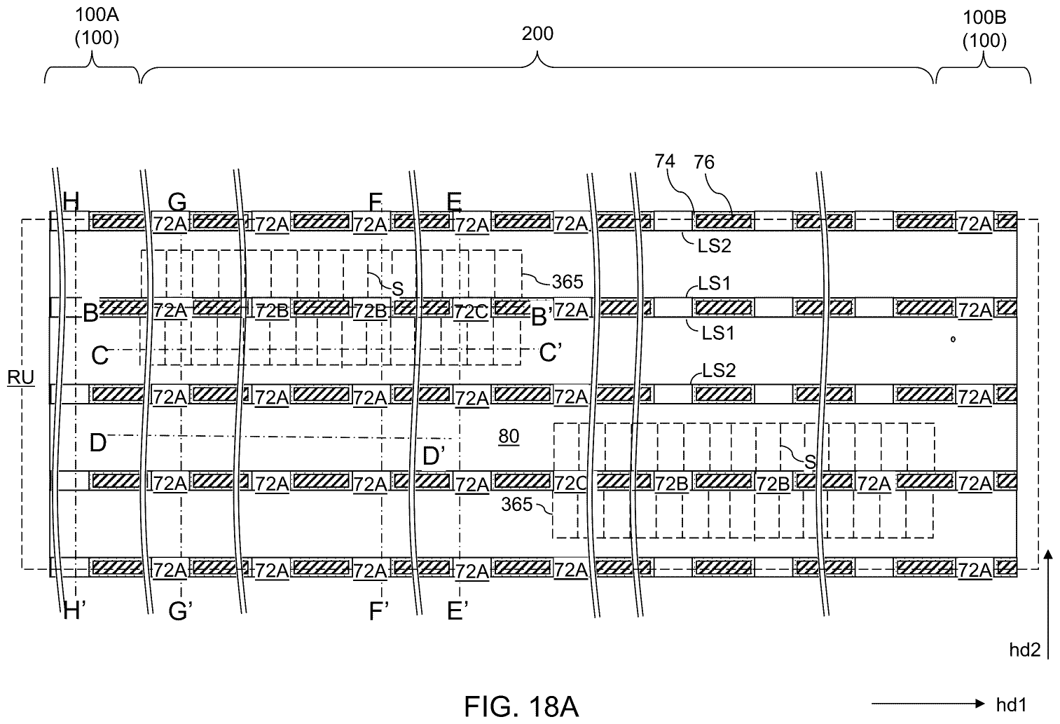

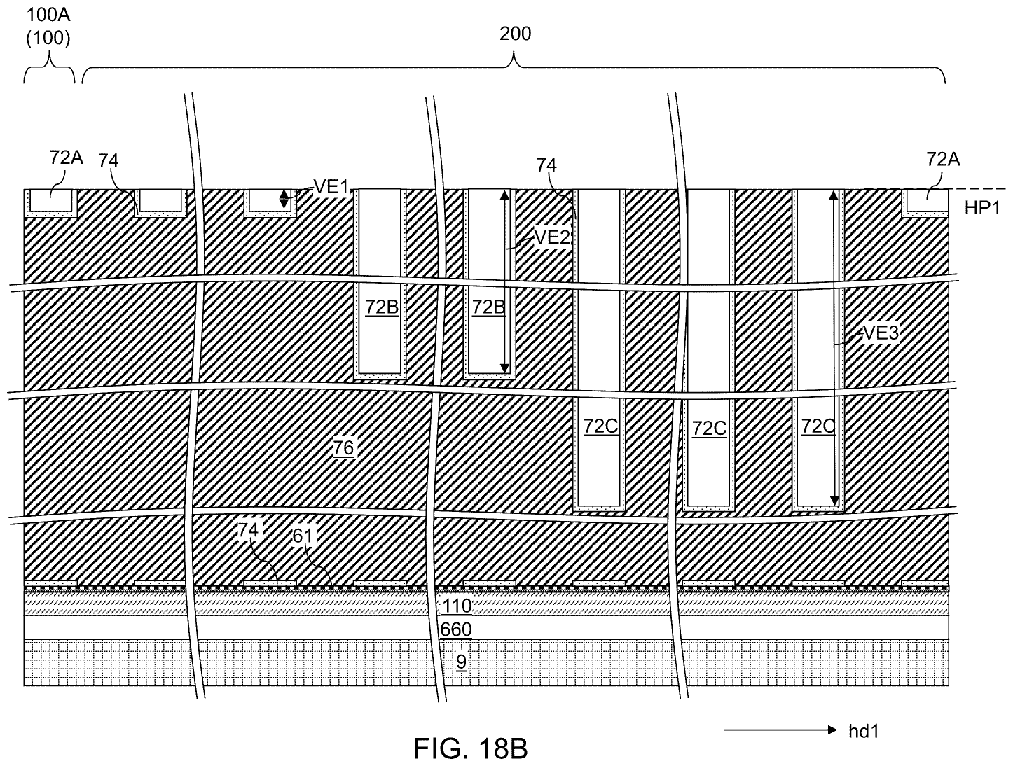

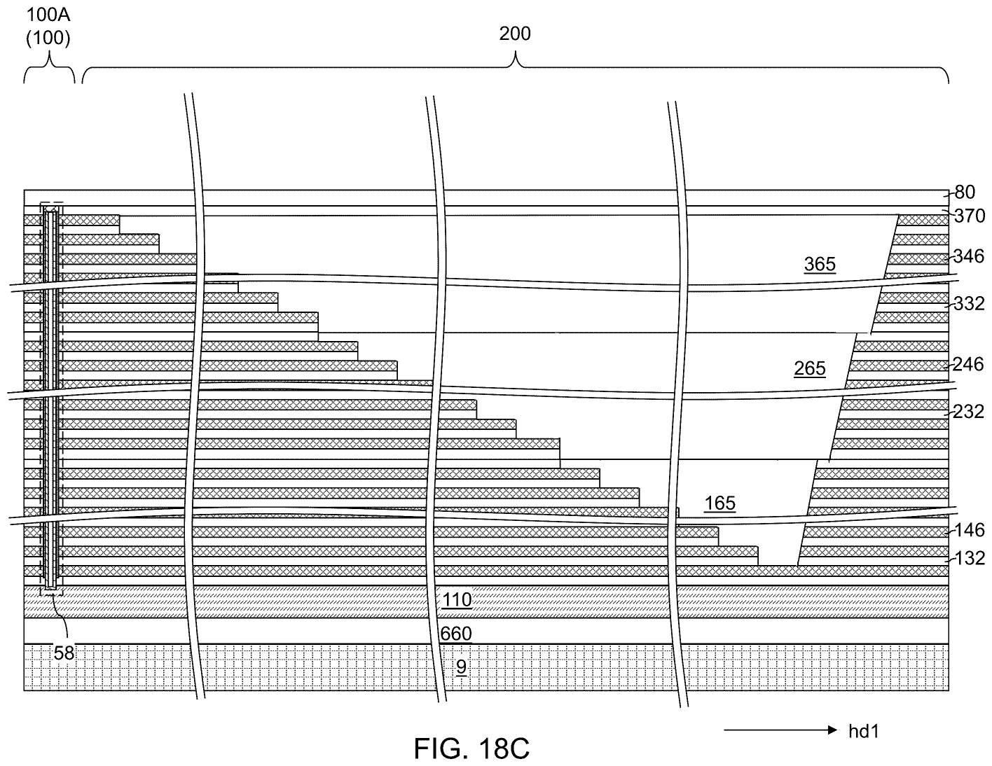

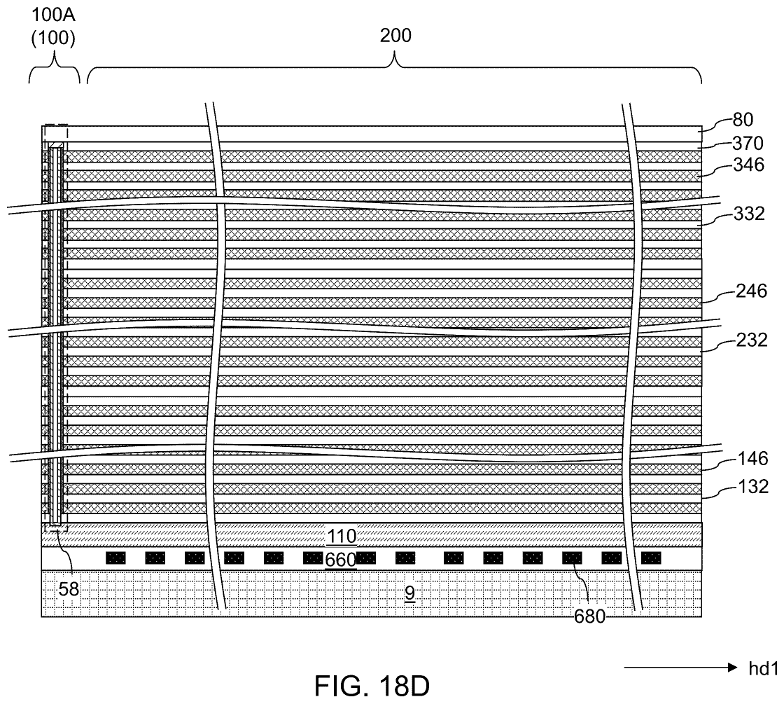

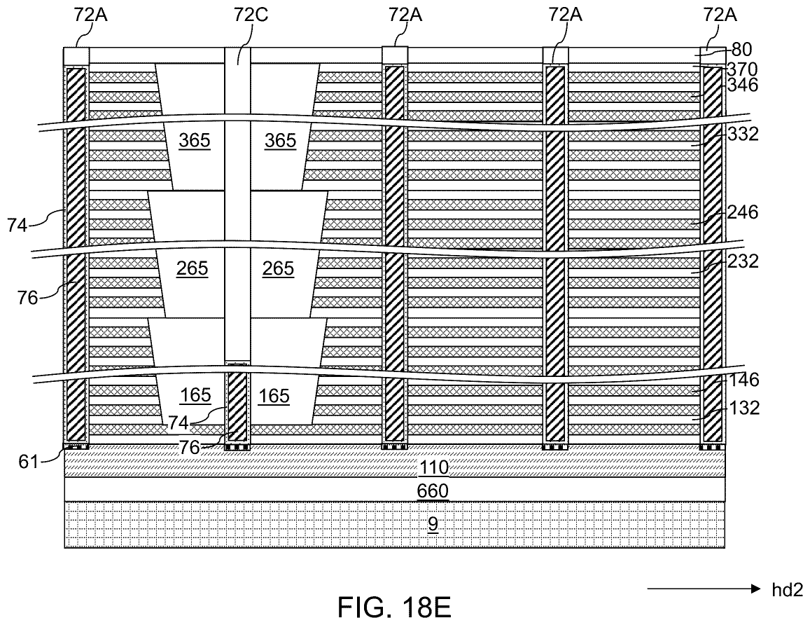

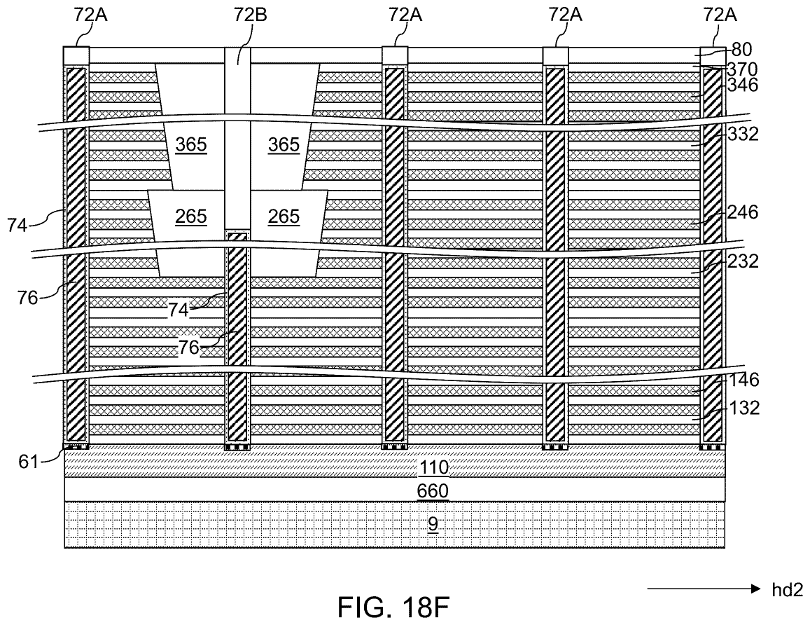

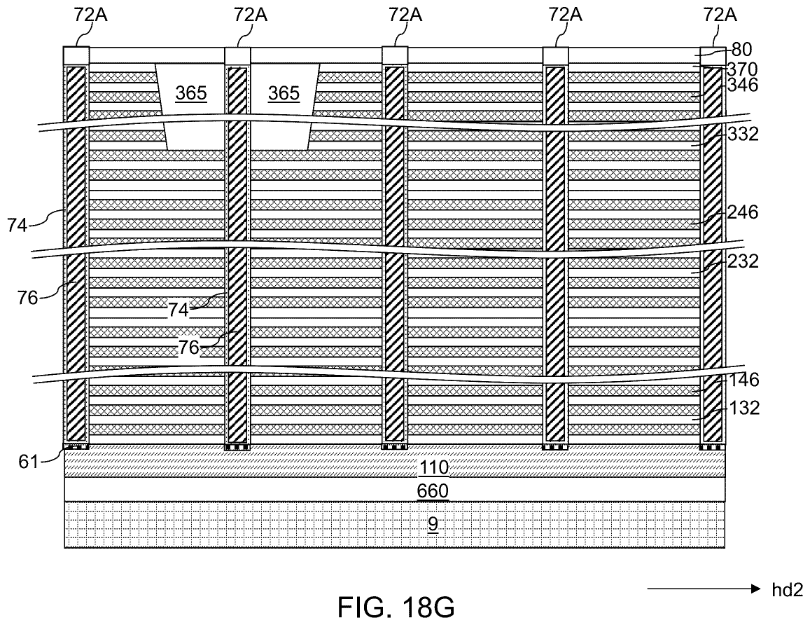

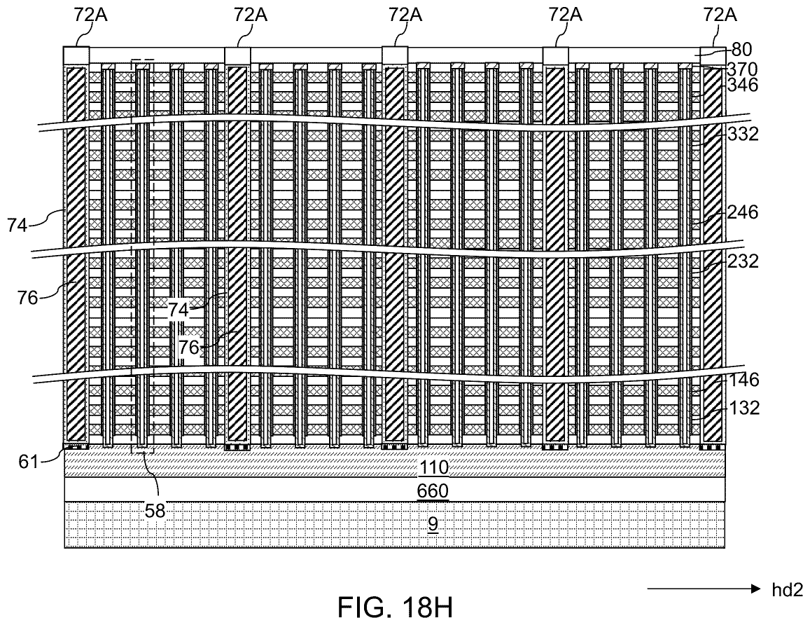

Referring to FIGS. 18A-18H, a dielectric material portion can be formed in each laterally-extending trench 79. The dielectric material portions that are formed in the first laterally-extending trenches 79A are herein referred to as first trench dielectric material portions, and the dielectric material portions that are formed in the second laterally-extending trenches 79B are herein referred to as second trench dielectric material portions. In one embodiment, the dielectric material portions may comprise dielectric liners 74. In this case, the dielectric liners 74 may be formed by conformally depositing a dielectric liner material (such as silicon oxide, silicon nitride, and/or a dielectric metal oxide) having a thickness that is less than the width of each laterally-extending trench 79 along the second horizontal direction hd2, and by performing an anisotropic etch process that removes unmasked horizontally-extending portions of the conformally deposited dielectric liner material. The anisotropic etch process removes exposed horizontal portions of the dielectric liner 74 from underlying horizontal surfaces, and exposes portions of the source regions 61 that do not underlie the dielectric bridge structures (72A, 72B, 72C). In an alternative embodiment, the dielectric liner 74 may be removed under the dielectric bridge structures (72A, 72B, 72C).

Each sidewall of the laterally-extending trenches 79 and each sidewall of the dielectric bridge structures (72A, 72B, 72C) may be covered by a respective vertically-extending portion of a dielectric liner 74. Further, each bottom surface of the dielectric bridge structures (72A, 72B, 72C) and each segment of the top surfaces of the source regions 61 that underlies a respective one of the dielectric bridge structures (72A, 72B, 72C) may be covered by a horizontally-extending portion of a respective dielectric liner 74. The thickness of the dielectric liner 74 may be in a range from 5 nm to 100 nm, such as from 10 nm to 50 nm, although lesser and greater thicknesses may also be employed.

At least one conductive material, such as at least one metallic material, may be deposited in remaining volumes of the laterally-extending trenches 79. Excess portions of the at least one conductive material can be removed from above the first horizontal plane HP1 including the top surface of the contact-level dielectric layer 80 by a planarization process, such as a chemical mechanical polishing process. Each remaining portion of the at least one conductive material in respective laterally-extending trench 79 constitutes a via structure, which is herein referred to as a trench fill via structure 76. In an alternative embodiment, if the dielectric liner 74 is removed under the dielectric bridge structures (72A, 72B, 72C), then the conductive material of the structure 76 extends along the entire trench 79. Each trench fill via structure 76 may vertically extend from the first horizontal plane HP1 to a top surface of a respective top surface segment of a source region 61 between each neighboring pair of dielectric bridge structures (72A, 72B, 72C). Each trench fill via structure 76 may vertically extend from underneath a dielectric bridge structure (72A, 72B, 72C) to a top surface of a horizontally-extending portion of a dielectric liner 74 contacting a top surface segment of a source region 61 within the area of the dielectric bridge structure (72A, 72B, 72C).

At least one alternating stack {(132, 146), (232, 246), (332, 346)} of insulating layers (132, 232, 332) and electrically conductive layers (146, 246, 346) is provided between each neighboring pair of a first laterally-extending trench 79A and a second laterally-extending trench 79B. A first laterally-extending trench fill structure (72A, 72B, 72C, 74, 76) can be formed within each first laterally-extending trench 79A. The first laterally-extending trench fill structure (72A, 72B, 72C, 74, 76) contacts the first lengthwise sidewall LS1 of the at least one alternating stack {(132, 146), (232, 246), (332, 346)}. In one embodiment, the first laterally-extending trench fill structure (72A, 72B, 72C, 74, 76) comprises a first trench dielectric material portion, which may comprise a dielectric liner 74 having a thickness that is less than one half of a lateral dimension of the first laterally-extending trench fill structure {72A, 72B, 72C, (74, 76)} along a second horizontal direction hd2 that is perpendicular to the first horizontal direction hd1. Further, the first laterally-extending trench fill structure (72A, 72B, 72C, 74, 76) may further comprise a trench fill via structure 76 that vertically extends from the first horizontal plane HP1 to a top surface of the semiconductor material layer 110 (such as a top surface of a source region 61).

In one embodiment, the first-type dielectric bridge structure 72A does not contact any of the retro-stepped dielectric material portions (165, 265, 365). In one embodiment, the second-type dielectric bridge structure 72B and the optional third-type dielectric bridge structure 72C contact a topmost retro-stepped dielectric material portion (such as a third retro-stepped dielectric material portion 365) and optionally another retro-stepped dielectric material portion (such as a second retro-stepped dielectric material portion 265). In one embodiment, the first trench dielectric material portion (such as the first dielectric liner 74) contacts each retro-stepped dielectric material portion within the two or more retro-stepped dielectric material portions (165, 265, 365) that are vertically stacked.

A second laterally-extending trench fill structure (72A, 74, 76) can be formed within the second laterally-extending trench 79B. The second laterally-extending trench fill structure (72A, 74, 76) can contact the second lengthwise sidewall LS2 of the at least one alternating stack {(132, 146), (232, 246), (332, 346)}. The second laterally-extending trench fill structure (72A, 74, 76) can comprise additional dielectric bridge structures (such as additional first-type dielectric bridge structures 72A). Each dielectric bridge structure within the second laterally-extending trench fill structure (72A, 74, 76) has a same vertical extent that is the same as the first vertical distance (such as the first vertical extent VE1). In one embodiment, the second laterally-extending trench fill structure {72A, (74, 76)} comprises a second trench dielectric material portion (e.g., a second dielectric liner 74) contacting each of the additional dielectric bridge structures and having a same material composition as the first trench dielectric material portion (e.g., the first dielectric liner 74).

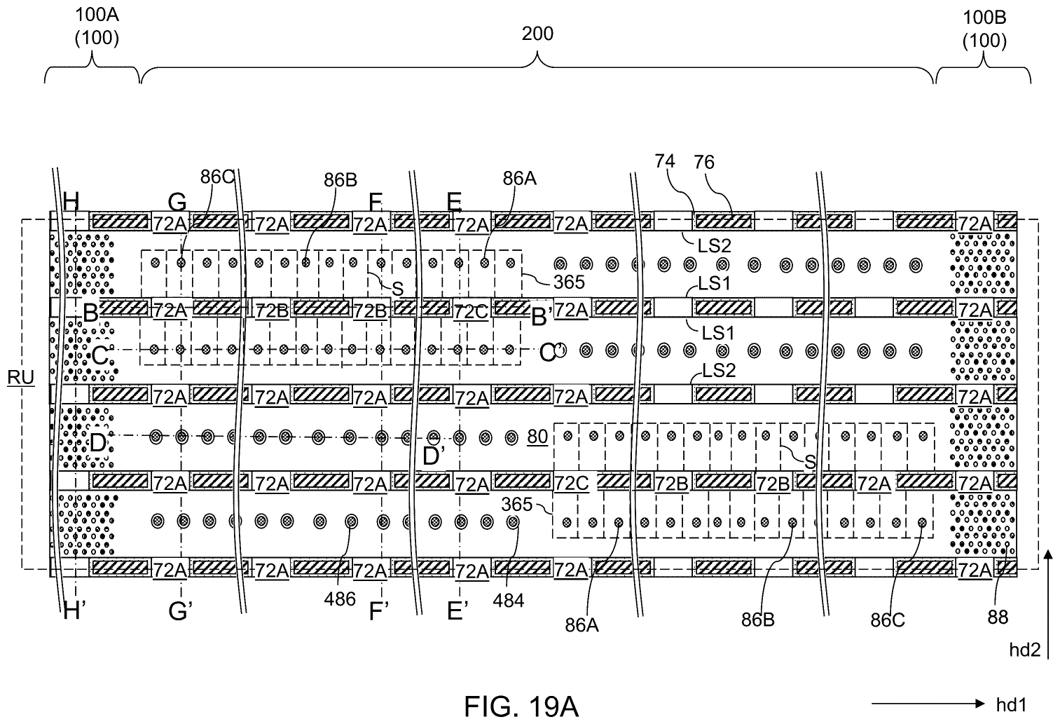

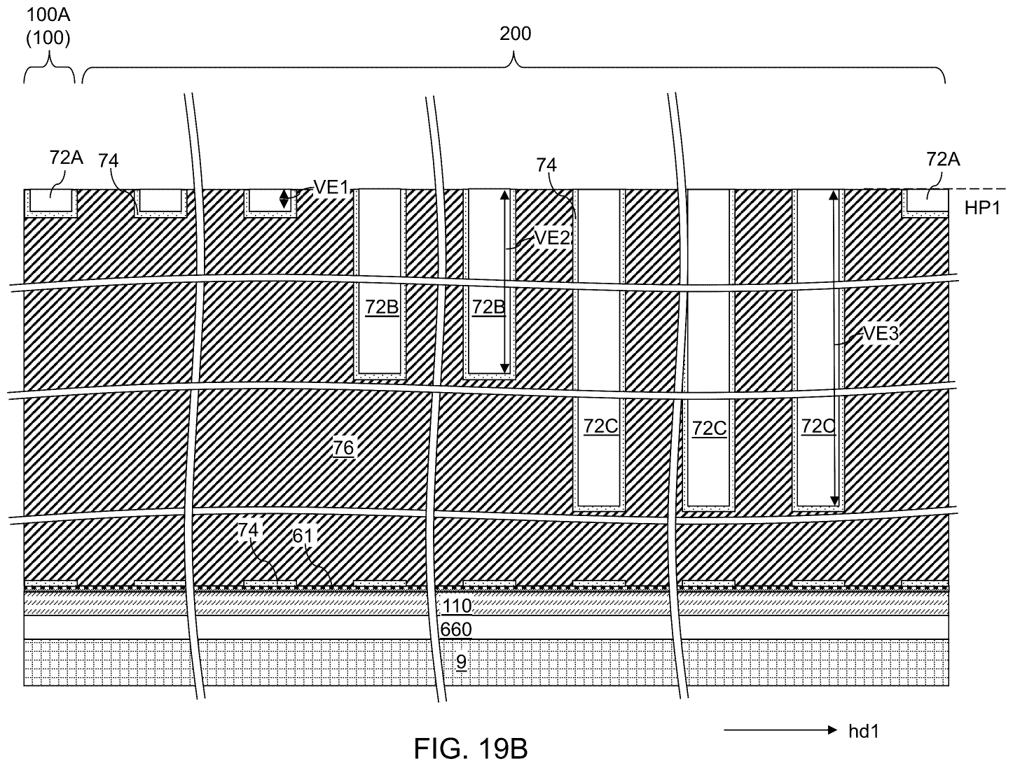

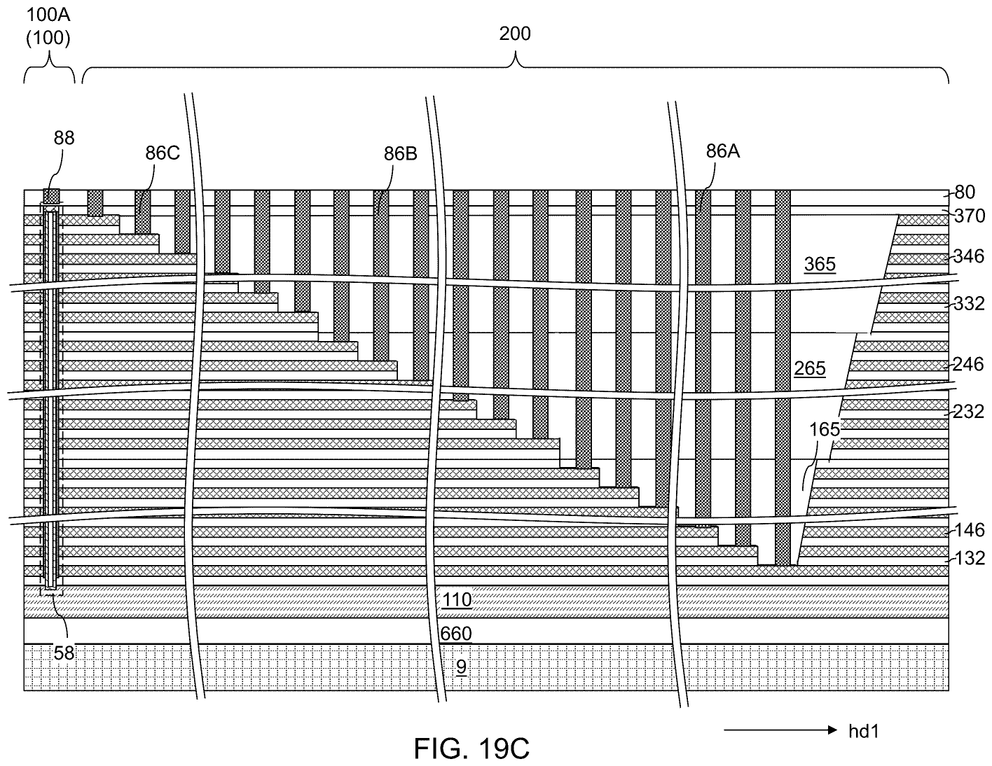

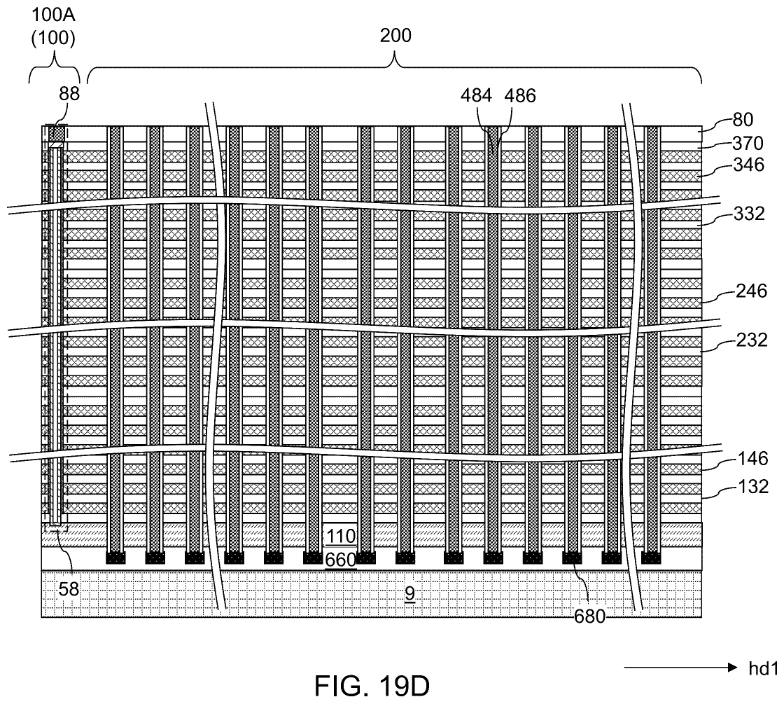

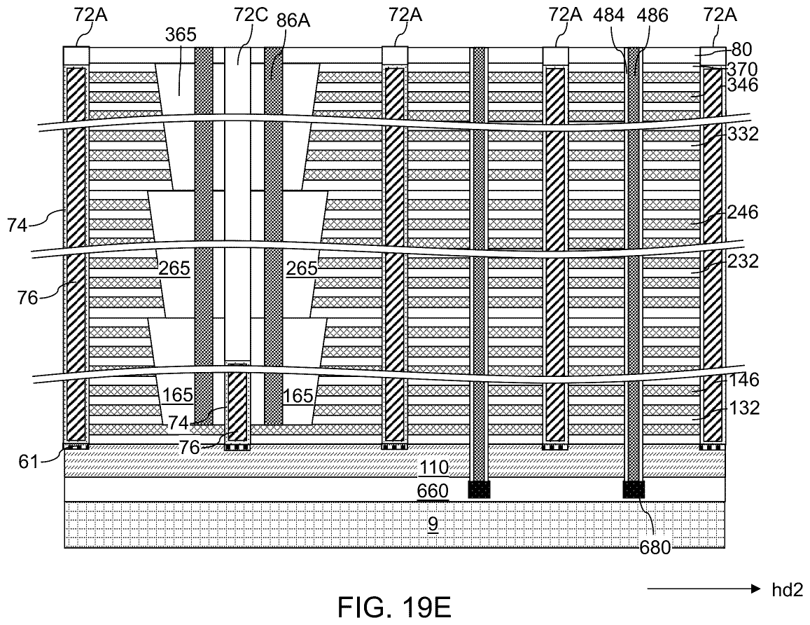

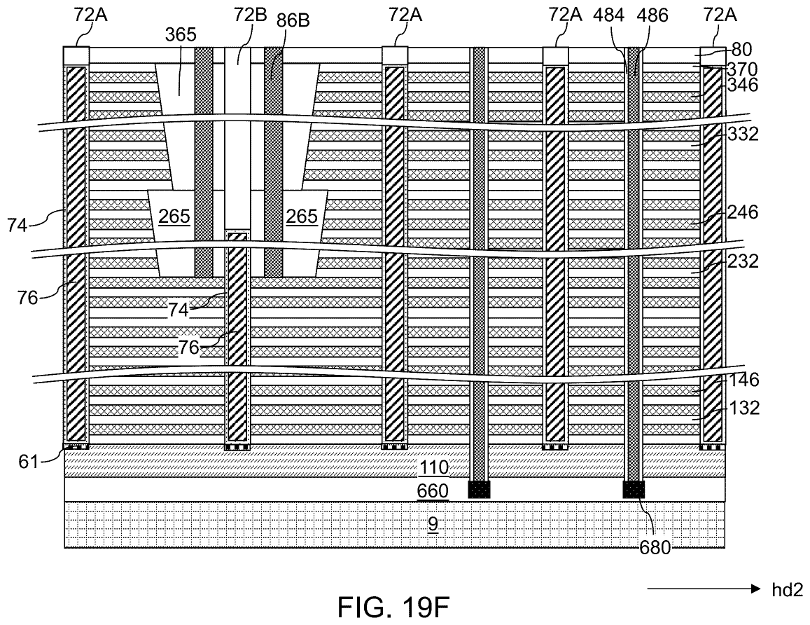

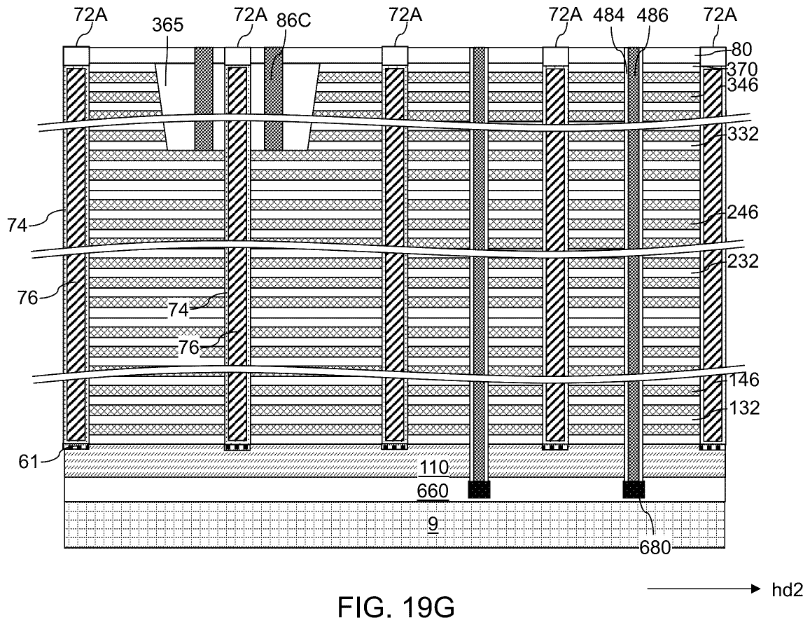

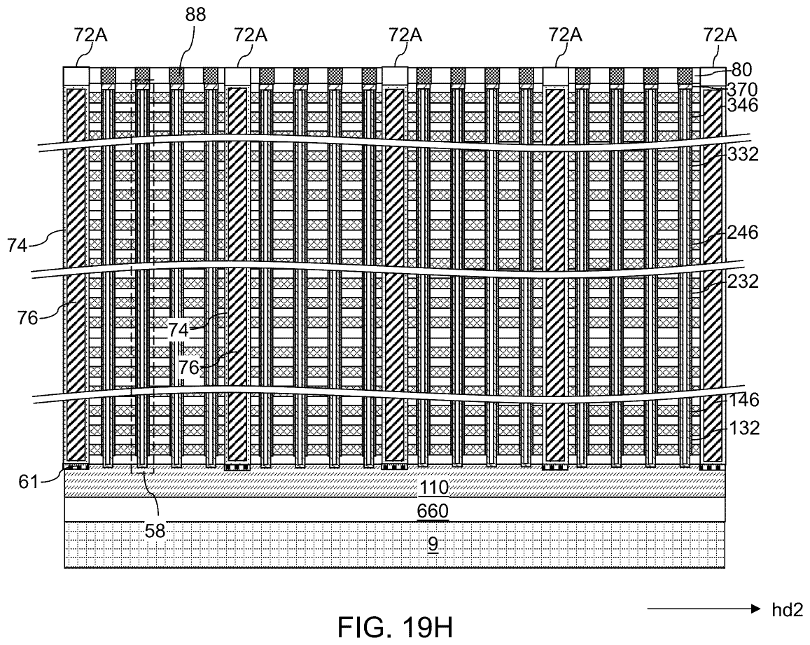

Referring to FIGS. 19A-19H, layer contact via structures (86A, 86B, 86C) can be formed through the contact-level dielectric layer 80 and through the at least one retro-stepped dielectric material portion (165, 265, 365) directly on a top surface of a respective electrically conductive layer {(146, 246, 346)} within the at least one alternating stack {(132, 146), (232, 246), (332, 346)}. The layer contact via structures (86A, 86B, 86C) may comprise first layer contact via structures 86A contacting a respective first electrically conductive layer 146, second layer contact via structures 86B contacting a respective second electrically conductive layer 246, and third layer contact via structures 86C contacting a respective third electrically conductive layer 346. Drain contact via structures 88 can be formed through the contact-level dielectric layer 80 on a top surface of a respective drain region 63.

In some embodiments, through-memory-level connection via structures 486 may be formed through the alternating stacks {(132, 146), (232, 246), (332, 346)} on a top surface of a respective metallic landing pads 680. In this case, the through-memory-level connection via structures 486 may be electrically isolated from the alternating stacks {(132, 146), (232, 246), (332, 346)} by tubular dielectric liners 484. In alternative embodiments, such as where the peripheral circuit 720 is formed in a separate logic die 700 which is bonded to the memory die 900, the through-memory-level connection via structures 486 and the tubular dielectric liners 484 may be omitted.

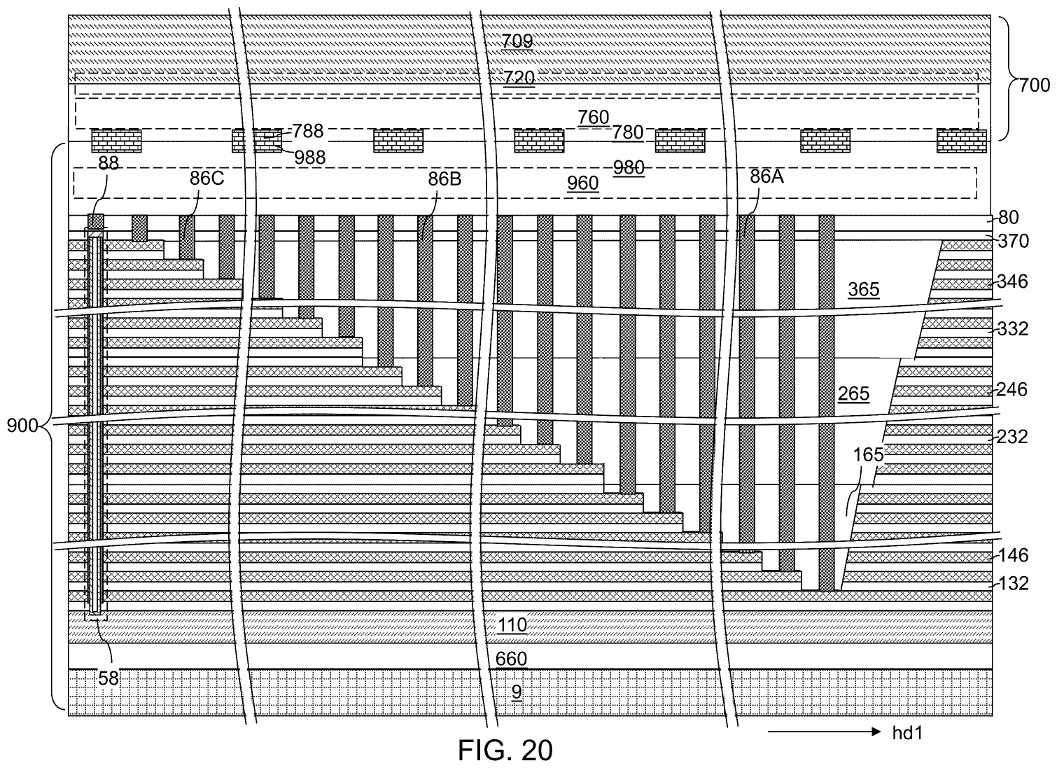

Referring to FIG. 20, additional dielectric material layers and additional metal interconnect structures can be formed over the contact-level dielectric layer 80. The additional dielectric material layers may include at least one via-level dielectric layer, at least one additional line-level dielectric layer, and/or at least one additional line-and-via-level dielectric layer. The additional metal interconnect structures may comprise metal via structures, metal line structures, and/or integrated metal line-and-via structures. The additional dielectric material layers that are formed above the contact-level dielectric layer 80 are herein referred to as memory-side dielectric material layers 960. The additional metal interconnect structures are collectively referred to as memory-side dielectric material layers 960. The memory-side dielectric material layers 960 comprise a bit-line-level dielectric material layer embedding bit lines, which are a subset of the memory-side metal interconnect structures 980.

Metal bonding pads, which are herein referred to as upper bonding pads 988, may be formed at the topmost level of the memory-side dielectric material layers 960. The upper bonding pads 988 may be electrically connected to the memory-side metal interconnect structures 980 and various nodes of the three-dimensional memory array including the alternating stacks of insulating layers (132, 232, 332) and electrically conductive layers (146, 246, 346) and the memory opening fill structures 58. A memory die 900 can thus be provided.

The memory-side dielectric material layers 960 are formed over the alternating stacks {(132, 146), (232, 246), (332, 346)}. The memory-side metal interconnect structures 980 are embedded in the memory-side dielectric material layers 960. The memory-side bonding pads 988 can be embedded within the memory-side dielectric material layers 960, and specifically, within the topmost layer among the memory-side dielectric material layers 960. The memory-side bonding pads 988 can be electrically connected to the memory-side metal interconnect structures 980.

Generally speaking, a memory die 900 is provided, which comprises a memory array, memory-side metal interconnect structures 980, and memory-side bonding pads 988 embedded within memory-side dielectric material layers 960. The memory die 900 comprises a memory device, which may comprise a three-dimensional memory array including an alternating stack of insulating layers (132, 232, 332) and electrically conductive layers (146, 246, 346), and further comprises a two-dimensional array of NAND strings vertically extending through the alternating stacks {(132, 146), (232, 246), (332, 346)}. In one embodiment, the electrically conductive layers (146, 246, 346) comprise word lines of the two-dimensional array of NAND strings. In one embodiment, the memory-side metal interconnect structures 980 comprise bit lines for the two-dimensional array of NAND strings.

In one embodiment, a logic die 700 can be provided. The logic die 700 comprises a peripheral circuit 720 that is formed on a logic-side substrate 709. According to an aspect of the present disclosure, the peripheral circuit 720 can be configured to control operation of the memory array within the memory die 900. For example, the peripheral circuit 720 may comprise word line driver regions, bit line driver regions, sense amplifier regions, input/output buffer regions, etc. Logic-side metal interconnect structures 780 embedded within logic-side dielectric material layers 760 can be formed over the peripheral circuit 720. The logic die 700 comprises logic-side bonding pads 788 embedded within logic-side dielectric material layers 760.

In one embodiment shown in FIGS. 2B-2D, a first peripheral circuit 920 may be provided on a top surface of the substrate 9, and the peripheral circuit 720 in the logic die 700 may comprise a second peripheral circuit that is employed in conjunction with the first peripheral circuit to control the operation of the three-dimensional memory array in the memory die 900. Alternatively, if the substrate 9 is a carrier substrate or if no peripheral circuit 920 is provided on a top surface of the substrate 9, the peripheral circuit 720 may be the sole control circuit for controlling the operation of the three-dimensional memory device in the memory die 900. Alternatively, the logic die 700 may not be employed, and the peripheral circuit 920 provided on the top surface of the substrate 9 may be employed to control the operation of the three-dimensional memory device in the memory die 900. The peripheral circuit provided on the top surface of the substrate 9 may be located below and/or next to the at least one alternating stack [{(132, 146), (232, 246), (332, 346)}, (32, 46)]

Subsequently, a bonded assembly can be formed by bonding a logic die 700 with the memory die 900. The logic die 700 can be attached to the memory die 900, for example, by bonding the logic-side bonding pads 788 to the memory-side bonding pads 988. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within a respective memory die 900.

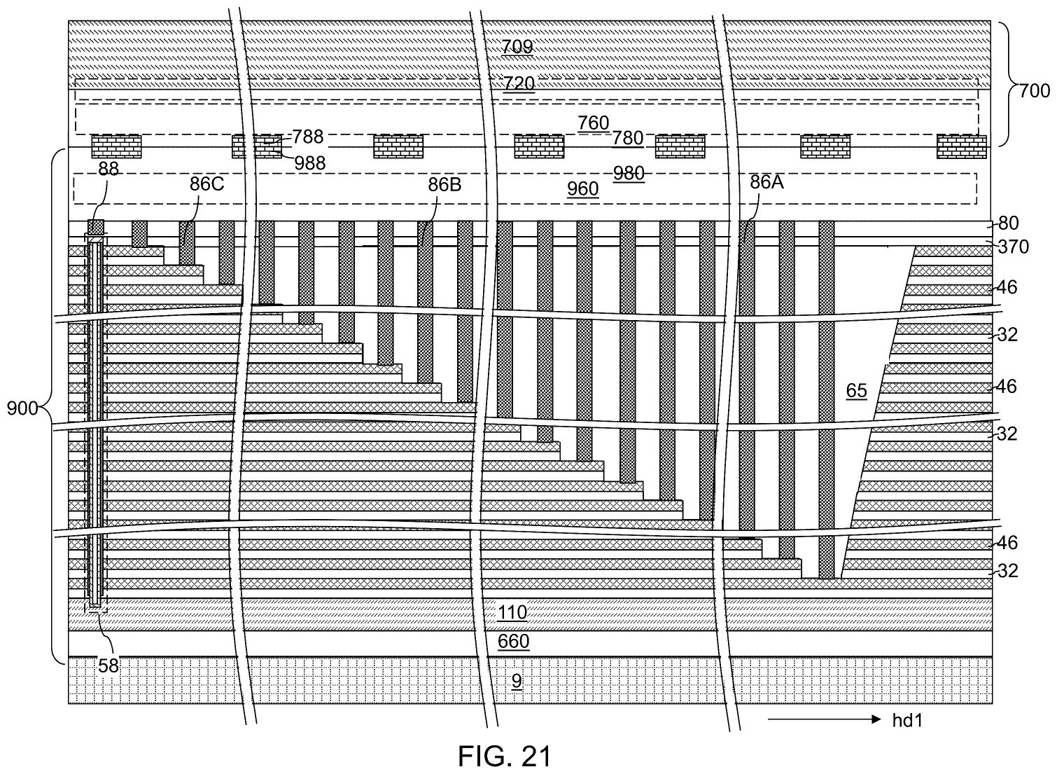

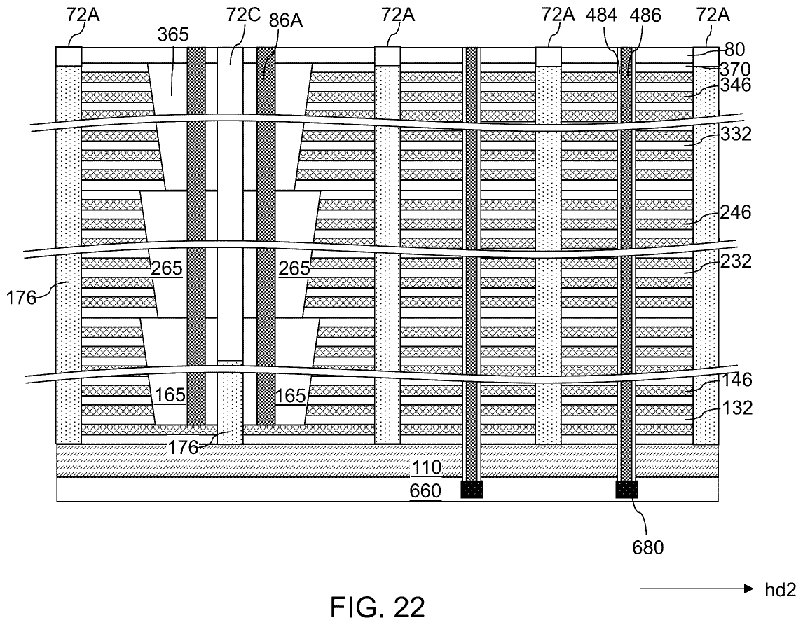

Referring to FIG. 21, a first alternative configuration of the exemplary structure according to an embodiment of the present disclosure can be derived from the exemplary structure illustrated in FIG. 20 (or derivatives thereof as described above) by employing a single-tier structure in lieu of a multi-tier structure. In this case, a single vertically alternating sequence of insulating layers 32 and sacrificial material layers are formed, and laterally-extending trenches are formed through the single vertically alternating sequence. A single retro-stepped dielectric material portion 65 can be formed in lieu of each vertical stack of a first retro-stepped dielectric material portion 165, a second retro-stepped dielectric material portion 265, and a third retro-stepped dielectric material portion 365.

An alternating stack of insulating layers 32 and sacrificial material layers can be formed between each neighboring pair of a first laterally-extending trench 79A and a second laterally-extending trench 79B. Sacrificial lateral-isolation trench fill structures 71 may be formed as described above, and first-type recess cavities 73A having a first depth D1 and second-type recess cavities 73B having a second depth D2 may be formed. Optionally, third-type recess cavities 73C having a third depth D3 may be formed. The first depth D1 is less than the sum of the thickness of the contact-level dielectric layer 80 and the thickness of the insulating cap layer 370; the second depth is greater than the sum of the thickness of the contact-level dielectric layer 80 and the thickness of the insulating cap layer 370; and the third depth D3 is greater than the second depth D3. In one embodiment, the first-type dielectric bridge structures 72A do not contact the retro-stepped dielectric material portion 65, and the second-type dielectric bridge structures 72B (and the third-type dielectric bridge structures 72C) contact a sidewall of a respective retro-stepped dielectric material portion 65, but do not contact the sacrificial material layers or the electrically conductive layers 46.

Referring to FIG. 22, a second alternative configuration of the exemplary structure according to an embodiment of the present disclosure can be derived from the exemplary structures illustrated in FIG. 20 or 21 (or derivatives thereof as described above) by forming trench dielectric material portions that fill all remaining volumes of the laterally-extending cavities 79′ after formation of the dielectric bridge structures (72A, 72B, 72C). In this case, the trench dielectric material portions may comprise dielectric trench fill material portions 176. The volumes of the lateral isolation trenches 79 are not employed for source interconnects local interconnects. In this case, formation of the source regions 61 may be omitted, and horizontal discrete strap contacts (e.g., source regions) comprising a doped semiconductor material of the second conductivity type may contact a lower portion of a sidewall of respective vertical semiconductor channels 60.

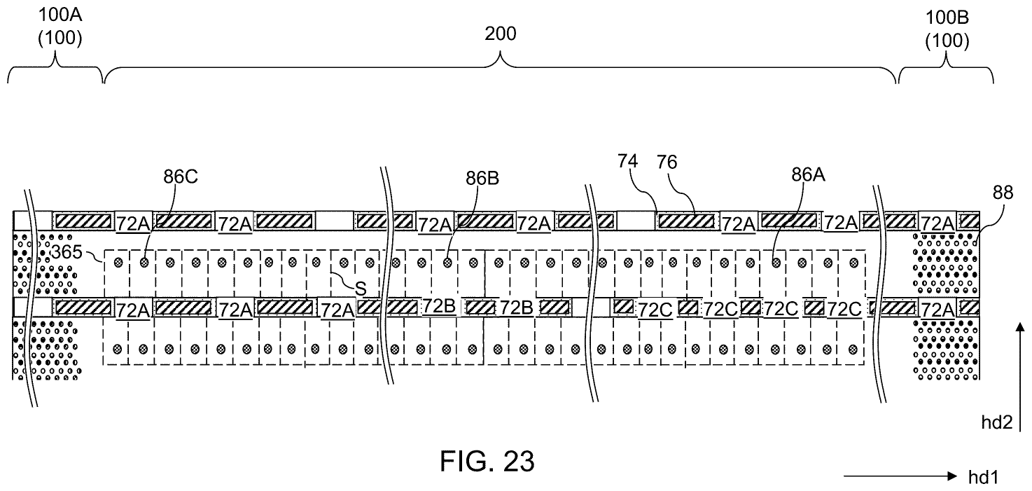

Referring to FIG. 23, a third alternative configuration of the exemplary structure according to an embodiment of the present disclosure can be derived from the exemplary structures illustrated in FIGS. 19A-19H, 20 or 21 (or derivatives thereof as described above) by varying the pitch between the dielectric bridge structures located laterally adjacent to different parts of a staircase. For example, the first-type dielectric bridge structures 72A may have a first pitch, and the second-type dielectric bridge structures 72B may have a second pitch which is different from the first pitch. If present, the third-type dielectric bridge structures 72C may have a third pitch which is different from the first pitch and the second pitch.

In one configuration, the second-type dielectric bridge structures 72B may be located laterally adjacent to a deeper part of the staircase than the first-type dielectric bridge structures 72A. The third-type dielectric bridge structures 72C (if present) may be located laterally adjacent to an even deeper part of the staircase than both the first-type dielectric bridge structures 72A and the second-type dielectric bridge structures 72B. In other words, the third-type dielectric bridge structures 72C located laterally adjacent to the deepest part of the staircase (which includes the lowermost stepped surfaces, e.g., the stepped surfaces of the first electrically conductive layers 146) may be located closer to each other (i.e., laterally spaced by a smaller distance along the first horizontal direction hd1) than the second-type dielectric bridge structures 72B which are located laterally adjacent to an intermediate depth part of the staircase. The second-type dielectric bridge structures 72B may be located closer to each other (i.e., laterally spaced by a smaller distance along the first horizontal direction hd1) than the first-type dielectric bridge structures 72A which are located laterally adjacent to the shallowest part of the staircase. Thus, the dielectric bridge structures with the smaller pitch are located laterally adjacent to a deeper part of the staircase than the dielectric bridge structures with a larger pitch.

In this embodiment, the first-type dielectric bridge structures 72A, the second-type dielectric bridge structures 72B, and the third-type dielectric bridge structures 72C may have the same volume (i.e., the same length, width and thickness). Alternatively, the first-type dielectric bridge structures 72A, the second-type dielectric bridge structures 72B, and the third-type dielectric bridge structures 72C may have different volumes from each other. For example, the third-type dielectric bridge structures 72C may have a greater volume (e.g., greater length, width and/or thickness) and a smaller pitch than the second-type dielectric bridge structures 72B. The second-type dielectric bridge structures 72B may have a greater volume (e.g., greater length, width and/or thickness) and a smaller pitch than the first-type dielectric bridge structures 72A.

Referring to all drawings and according to various embodiments of the present disclosure, a three-dimensional memory device comprises: at least one alternating stack [{(132, 146), (232, 246), (332, 346)}. (32, 46)] of insulating layers {(132, 232, 332), 32} and electrically conductive layers {(146, 246, 346), 46} having a first lengthwise sidewall LS1 and a second lengthwise sidewall LS2 that laterally extend along a first horizontal direction hd1; memory openings 49 vertically extending through the at least one alternating stack [{(132, 146), (232, 246), (332, 346)}. (32, 46)]; memory opening fill structures 58 located in the memory openings 49, wherein each of the memory opening fill structures 58 comprises a vertical semiconductor channel 60 and respective vertical stack of memory elements (e.g., portions of the memory film 50) located at levels of the electrically conductive layers {(146, 246, 346), 46}; and a first laterally-extending trench fill structure {72A, 72B, 72C, and (74, 76) or 176} contacting the first lengthwise sidewall LS1 of the at least one alternating stack [{(132, 146), (232, 246), (332, 346)}, (32, 46)]. The first laterally-extending trench fill structure {72A, 72B, 72C, and (74, 76) or 176} comprises: a first-type dielectric bridge structure 72A having a first volume; a second-type dielectric bridge structure 72B having a second volume greater than the first volume; and a first trench dielectric material portion {(74, 76) or 176}.

In one embodiment shown in FIGS. 14A-14H, the second-type dielectric bridge structure 72B has a greater vertical thickness (i.e., height) than the first-type dielectric bridge structure 72A. In alternative embodiments shown in FIGS. 14I and 14J, the second-type dielectric bridge structure 72B has at least one of a greater horizontal length along the first horizontal direction hd1 or a greater horizontal width along a second horizontal direction hd2 perpendicular to the first horizontal direction hd1 than the first-type dielectric bridge structure 72A, instead of or in addition to the greater vertical thickness.

In one embodiment, the first-type dielectric bridge structure 72A has a first top surface located within a first horizontal plane HP1 and has a first bottom surface that is vertically spaced from the first horizontal plane HP1 by a first vertical distance (such as the first vertical extent VE1). The second-type dielectric bridge structure 72B has a second top surface located within the first horizontal plane HP1 and having a second bottom surface that is vertically spaced from the first horizontal plane HP1 by a second vertical distance (such as the second vertical extent VE2) greater than the first vertical distance VE1.

In one embodiment, the first trench dielectric material portion (74 or 176) comprises a topmost surface segment located within the first horizontal plane HP1 between the first-type dielectric bridge structure 72A and the second-type dielectric bridge structure 72B, a first recessed surface segment contacting the first bottom surface, and a second recessed surface segment contacting the second bottom surface.

In one embodiment shown in FIG. 23, the first laterally-extending trench fill structure {72A, 72B, 72C, and (74, 76) or 176} comprises a plurality of the first-type dielectric bridge structures 72A having the first volume and a first pitch; and a plurality of the second-type dielectric bridge structures 72B having a second volume greater than the first volume, and a second pitch smaller than the first pitch.

In one embodiment, the three-dimensional memory device further comprises at least one retro-stepped dielectric material portion {(165, 265, 365), 65} embedded within the at least one alternating stack [{(132, 146), (232, 246), (332, 346)}, (32, 46)] and comprising a respective dielectric material, wherein one of the at least one retro-stepped dielectric material portion {(165, 265, 365), 65} contacts each of the first-type dielectric bridge structure 72A, the second-type dielectric bridge structure 72B, and the first trench dielectric material portion (74 or 176).

In one embodiment, the at least one alternating stack [{(132, 146), (232, 246), (332, 346)}. (32, 46)] comprises a staircase having stepped surfaces “S”. The stepped surfaces S contact stepped bottom surfaces of the at least one retro-stepped dielectric material portion {(165, 265, 365), 65}. The staircase comprises a respective lengthwise sidewall LS1 that contacts the first laterally-extending trench fill structure {72A, 72B, 72C, and (74, 76) or 176}. The memory opening fill structures 58 are located in a first memory array region 100A and in a second memory array region 100B. The staircase is located between the first and the second memory array regions (100A, 100B). The electrically conductive layers {(146, 246, 346), 46} extend continuously from the first memory array region 100A to the second memory array region 100B (e.g., along the first horizontal direction hd1 which corresponds to the word line direction). The first-type dielectric bridge structure 72A is located laterally adjacent to an upper portion of the staircase; and the second-type bridge structure 72B is located laterally adjacent to a lower portion of the staircase which is located closer to the substrate 9 than the upper portion of the staircase.

In one embodiment, the three-dimensional memory device further comprises layer contact via structures 86 vertically extending through the at least one retro-stepped dielectric material portion {(165, 265, 365), 65} and contacting a top surface of a respective electrically conductive layer {(146, 246, 346), 46} within the at least one alternating stack [{(132, 146), (232, 246), (332, 346)}, (32, 46)].

In one embodiment, the at least one retro-stepped dielectric material portion {(165, 265, 365), 65} is laterally spaced from the second lengthwise sidewall LS2.

In one embodiment, the first laterally-extending trench fill structure {72A, 72B, 72C, (74, 76) or 176} further comprises an additional first-type dielectric bridge structure 72A that is laterally spaced from the first-type dielectric bridge structure 72A and from the second-type dielectric bridge structure 72B, and does not directly contact any electrically conductive layer {(146, 246, 346), 46} within the at least one alternating stack [{(132, 146), (232, 246), (332, 346)}. (32, 46)] or the at least one retro-stepped dielectric material portion {(165, 265, 365), 65}.

In one embodiment, the at least one retro-stepped dielectric material portion {(165, 265, 365), 65} comprises two or more retro-stepped dielectric material portions (165, 265, 365) that comprise: a bottommost retro-stepped dielectric material portion 165; and a topmost retro-stepped dielectric material portion (265 or 365 depending on the number of tiers) that overlies the bottommost retro-stepped dielectric material portion 165, and contacts each of the first-type dielectric bridge structure 72A, the second-type dielectric bridge structure 72B, and the first trench dielectric material portion (74 or 176).

In one embodiment, the first-type dielectric bridge structure 72A does not contact any of the two or more retro-stepped dielectric material portions (165, 265, 365); and the second-type dielectric bridge structure 72B contacts the topmost retro-stepped dielectric material portion (265 or 365). In one embodiment, the first trench dielectric material portion (74 or 176) contacts each of the two or more retro-stepped dielectric material portions (165, 265, 365).

In one embodiment, the first laterally-extending trench fill structure further comprises a third-type dielectric bridge structure 72C having a third volume greater than the second volume of the second-type dielectric bridge structure 72B.

In one embodiment, the three-dimensional memory device comprises a second laterally-extending trench fill structure {72A, (74, 76) or 176} contacting the second lengthwise sidewall LS2 of the at least one alternating stack [{(132, 146), (232, 246), (332, 346)}, (32, 46)] and comprising additional dielectric bridge structures. Each of the additional dielectric bridge structures within the second laterally-extending trench fill structure {72A, (74, 76) or 176} has the first volume. In one embodiment, each of the additional dielectric bridge structures 72A has a same vertical thickness, horizontal length and horizontal width as each of the first-type dielectric bridge structures 72A; and the second laterally-extending trench fill structure {72A, (74, 76) or 176} comprises a second trench dielectric material portion (74 or 176) contacting each of the additional dielectric bridge structures and having a same material composition as the first trench dielectric material portion (74 or 176). Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. If publications, patent applications, and/or patents are cited herein, each of such documents is incorporated herein by reference in their entirety.

What is claimed is:

1. A three-dimensional memory device, comprising:
at least one alternating stack of insulating layers and electrically conductive layers having a first lengthwise sidewall and a second lengthwise sidewall that laterally extend along a first horizontal direction;
memory openings vertically extending through the at least one alternating stack;
memory opening fill structures located in the memory openings, wherein each of the memory opening fill structures comprises a vertical semiconductor channel and a respective vertical stack of memory elements located at levels of the electrically conductive layers; and
a first laterally-extending trench fill structure contacting the first lengthwise sidewall of the at least one alternating stack and comprising:
a first-type dielectric bridge structure having a first volume;
a second-type dielectric bridge structure having a second volume greater than the first volume; and
a first trench dielectric material portion.

2. The three-dimensional memory device of claim 1, wherein the second-type dielectric bridge structure has a greater vertical thickness than the first-type dielectric bridge structure.

3. The three-dimensional memory device of claim 2, wherein:
the first-type dielectric bridge structure has a first top surface located within a first horizontal plane and has a first bottom surface that is vertically spaced from the first horizontal plane by a first vertical distance;
the second-type dielectric bridge structure has a second top surface located within the first horizontal plane and having a second bottom surface that is vertically spaced from the first horizontal plane by a second vertical distance greater than the first vertical distance; and
the first trench dielectric material portion comprises a topmost surface segment located within the first horizontal plane between the first-type dielectric bridge structure and the second-type dielectric bridge structure, a first recessed surface segment contacting the first bottom surface, and a second recessed surface segment contacting the second bottom surface.

4. The three-dimensional memory device of claim 1, wherein the first laterally-extending trench fill structure comprises:
a plurality of the first-type dielectric bridge structures having the first volume and a first pitch; and
a plurality of the second-type dielectric bridge structures having a second volume greater than the first volume, and a second pitch different from the first pitch.

5. The three-dimensional memory device of claim 1, wherein the second-type dielectric bridge structure has at least one of a greater horizontal length along the first horizontal direction or a greater horizontal width along a second horizontal direction perpendicular to the first horizontal direction than the first-type dielectric bridge structure.

6. The three-dimensional memory device of claim 1, further comprising at least one retro-stepped dielectric material portion embedded within the at least one alternating stack and comprising a respective dielectric material, wherein one of the at least one retro-stepped dielectric material portion contacts each of the first-type dielectric bridge structure, the second-type dielectric bridge structure, and the first trench dielectric material portion.

7. The three-dimensional memory device of claim 6, wherein:
the at least one alternating stack comprises a staircase having stepped surfaces;
the stepped surfaces contact stepped bottom surfaces of the at least one retro-stepped dielectric material portion;
the staircase comprises a respective lengthwise sidewall that contacts the first laterally-extending trench fill structure;
the memory opening fill structures are located in a first memory array region and in a second memory array region;
the staircase is located between the first and the second memory array regions;
the electrically conductive layers extend continuously from the first memory array region to the second memory array region;
the first-type dielectric bridge structure is located laterally adjacent to an upper portion of the staircase; and
the second-type bridge structure is located laterally adjacent to a lower portion of the staircase.

8. The three-dimensional memory device of claim 6, further comprising layer contact via structures vertically extending through the at least one retro-stepped dielectric material portion and contacting a top surface of a respective electrically conductive layer within the at least one alternating stack.

9. The three-dimensional memory device of claim 6, wherein the at least one retro-stepped dielectric material portion is laterally spaced from the second lengthwise sidewall.

10. The three-dimensional memory device of claim 6, wherein the first laterally-extending trench fill structure further comprises an additional first-type dielectric bridge structure that is laterally spaced from the first-type dielectric bridge structure and from the second-type dielectric bridge structure, and does not directly contact any electrically conductive layer within the at least one alternating stack or the at least one retro-stepped dielectric material portion.

11. The three-dimensional memory device of claim 6, wherein the at least one retro-stepped dielectric material portion comprises two or more retro-stepped dielectric material portions that comprise:
a bottommost retro-stepped dielectric material portion; and
a topmost retro-stepped dielectric material portion that overlies the bottommost retro-stepped dielectric material portion, and contacts each of the first-type dielectric bridge structure, the second-type dielectric bridge structure, and the first trench dielectric material portion.

12. The three-dimensional memory device of claim 11, wherein:
the first-type dielectric bridge structure does not contact any of the two or more retro-stepped dielectric material portions;
the second-type dielectric bridge structure contacts the topmost retro-stepped dielectric material portion; and
the first trench dielectric material portion contacts each of the two or more retro-stepped dielectric material portions.

13. The three-dimensional memory device of claim 1, wherein the first laterally-extending trench fill structure further comprises a third-type dielectric bridge structure having a third volume greater than the second volume.

14. The three-dimensional memory device of claim 1, further comprising a second laterally-extending trench fill structure contacting the second lengthwise sidewall of the at least one alternating stack and comprising additional dielectric bridge structures, wherein each of the additional dielectric bridge structures within the second laterally-extending trench fill structure has that first volume, wherein:
each of the additional dielectric bridge structures has a same vertical thickness, horizontal length and horizontal width as each of the first-type dielectric bridge structures; and
the second laterally-extending trench fill structure comprises a second trench dielectric material portion contacting each of the additional dielectric bridge structures and having a same material composition as the first trench dielectric material portion.

15. A three-dimensional memory device, comprising:
at least one alternating stack of insulating layers and electrically conductive layers having a first lengthwise sidewall and a second lengthwise sidewall that laterally extend along a first horizontal direction;
memory openings vertically extending through the at least one alternating stack;
memory opening fill structures located in the memory openings, wherein each of the memory opening fill structures comprises a vertical semiconductor channel and a respective vertical stack of memory elements located at levels of the electrically conductive layers; and
a first laterally-extending trench fill structure contacting the first lengthwise sidewall of the at least one alternating stack and comprising:
a first trench dielectric material portion;
a plurality of the first-type dielectric bridge structures having the first volume and a first pitch; and
a plurality of the second-type dielectric bridge structures having a second volume greater than the first volume, and a second pitch different from the first pitch.

16. A method of forming a three-dimensional memory device, comprising:
forming at least one vertically alternating sequence of insulating layers and sacrificial material layers over a substrate;
forming memory openings through the at least one vertically alternating sequence;
forming memory opening fill structures in the memory openings, wherein each of the memory opening fill structures comprises a vertical semiconductor channel and a respective vertical stack of memory elements;
forming laterally-extending trenches through the at least one at least one vertically alternating sequence, the laterally-extending trenches comprising a first laterally-extending trench and a second laterally-extending trench;
forming a first sacrificial laterally-extending trench fill structure and a second sacrificial laterally-extending trench fill structure in the first laterally-extending trench and the second laterally-extending trench, respectively;
forming a first-type recess cavity having a first volume and a second-type recess cavity having a second volume by recessing portions of the first sacrificial laterally-extending trench fill structure, wherein the second volume is greater than the first volume;
forming a first-type dielectric bridge structure and a second-type dielectric bridge structure in the first-type recess cavity and the second-type recess cavity, respectively;
removing the first sacrificial laterally-extending trench fill structure and the second sacrificial laterally-extending trench fill structure; and
replacing remaining portions of the sacrificial material layers with electrically conductive layers.

17. The method of claim 16, wherein the first-type recess cavity has first depth, and the second-type recess cavity has a second depth greater than the first depth.

18. The method of claim 17, further comprising:
forming additional recess cavities by recessing portions of the second sacrificial laterally-extending trench fill structure; and
forming additional dielectric bridge structures in the additional recess cavities, wherein each dielectric bridge structure that is formed within the second laterally-extending trench has a same vertical extent that is the same as the first depth.

19. The method of claim 17, wherein:
a bottommost surface of the first-type dielectric bridge structure is formed above a horizontal plane including a top surface of a topmost sacrificial material layer of the sacrificial material layers; and
a bottommost surface of the second-type dielectric bridge structure is formed below the horizontal plane including the top surface of the topmost sacrificial material layer.

20. The method of claim 16, further comprising:
forming at least one set of stepped surfaces by patterning the at least one vertically alternating sequence; and
forming at least one retro-stepped dielectric material portion over the at least one set of stepped surfaces,
wherein:
the first laterally-extending trench cuts through at least one retro-stepped dielectric material portion;
the second laterally-extending trench is laterally spaced from the at least one retro-stepped dielectric material portion;
the first-type dielectric bridge structure does not contact any of the at least one retro-stepped dielectric material portion; and
the second-type dielectric bridge structure is formed directly on a sidewall of the at least one retro-stepped dielectric material portion.
